(19) United States
(12) Patent Application Publication
(10) Pub. No.: US 2015/0301451 A1
(43) Pub. Date: Oct. 22, 2015

(54) PATTERN FORMING METHOD, ACTINIC RAY-SENSITIVE OR RADIATION-SENSITIVE RESIN COMPOSITION, RESIST FILM, METHOD FOR MANUFACTURING ELECTRONIC DEVICE, AND ELECTRONIC DEVICE

(71) Applicant: FUJIFILM Corporation, Tokyo (JP)

(72) Inventor: Kaoru IWATO, Haibara-gun (JP)

(73) Assignee: FUJIFILM Corporation, Tokyo (JP)

(21) Appl. No.: 14/754,017

(22) Filed: Jun. 29, 2015

Related U.S. Application Data
(63) Continuation of application No. PCT/JP2013/083238, filed on Dec. 11, 2013.

(30) Foreign Application Priority Data
Feb. 8, 2013 (JP) 2013-023550
Mar. 29, 2013 (JP) 2013-075278

(51) Int. Cl. G03F 7/038; G03F 7/20

(52) U.S. Cl. CPC G03F 7/038; G03F 7/2041

(57) ABSTRACT

A pattern forming method of the present invention includes (a) forming a film using an actinic ray-sensitive or radiation-sensitive resin composition which contains (A) to (C) below,
(A) a resin where polarity increases due to an action of acid and solubility decreases with respect to a developer which includes an organic solvent,
(B) a compound which generates acid when irradiated with actinic rays or radiation, and
(C) a compound which has a cation site and an anion site in the same molecule and where the cation site and the anion site are linked with each other by a covalent bond,
(b) exposing the film, and
(c) forming a negative tone pattern by developing the exposed film using a developer which includes an organic solvent.

### CROSS-REFERENCE TO RELATED APPLICATIONS

This application is a Continuation of PCT International Application No. PCT/JP2013/083238 filed on Dec. 11, 2013, which claims priority under 35 U.S.C. §119(a) to Japanese Patent Application No. 2013-023550 filed on Feb. 8, 2013 and Japanese Patent Application No. 2013-075278 filed on Mar. 29, 2013. Each of the above application(s) is hereby expressly incorporated by reference, in its entirety, into the present application.

### BACKGROUND OF THE INVENTION

1. Field of the Invention

The present invention relates to a pattern forming method, an actinic ray-sensitive or radiation-sensitive resin composition, a resist film, a method for manufacturing an electronic device, and an electronic device. In more detail, the present invention relates to a favorable pattern forming method for processes for manufacturing semiconductors such as IC, processes for manufacturing circuit substrates such as liquid crystals and thermal heads, and additionally lithography processes for other photofabrication, an actinic ray-sensitive or radiation-sensitive resin composition which is used in the pattern forming method, a resist film which is formed by the composition, a method for manufacturing an electronic device which includes the pattern forming method, and an electronic device. In particular, the present invention relates to a favorable pattern forming method for exposure in ArF exposure apparatuses and ArF liquid immersion type projection exposure apparatuses having far ultraviolet ray light with a wavelength of 300 nm or less as a light source, an actinic ray-sensitive or radiation-sensitive resin composition which is used in the pattern forming method, a resist film, a method for manufacturing an electronic device, and an electronic device.

2. Description of the Related Art

A pattern forming method which uses chemical amplification in order to compensate for a sensitivity decrease due to light absorption has been used since the development of a resist for a KrF excimer laser (248 nm). For example, in a positive type chemical amplification method, firstly, a photo-acid generator which is included in an exposed section generates acid by being decomposed due to light irradiation. Then, in a baking (PEB: Post Exposure Bake) process or the like after exposure, an alkali-insoluble group which is included in an actinic composition is changed to an alkali-soluble group due to the catalytic action of the generated acid. After that, development is performed, for example, using an alkali solution. Due to this, a desired pattern is obtained by removing the exposed section.

In the method described above, various types of alkali developers have been proposed. For example, as the alkali developer, water-based alkali developers such as a 2.38 mass % tetramethyl ammonium hydroxide water solution (TMAH) are widely used.

In addition, due to the refinement of semiconductor elements, the wavelength of exposure light sources has been shortened and the numerical aperture (high NA) of the projection lenses has been increased, and exposure devices which have an ArF excimer laser which has a wavelength of 193 nm as a light source are being developed. As a technique for further increasing resolution, a method (that is, a liquid immersion method) in which a liquid with a high refractive index (also referred to below as a “liquid immersion liquid”) is filled between a projection lens and a sample has been proposed. In addition, EUV lithography in which exposure is performed using ultraviolet light with an even shorter wavelength (13.5 nm) has been also proposed.

For example, in the positive type chemical amplification method described above, for the purpose of improving the performance of a resist composition which is used for forming a fine pattern, a technique of using an additive agent has been proposed (for example, refer to JP2012-189977A, JP2012-252124A, JP2013-6827A, and JP2013-8020A).

In addition, in recent years, a pattern forming method which uses a developer (an organic-based developer) which includes an organic solvent has also been developed (for example, refer to JP2011-123469A and WO2011/122336A). For example, JP2011-123469A and WO2011/122336A disclose a pattern forming method which includes a process of coating a substrate with a resist composition where a degree of solubility with respect to an organic-based developer is decreased when irradiated with actinic rays or radiation, an exposure process, and a developing process using an organic-based developer. According to these methods, it is considered that it is possible to stably form fine patterns with high precision.

### SUMMARY OF THE INVENTION

However, while it is now possible to obtain a favorable pattern shape with the pattern forming method in the related art described above which uses a developer which includes an organic solvent, in practice, there is a demand for further reductions in line width roughness (LWR) and development defects and further improvements in performance for pattern profiles and CDU, with respect to resist compositions.

The present inventors completed the present invention as a result of intensive research in order to solve the problems described above.

That is, the present invention has the following configurations.

(1) A pattern forming method including (a) forming a film using an actinic ray-sensitive or radiation-sensitive resin composition which contains (A) to (C) below, (A) a resin where polarity increases due to an action of acid and solubility decreases with respect to a developer which includes an organic solvent, (B) a compound which generates acid when irradiated with actinic rays or radiation, and (C) a compound which has a cation site and an anion site in a same molecule with the cation site and the anion site being linked with each other by a covalent bond; (b) exposing the film; and (c) forming a negative tone pattern by developing the exposed film using a developer which includes an organic solvent.

(2) The pattern forming method according to (1), in which the compound (C) is a compound which is represented by any of general Formulas (C-1) to (C-4) below.

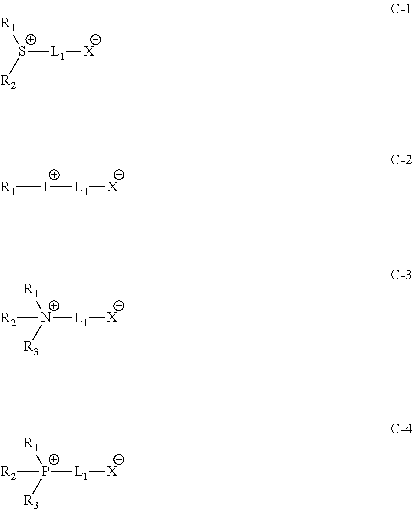

In general Formulas (C-1) to (C-4), R₁, R₂, and R₃ each independently represents a substituent with 1 or more carbon atoms. L₁ represents a divalent linking group or a single bond which links a cation site and an anion site. —X⁻ represents an anion site which is selected from —COO⁻, —SO₃⁻, —SO₂⁻, and —N—R₄. R₄ represents a monovalent substituent having a group selected from a carbonyl group: —C(═O)—, a sulfonyl group: —S(═O)₂—, and a sulfinyl group: —S(═O)— in a linking site with an adjacent N atom. Two groups selected from R₁, R₂, and L₁ in general Formula (C-1) may be linked to form a ring structure. R₁ and L₁ in general Formula (C-2) may be linked to form a ring structure. Two or more groups selected from R₁, R₂, R₃, and L₁ in general Formula (C-3) may be linked to form a ring structure. Two or more groups selected from R₁, R₂, R₃, and L₁ in general Formula (C-4) may be linked to form a ring structure.

(3) The pattern forming method according to (1) or (2), in which the content of the organic solvent in the developer which includes the organic solvent is 90 mass % to 100 mass % with respect to a total amount of the developer.

(4) The pattern forming method according to any one of (1) to (3), in which the developer contains at least one type of an organic solvent which is selected from the group consisting of a ketone-based solvent, an ester-based solvent, an alcohol-based solvent, an amide-based solvent, and an ether-based solvent.

(5) The pattern forming method according to any one of (1) to (4), in which the actinic ray-sensitive or radiation-sensitive resin composition further contains a hydrophobic resin (HR) which is different from the resin (A).

(6) The pattern forming method according to any one of (1) to (5), in which the exposure in step (b) is liquid immersion exposure.

(7) An actinic ray-sensitive or radiation-sensitive resin composition which is used for the pattern forming method according to any one of (1) to (6).

(8) A resist film which is formed by the actinic ray-sensitive or radiation-sensitive resin composition according to (7).

(9) A method for manufacturing an electronic device which includes the pattern forming method according to any one of (1) to (6).

(10) An electronic device which is manufactured by the method for manufacturing an electronic device according to (9).

According to the present invention, it is possible to provide a pattern forming method where LWR is small and there are not many development defects and with an excellent pattern profile and CDU, an actinic ray-sensitive or radiation-sensitive resin composition which is used for this pattern forming method, a resist film, a method for manufacturing an electronic device, and an electronic device.

### DESCRIPTION OF THE PREFERRED EMBODIMENTS

Detailed description will be given below of embodiments of the present invention.

In the notation of the groups (atomic groups) in the present specification, notation which does not specify substituted or unsubstituted includes both groups (atomic groups) which do not have a substituent and groups (atomic groups) which have a substituent. For example, “alkyl group” includes not only an alkyl group which does not have a substituent (an unsubstituted alkyl group), but also an alkyl group which has a substituent (a substituted alkyl group).

“Actinic rays” or “radiation” in the present specification has the meaning of, for example, a bright line spectrum of a mercury lamp, far ultraviolet rays which are represented by an excimer laser, extreme ultraviolet rays (EUV light), X-rays, electron beams (EB), and the like. In addition, light in the present invention has the meaning of actinic rays or radiation.

Unless otherwise stated, “exposure” in the present specification includes not only exposure with far ultraviolet rays, extreme ultraviolet rays, X-rays, EUV light, and the like, which are represented by mercury lamps and excimer lasers, but also drawing using particle beams such as electron beams and ion beams.

In the present specification, a “(meth)acryl-based monomer” has the meaning of at least one type of a monomer which has a structure of “CH₂═CH—CO—” or “CH₂═C(CH₃)—CO—”. In the same manner, “(meth)acrylate” and “(meth)acrylic acid” respectively have the meaning of “at least one type of acrylate and methacrylate” and “at least one type of acrylic acid and methacrylic acid”.

A pattern forming method of the present invention includes (a) forming a film using an actinic ray-sensitive or radiation-sensitive resin composition which contains (A) to (C) below, (A) a resin where polarity increases due to an action of acid and solubility decreases with respect to a developer which includes an organic solvent, (B) a compound which generates acid when irradiated with actinic rays or radiation, and (C) a compound which has a cation site and an anion site in the same molecule and where the cation site and the anion site are linked with each other by a covalent bond, (b) exposing the film, and (c) forming a negative tone pattern by developing the exposed film using a developer which includes an organic solvent.

According to the present invention, it is possible to provide a pattern forming method where the LWR is small and there are not many development defects and with an excellent pattern profile and CDU, an actinic ray-sensitive or radiation-sensitive resin composition which is used for this pattern forming method, a resist film, a method for manufacturing an electronic device, and an electronic device.

The reasons therefor are not certain, but, for example, are considered to be as follows.

Due to the compound (C) which contains an actinic ray-sensitive or radiation-sensitive resin composition which is used for the pattern forming method of the present invention having an anion and a cation in the same molecule, the cation section is decomposed during exposure and the molecular weight of the compound (C) described above decreases.

Due to this, it may be considered that, since the solubility with respect to a developer which includes an organic solvent of an exposed section is further decreased and the dissolution contrast is improved as a result, the LWR and the number of development defects of formed patterns are reduced and the pattern profile and CDU are improved.

The pattern forming method of the present invention preferably further includes (d) a cleaning step using a rinsing liquid which includes an organic solvent.

The rinsing liquid preferably contains at least one type of an organic solvent which is selected from the group consisting of a hydrocarbon-based solvent, a ketone-based solvent, an ester-based solvent, an alcohol-based solvent, an amide-based solvent, and an ether-based solvent.

The pattern forming method of the present invention preferably has (e) a heating step after (b) the exposure step.

In addition, the resin (A) is also a resin where polarity increases due to an action of acid and a degree of solubility with respect to an alkali developer increases. Thus, the pattern forming method of the present invention may further have (f) a step of developing using an alkali developer.

The pattern forming method of the present invention is able to carry out (b) the exposure step in plural.

The pattern forming method of the present invention is able to carry out (e) the heating step in plural.

The resist film of the present invention is formed by the actinic ray-sensitive or radiation-sensitive resin composition described above and, for example, is a film which is formed by coating an actinic ray-sensitive or radiation-sensitive resin composition onto a base material.

Description will be given below of an actinic ray-sensitive or radiation-sensitive resin composition which may be used in the present invention.

In addition, the present invention also relates to an actinic ray-sensitive or radiation-sensitive resin composition which will be described below.

The actinic ray-sensitive or radiation-sensitive resin composition of the present invention contains the components shown below.

<(A) A Resin Where Polarity Increases Due to an Action of Acid and Solubility Decreases With Respect to an Organic Solvent (Referred to Below as a Resin (A))>

The resin (A) is a resin where polarity increases due to an action of acid and solubility decreases with respect to an organic solvent. With regard to the resin (A), a part or all of hydrophilic groups in a molecule are protected by a protective group which may leave due to contact with acid, and when the resin (A) comes into contact with acid, the protective group leaves and the solubility of the resin (A) in an organic solvent decreases. The hydrophilic group which is protected by the protective group is referred to below as an “acid-unstable group”. Examples of the hydrophilic group include a hydroxy group or a carboxy group and a carboxy group is more preferable.

It is possible to manufacture the resin (A) by polymerizing monomers which have an acid-unstable group (referred to below as “monomers (a1)”). At the time of polymerization, only one type of the monomers (a1) may be used or two or more types may be used together.

<Monomer (a1)>

The monomer (a1) has an acid-unstable group. Examples of acid-unstable groups in a case where a hydrophilic group is a carboxy group include groups where a hydrogen atom of the carboxy group is substituted with an organic residue and an atom of the organic residue which is bonded with an oxy group is a tertiary carbon atom. Among the acid-unstable groups, a preferable acid-unstable group is, for example, represented by Formula (1) below (referred to below as an “acid-unstable group (1)”).

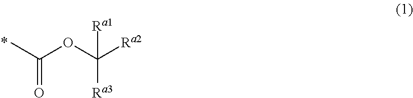

[In Formula (1), R^{a1}, R^{a2}, and R^{a3} (notated below as “R^{a1} to R^{a3}” and in the same manner thereafter) each independently represents an aliphatic hydrocarbon group (preferably with 1 to 8 carbon atoms) or an alicyclic hydrocarbon group (preferably with 3 to 20 carbon atoms) or R^{a1} and R^{a2} are bonded with each other to form a ring (preferably 3 to 20 carbon atoms) with a carbon atom with which these are bonded. In a case where the aliphatic hydrocarbon group, the alicyclic hydrocarbon group, or a ring which is formed by R^{a1} and R^{a2} being bonded with each other has a methylene group, the methylene group may be substituted with an oxy group, —S—, or a carbonyl group. * represents an atomic bond.]

Examples of the aliphatic hydrocarbon group of R^{a1} to R^{a3} include alkyl groups such as a methyl group, an ethyl group, a propyl group, a butyl group, a pentyl group, and a hexyl group.

The alicyclic hydrocarbon group of R^{a1} to R^{a3} may be either monocyclic or polycyclic and may be either unsaturated or saturated which does not exhibit an aromatic property.

Examples of monocyclic alicyclic hydrocarbon groups include cycloalkyl groups such as a cyclopentyl group, a cycloheyxl group, a methylcyclohexyl group, a dimethylcyclohexyl group, a cycloheptyl group, and a cyclooctyl group. Examples of polycyclic alicyclic hydrocarbon groups include a decahydronaphthyl group, an adamantyl group, a norbornyl group, and a methylnorbornyl group, as well as groups and the like which will be shown below.

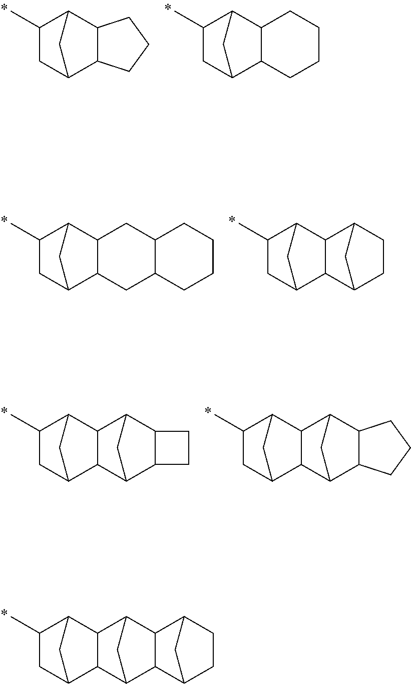

The alicylic hydrocarbon group of R^{a1} to Ra3 is preferably a saturated hydrocarbon group and the number of carbon atoms is preferably in a range of 3 to 16.

In a ring formed by R^{a1} and R^{a2} bonding with each other, examples of a group which is represented by —C(R^{a1})(R^{a2})(R^{a3}) include groups which will be shown below.

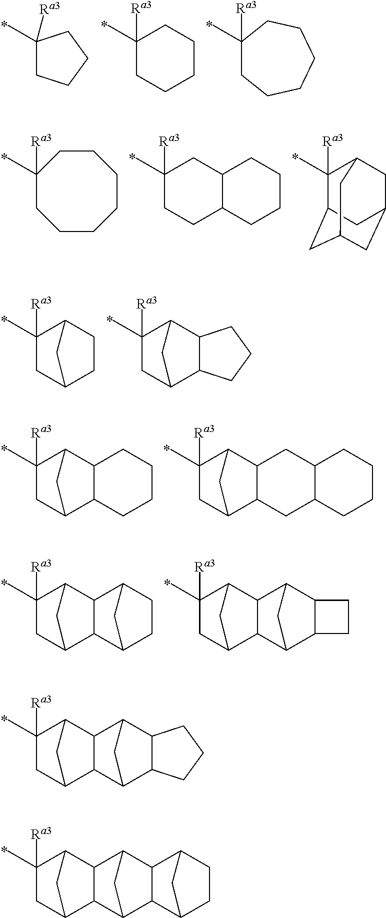

The number of carbon atoms of a ring formed by R^{a1} and R^{a2} bonding with each other is preferably 3 to 12.

Specific examples of the acid-unstable group (1) include 1,1-dialkylalkoxycarbonyl group (in Formula (1), a group where R^{a1} to R^{a3} are all alkyl groups, one out of the alkyl groups is preferably a tert-butoxycarbonyl group), 2-alkyladamantane-2-yloxycarbonyl group (in Formula (1), a group where R^{a1} and R^{a2} are bonded with each other to form an adamantyl ring with a carbon atom with which these are bonded and R^{a3} is an alkyl group), 1-(adamantane-1-yl)-1-alkylalkoxycarbonyl group (in Formula (1), a group where R^{a1} and R^{a2} are alkyl groups and R^{a3} is an adamantyl group), and the like.

On the other hand, examples of acid-unstable groups in a case where a hydrophilic group is a hydroxy group include groups where a hydrogen atom of the hydroxy group is substituted with an organic residue and which includes an acetal structure. Among the acid-unstable groups, a preferable acid-unstable group is, for example, represented by Formula (2) below (referred to below as “acid-unstable group (2)”).

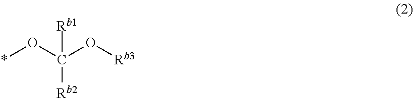

[In Formula (2), R^{b1} and R^{b2} each independently represents a hydrogen atom or a hydrocarbon group (preferably with 1 to 12 carbon atoms) and R^{b3} represents a hydrocarbon group (preferably 1 to 20 carbon atoms) or R^{b2} and R^{b3} are bonded with each other to form a ring (preferably with 3 to 20 carbon atoms) with a carbon atom and an oxygen atom with which each of these is bonded. In a case where a hydrocarbon group or a ring which is formed by R^{b2} and R^{b3} being bonded with each other has a methylene group, the methylene group may be substituted with an oxy group, —S—, or a carbonyl group. * represents an atomic bond.]

Examples of the hydrocarbon group include an aliphatic hydrocarbon group, alicyclic hydrocarbon group, and an aromatic hydrocarbon group.

At least one out of R^{b1} and R^{b2} is preferably a hydrogen atom.

Specific examples of the acid-unstable group (2) include the groups below.

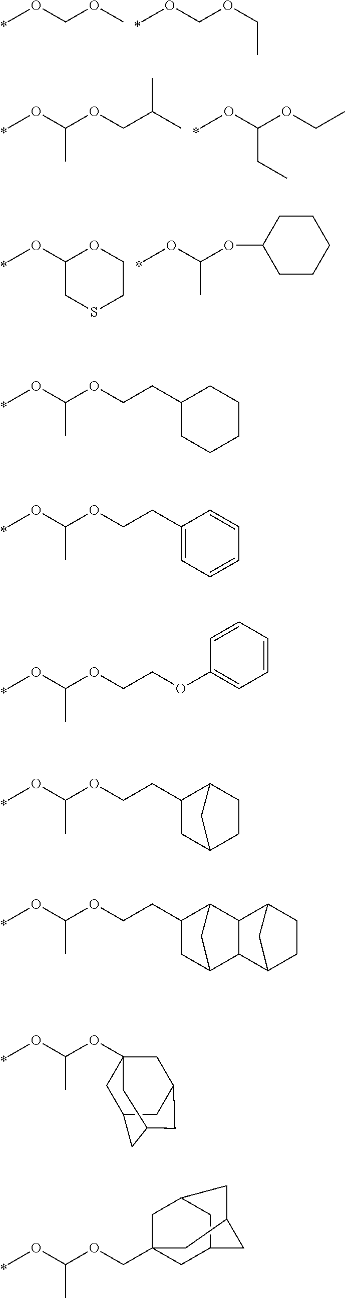

The monomer (a1) which has an acid-unstable group is preferably a monomer which has an acid-unstable group and a carbon-carbon double bond, and more preferably a (meth)acryl-based monomer which has an acid-unstable group.

In particular, the monomer (a1) is preferably a monomer which has an acid-unstable group (1) and/or an acid-unstable group (2) and a carbon-carbon double bond in the molecule, and more preferably a (meth)acryl-based monomer which has the acid-unstable group (1).

Among (meth)acryl-based monomers which have the acid-unstable group (1), a group where the acid-unstable group (1) has an alicyclic hydrocarbon structure with 5 to 20 carbon atoms is preferable. With regard to the resin (A) which is obtained by polymerizing the monomer (a1) which has a group which has a sterically bulky alicyclic hydrocarbon structure, it is possible to manufacture resist patterns with a more favorable resolution when a resist pattern is manufactured using a resist composition of the present invention which includes the resin (A). Here, (meth)acryl represents acryl and/or methacryl.

Among (meth)acryl-based monomers which have the acid-unstable group (1) which includes an alicyclic hydrocarbon structure, monomers which are represented by Formula (a1-1) (referred to below as “monomer (a1-1)”) and monomers which are represented by Formula (a1-2) (referred to below as “monomer (a1-2)”) are preferable. When manufacturing the resins (A), these may be used individually or may be used in a combination of two or more types. The resin (A) preferably contains at least one type which is selected from repeating units which are derived from monomers which are represented by Formula (a1-1) and repeating units which are derived from monomers which are represented by Formula (a1-2). In addition, the resin (A) preferably includes at least one type each of repeating units which are derived from monomers which are represented by Formula (a1-1) and repeating units which are derived from monomers which are represented by Formula (a1-2). In addition, in another aspect, the resin (A) preferably includes two or more types of repeating units which are derived from monomers which are represented by Formula (a1-2). In the resin (A), the ratio of the whole amount of repeating units which are derived from monomers which are represented by Formula (a1-1) and repeating units which are derived from monomers which are represented by Formula (a1-2) with respect to the total of the repeating units is preferably 40 mol % or more, more preferably 45 mol % or more, and even more preferably 50 mol % or more. In particular, the ratio of repeating units which are derived from monomers which are represented by Formula (a1-2) with respect to the total of the repeating units is preferably 30 mol % or more, more preferably 35 mol % or more, and even more preferably 40 mol % or more. It is possible to measure the content ratio of each of the repeating units in the resin (A) by, for example, ¹³C-NMR.

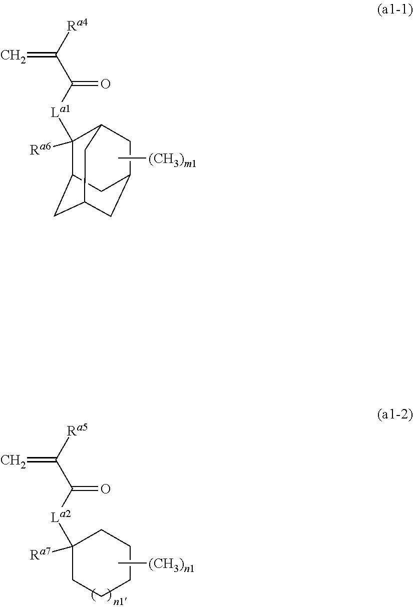

[In Formula (a1-1) and Formula (a1-2), L^{a1} and L^{a2} each independently represents an oxy group or a group which is represented by *—O—(CH₂)ₖ₁—CO—O—. Here, k1 represents an integer of 1 to 7 and * is an atomic bond with a carbonyl group (—CO—).

R^{a4} and R^{a5} each independently represents a hydrogen atom or a methyl group.

R^{a6} and ^{Ra7} each independently represents an aliphatic hydrocarbon group (preferably with 1 to 8 carbon atoms) or an alicyclic hydrocarbon group (preferably 3 to 10 carbon atoms). m1 represents an integer of 0 to 14 and n1 represents an integer of 0 to 10. n1′ represents an integer of 0 to 3.]

Here, the notation “—(CH₃)ₘ₁” in the adamantane ring in Formula (a1-1) has the meaning that hydrogen atoms which bond with the carbon atoms which configure the adamantane ring (that is, hydrogen atoms of a methylene group and/or a methine group) are substituted with methyl groups, and that the number of the methyl groups is m1.

In Formula (a1-1) and Formula (a1-2), L^{a1} and L^{a2} are preferably an oxy group or a group which is represented by *—O—(CH₂)_{f1}—CO—O— (here, f1 represents an integer of 1 to 4), and more preferably an oxy group. f1 is more preferably 1.

R^{a4} and R^{a5} are preferably a methyl group.

An aliphatic hydrocarbon group of R^{a6} or R^{a7} is preferably a group with 6 or less carbon atoms. An alicyclic hydrocarbon group of R^{a6} or R^{a7} preferably has 8 or less carbon atoms, and more preferably 6 or less.

In a case where R^{a6} or R^{a7} is an alicyclic hydrocarbon group, the alicyclic hydrocarbon group may be either monocyclic or polycyclic and either saturated or unsaturated; however, it is preferably a saturated hydrocarbon group.

m1 is preferably an integer of 0 to 3, and more preferably 0 or 1.

n1 is preferably an integer of 0 to 3, and more preferably 0 or 1.

n1′ is preferably 0 or 1.

Examples of monomer (a1-1) include the following.

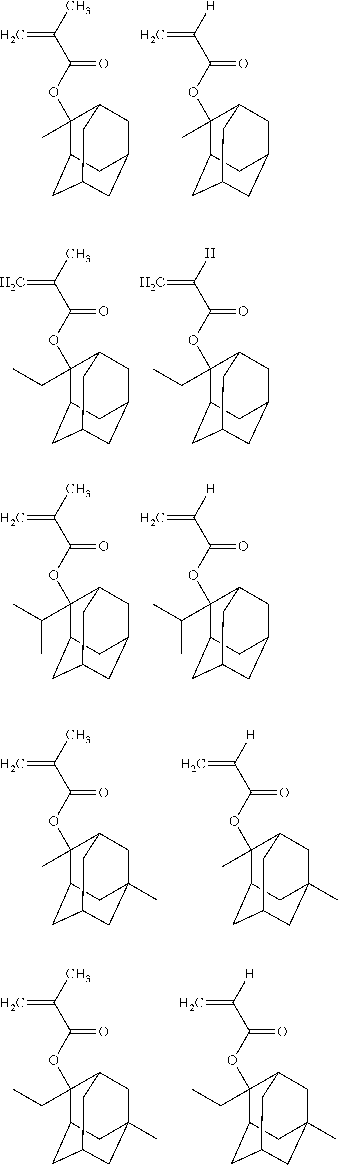

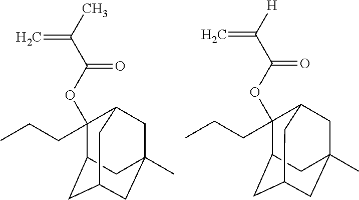

Among these, as the monomer (a1-1), 2-methyladamantane-2-yl(meth)acrylate, 2-ethylamandane-2-yl(meth)acrylate, and 2-isopropyladamantane-2-yl(meth)acrylate are preferable, and 2-methyladamantane-2-ylmethacrylate, 2-ethylamandane-2-ylmethacrylate, and 2-isopropyladamantane-2-ylmethacrylate are more preferable.

Examples of the monomer (a1-2) include the following. Among these, as the monomer (a1-2), 1-ethylcyclohexyl(meth)acrylate is preferable, and 1-ethylcyclohexylmethacrylate is more preferable.

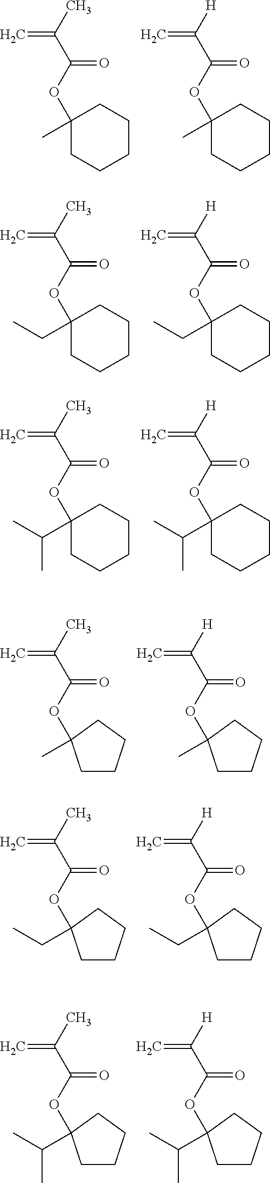

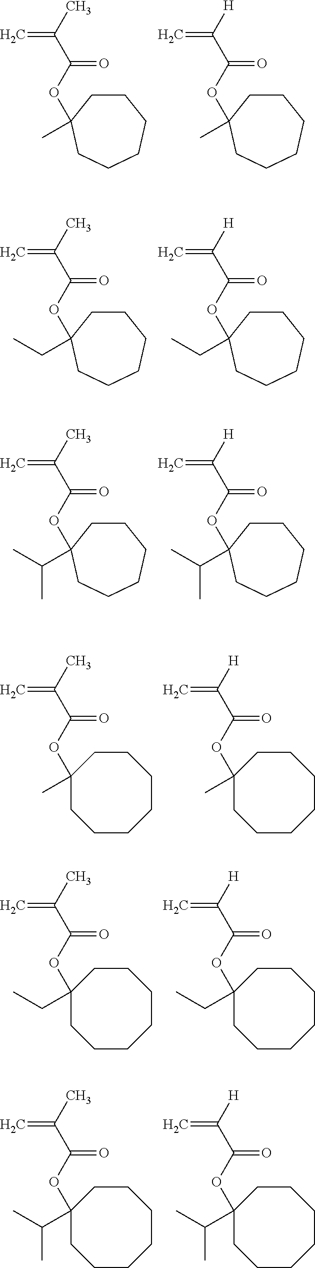

When the total of the structural units of the resin (A) is set to 100 mol %, the content of structural units which are derived from the monomer (a1) (preferably the total of the content of the structural units which are derived from the monomer (a1-1) and/or structural units which are derived from the monomer (a1-2)) is preferably in a range of 10 mol % to 95 mol %, a range of 15 mol % to 90 mol % is more preferable, a range of 20 mol % to 85 mol % is even more preferable, and a range of 50 mol % to 85 mol % is particularly preferable. In order to set the content of the structural units which are derived from the monomer (a1) in this range, the usage amount of the monomer (a1) with respect to the usage amount of all the monomers may be adjusted when manufacturing the resin (A).

It is also possible to use other monomers which have the acid-unstable group (1) and a carbon-carbon double bond in a molecule in addition to the (meth)acryl-based monomer (that is, the monomer (a1-1) and the monomer (a1-2)) for manufacturing the resin (A).

A monomer (a1) which has an acid-unstable group (2) is preferably a (meth)acryl-based monomer, and examples thereof include a monomer which is represented by Formula (a1-5) (referred to below as a “monomer (a1-5)”).

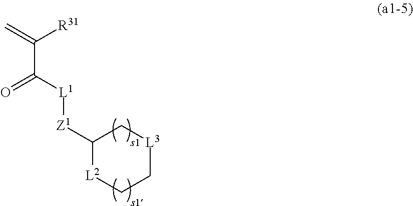

[In Formula (a1-5), R³¹ represents a hydrogen atom, a halogen atom, or an alkyl group (preferably with 1 to 6 carbon atoms) which may have a halogen atom.

L¹ to L³ represent an oxy group and a group which is represented by —S— or *—O—(CH₂)ₖ₁—CO—O—. Here, k1 represents an integer of 1 to 7 and * is an atomic bond with a carbonyl group (—CO—).

Z¹ is a single bond or an alkylene group (preferably with 1 to 6 carbon atoms) and a methylene group which is included in the alkylene group may be substituted with an oxy group or a carbonyl group.

s1 and s1′ each independently represents an integer of 0 to 4.]

In Formula (a1-5), R³¹ is preferably a hydrogen atom or a methyl group.

L¹ is preferably an oxy group.

One of L² and L³ is preferably an oxy group and the other is preferably —S—.

s1 is preferably 1.

s1′ is preferably 0 to 2.

Z¹ is preferably a single bond or —CH₂—CO—O—.

Specific examples of the monomer (a1-5) are as follows.

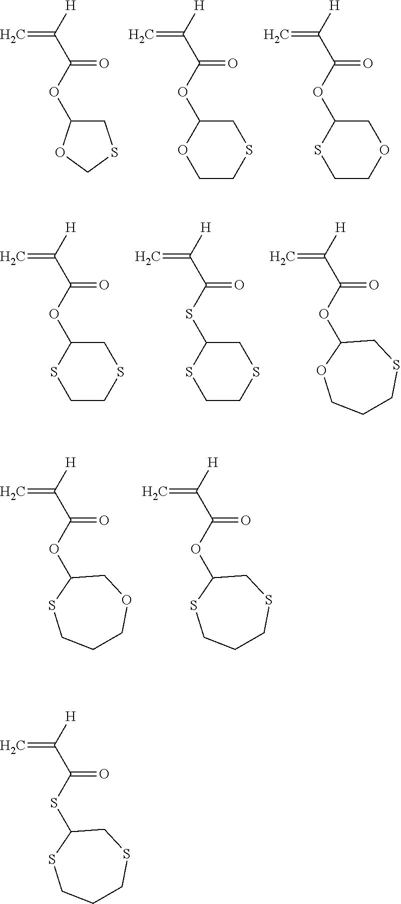

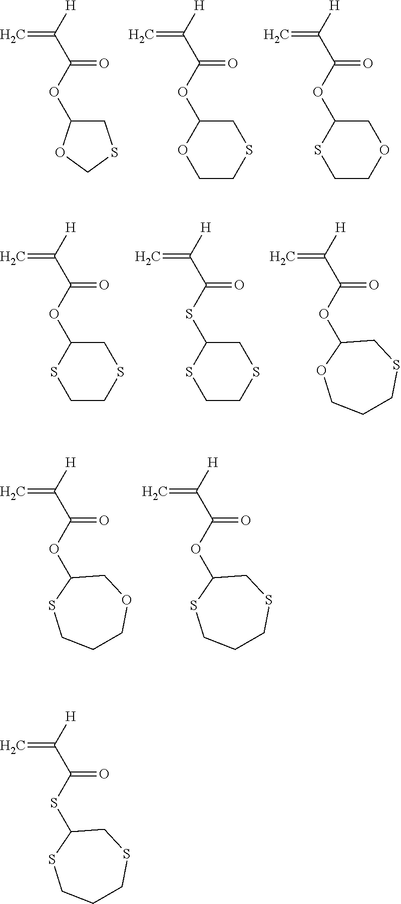

In a case where the resin (A) has structural units which are derived from the monomer (a1-5), the content is preferably in a range of 10 mol % to 95 mol % with respect to the total of the structural units (100 mol %) of the resin (A), a range of 15 mol % to 90 mol % is more preferable, and a range of 20 mol % to 85 mol % is even more preferable.

Acid-Stable Monomer

The resin (A) which is used for a resist composition is preferably a copolymer which is obtained using a monomer which does not have an acid-unstable group (referred to below as an “acid-stable monomer”) in addition to the monomer (a1).

In a case of manufacturing the resin (A) by using acid-stable monomers together, it is possible to determine the usage amount of acid stable monomers using the usage amount of the monomers (a1) as a reference. When represented as [monomer (a1)]/[acid-stable monomer], the ratio of the usage amount of the monomers (a1) and the usage amount of the acid-stable monomers is preferably 10 mol % to 80 mol %/90 mol % to 20 mol %, and more preferably 20 mol % to 60 mol %/80 mol % to 40 mol %. In addition, in a case of using a monomer which has an adamantyl group (in particular, the monomer (a1-1)) for the monomer (a1), the usage amount of the monomers which have an adamantyl group is preferably 15 mol % or more with respect to the total amount (100 mol %) of the usage amount of the monomers (a1). Due to this, there is a tendency for the dry etching resistance of a resist pattern which is obtained from a resist composition which includes the resin (A) to be favorable.

Examples of acid-stable monomers include a monomer which has a hydroxy group or a lactone ring in the molecule. With regard to the resin (A) which has a structural unit which is derived from an acid-stable monomer which has a hydroxy group (referred to below as an “acid-stable monomer (a2)”) and/or an acid-stable monomer which contains a lactone ring (referred to below as an “acid-stable monomer (a3)”), when a resist composition which includes the resin (A) is coated onto a substrate, it is easy for a coating film which is formed on the substrate or a composition layer which is obtained from the coating film to exhibit excellent adhesion to the substrate. In addition, the resist composition is able to produce a resist pattern with favorable resolution.

Acid-Stable Monomer (a2)

In a case of using an acid-stable monomer (a2) to manufacture the resin (A), it is possible to provide a favorable acid-stable monomer (a2) for each type of exposure source when obtaining a resist pattern from a resist composition which includes the resin (A). That is, in a case of using the resist composition of the present invention in high energy ray exposure such as KrF excimer laser exposure (wavelength: 248 nm), electron beams, or EUV light, it is preferable to use an acid-stable monomer (a2-0) which has a phenol hydroxy group [for example, hydroxystyrenes and the like] as an acid-stable monomer (a2) to manufacture the resin (A). In a case of using ArF excimer laser exposure with a short wavelength (wavelength: 193 nm), it is preferable to use an acid-stable monomer which is represented by Formula (a2-1) which will be described below as an acid-stable monomer (a2) to manufacture the resin (A). In this manner, it is possible to select a preferable acid-stable monomer (a2) which is used for manufacturing the resin (A) according to each of the exposure sources when manufacturing a resist pattern; however, with regard to the acid-stable monomer (a2), the resin (A) may be manufactured using only one type of favorable monomer depending on the type of exposure source, the resin (A) may be manufactured using two or more types of favorable monomers depending on the type of exposure source, or the resin (A) may be manufactured using two or more types of favorable monomers and other acid-stable monomers (a2) depending on the type of exposure source.

Examples of the acid-stable monomer (a2) include a styrene-based monomer such as p- or m-hydroxystyrene which is represented by Formula (a2-0) below (referred to below as “acid-stable monomer (a2-0)”). Here, the Formula (a2-0) is shown in a form where a phenol hydroxy group is not appropriately protected by a protective group.

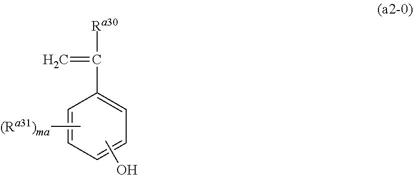

[In Formula (a2-0), R^{a30} represents an alkyl group which may have a halogen atom (preferably with 1 to 6 carbon atoms), a hydrogen atom, or a halogen atom.

R^{a31} represents a halogen atom, a hydroxy group, an alkyl group (preferably with 1 to 6 carbon atoms), an alkoxy group (preferably with 1 to 6 carbon atoms), an acyl group (preferably with 2 to 4 carbon atoms), an acyloxy group (preferably with 2 to 4 carbon atoms), an acryloyl group, or a methacryloyl group.

ma represents an integer of 0 to 4. In a case where ma is an integer of 2 or more, a plurality of R^{a31} are each independent.]

Examples of the halogen atom and the alkyl group with 1 to 6 carbon atoms which may have a halogen atom of R^{a30} include the same examples as the examples in the description of R^{a32} of the monomer (a1-4). Among these, with regard to R^{a30}, an alkyl group with 1 to 4 carbon atoms is preferable, a methyl group or an ethyl group is more preferable, and a methyl group is even more preferable.

As an alkyl group of R^{a31}, an alkyl group with 1 to 4 carbon atoms is preferable, an alkyl group with 1 or 2 carbon atoms is more preferable, and a methyl group is particularly preferable.

Examples of an alkoxy group of R^{a31} include the same examples as in the description of R^{a33} of the monomer (a1-4). Among these, with regard to R^{a31}, an alkoxy group with 1 to 4 carbon atoms is preferable, a methoxy group or an ethoxy group is more preferable, and a methoxy group is even more preferable.

With regard to ma, 0, 1 or 2 is preferable, 0 or 1 is more preferable, and 0 is even more preferable.

In a case of manufacturing the resin (A) which has a structural unit which is derived from the acid-stable monomer (a2-0), it is possible to use a monomer where a phenol hydroxy group in the acid-stable monomer (a2-0) is protected by a protective group. Examples of the protective group include a protective group which leaves due to acid, or the like. Since it is possible to deprotect a phenol hydroxy group which is protected by a protective group, which leaves due to acid, through contact with acid, it is possible to easily form a structural unit which is derived from the acid-stable monomer (a2-0).

However, since the resin (A) has a structural unit (a1) which includes an acid-unstable group as described above, it is preferable to perform polymerization using the acid-stable monomer (a2-0) where a phenol hydroxy group is protected by a protective group which is able to be deprotected using a base and to carry out deprotection through contact with a base so as not to remarkably damage the acid-unstable group of the structural unit (a1) during the deprotection. Examples of protective groups which are able to be deprotected using a base include acetyl groups and the like. Examples of bases include 4-dimethylaminopyridine, triethylamine, and the like.

Examples of the acid-stable monomer (a2-0) include the following monomers. Here, the examples below are also shown in a form where a phenol hydroxy group is not protected by a protective group.

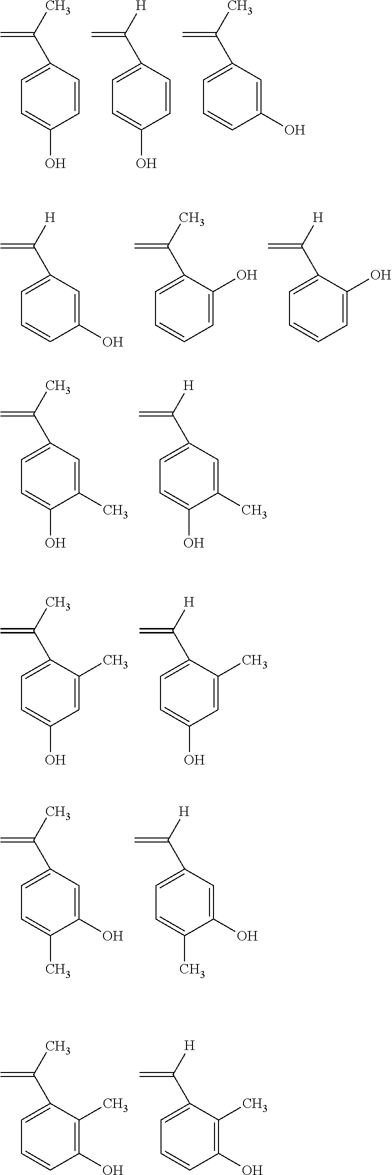

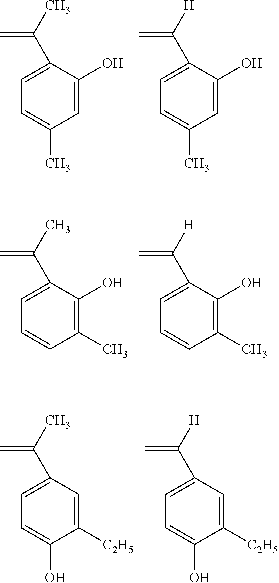

Among these, 4-hydroxystyrene or 4-hydroxy-α-methylstyrene is particularly preferable.

When manufacturing the resin (A) using 4-hydroxystyrene or 4-hydroxy-α-methylstyrene, it is preferable to use 4-hydroxystyrene or 4-hydroxy-α-methylstyrene where a phenol hydroxy group therein is protected by a protective group.

In a case where the resin (A) has a structural unit which is derived from the acid-stable monomer (a2-0), the content thereof is preferably selected from a range of 5 mol % to 95 mol % with respect to the total of the structural units (100 mol %) of the resin (A), a range of 10 mol % to 80 mol % is more preferable, and a range of 15 mol % to 80 mol % is even more preferable.

Examples of an acid-stable monomer (a2-1) include monomers which are represented by Formula (a2-1) below.

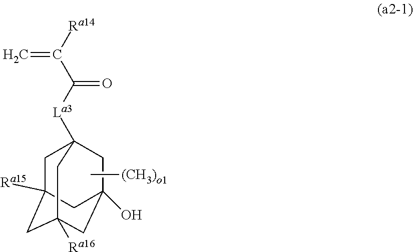

[In Formula (a2-1), L^{a3} represents an oxy group or *—O—(CH₂)ₖ₂—CO—O— and k2 represents an integer of 1 to 7. * represents an atomic bond with —CO—.

R^{a14} represents a hydrogen atom or a methyl group.

R^{a15} and R^{a16} each independently represents a hydrogen atom, a methyl group, or a hydroxy group.

o1 represents an integer of 0 to 10.

In Formula (a2-1), L^{a3} is preferably an oxy group or —O—(CH₂)_{f1}—CO—O— (here, f1 is an integer of 1 to 4), and more preferably an oxy group.

R^{a14} is preferably a methyl group.

R^{a15} is preferably a hydrogen atom.

R^{a16} is preferably a hydrogen atom or a hydroxy group.

o1 is preferably an integer of 0 to 3, and more preferably 0 or 1.]

Examples of the acid-stable monomer (a2-1) include the following. Among these, 3-hydroxyadamantane-1-yl(meth)acrylate, 3,5-dihydroxyadamantane-1-yl(meth)acrylate, and (meth)acrylic acid 1-(3,5-dihydroxyadamantane-1-yloxycarbonyl)methyl are preferable, 3-hydroxyadamantane-1-yl(meth)acrylate and 3,5-dihydroxyadamantane-1-yl(meth)acrylate are more preferable, and 3-hydroxyadamantane-1-ylmethacrylate and 3,5-dihydroxyadamantane-1-ylmethacrylate are even more preferable.

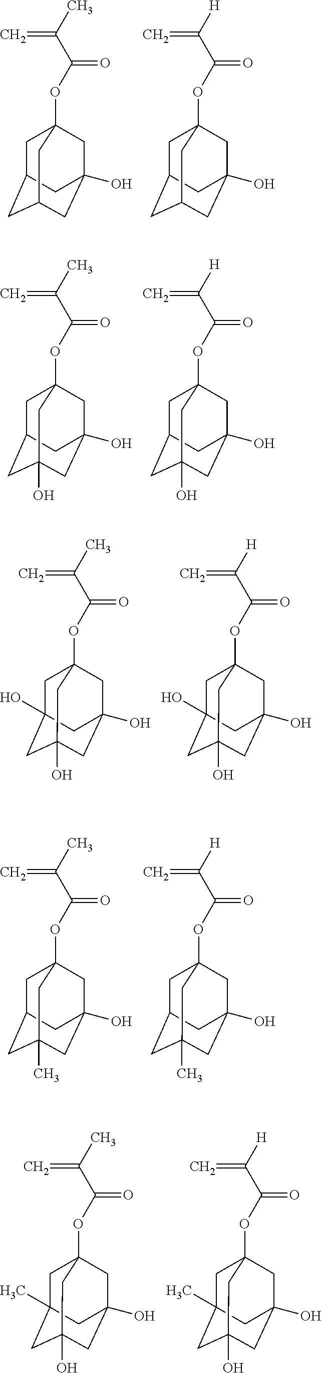

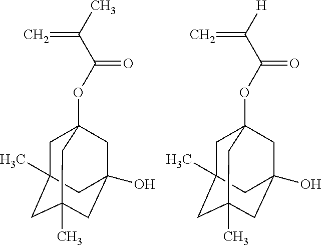 [SMILES: C=C(C)C(=O)OC12CC3(C)CC(C)(CC(O)(C3)C1)C2 ; C=CC(=O)OC12CC3(C)CC(C)(CC(O)(C3)C1)C2]

In a case where the resin (A) has a structural unit which is derived from the acid-stable monomer (a2-1), the content thereof is preferably selected from a range of 3 mol % to 40 mol % with respect to the total of the structural units (100 mol %) of the resin (A), a range of 5 mol % to 35 mol % is more preferable, a range of 5 mol % to 30 mol % is even more preferable, and a range of 5 mol % to 15 mol % is particularly preferable.

Acid-Stable Monomer (a3)

A lactone ring of an acid-stable monomer (a3), for example, may be monocyclic such as a β-propiolactone ring, a γ-butylolactone ring, or a δ-valerolactone ring, or may be a condensed ring of a monocyclic lactone ring and another ring. Among these lactone rings, the γ-butylolactone ring and a condensed ring of the γ-butylolactone ring and another ring are preferable.

The acid-stable monomer (a3) is preferably represented by Formula (a3-1), Formula (a3-2), or Formula (a3-3). In manufacturing the resin (A), only one type out of these may be used, or two or more types may be used together. The resin (A) more preferably includes at least one type of a repeating unit which is derived from a monomer which is represented by Formula (a3-1). In addition, the resin (A) particularly preferably includes at least one type of a repeating unit which is derived from a monomer which is represented by Formula (a3-1) and at least one type of a repeating unit which is derived from a monomer which is represented by Formula (a3-2). Here, in the description below, an acid-stable monomer (a3) which is shown by Formula (a3-1) is referred to as an “acid-stable monomer (a3-1)”, an acid-stable monomer (a3) which is shown by Formula (a3-2) is referred to as an “acid-stable monomer (a3-2)”, and an acid-stable monomer (a3) which is shown by Formula (a3-3) is referred to as an “acid-stable monomer (a3-3)”.

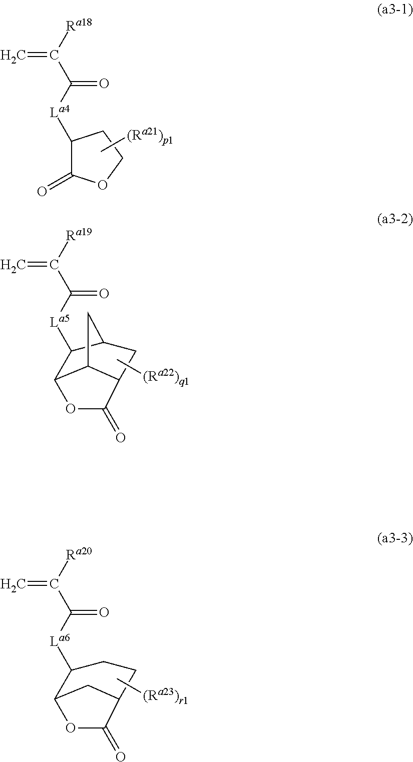

[In Formula (a3-1), Formula (a3-2), and Formula (a3-3), L^{a4}, L^{a5}, and L^{a6} (below, described as “L^{a4} to L^{a6}”) each independently represents —O— or *—O—(CH₂)ₖ₃—CO—O—.

k3 represents an integer of 1 to 7. * represents an atomic bond with —CO—.

R^{a18}, R^{a19}, and R^{a20} (below, described as “R^{a18} to R^{a20}”) each independently represents a hydrogen atom or a methyl group.

R^{a21} represents an aliphatic hydrocarbon group (preferably 1 to 4 carbon atoms).

p1 represents an integer of 0 to 5.

R^{a22} and R^{a23} each independently represents a carboxy group, a cyano group, or an aliphatic hydrocarbon group (preferably with 1 to 4 carbon atoms).

q1 and r1 each independently represents an integer of 0 to 3.

When p1, q1, or r1 is 2 or more, a plurality of R^{a21}, R^{a22}, or R^{a23} may be the same as or different from each other.]

Examples of L^{a4} to L^{a6} in Formula (a3-1) to Formula (a3-3) include the examples described in L^{a3}.

L^{a4} to L^{a6} are preferably each independently —O— or *—O—(CH₂)_{d1}—CO—O— (here, d1 is an integer of 1 to 4), and more preferably —O—.

R^{a18} to R^{a21} are preferably a methyl group.

R^{a22} and R^{a23} are each independently preferably a carboxy group, a cyano group, or a methyl group.

p1, q1, and r1 are each independently preferably an integer of 0 to 2, and more preferably 0 or 1.

Examples of the acid-stable monomer (a3-1) include the following.

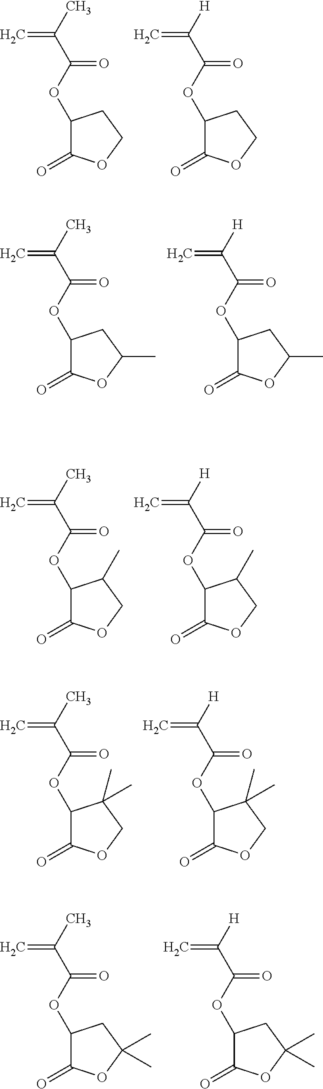

Examples of an acid-stable monomer (a3-2) which has a condensed ring of a γ-butylolactone ring and a norbornane ring include the following.

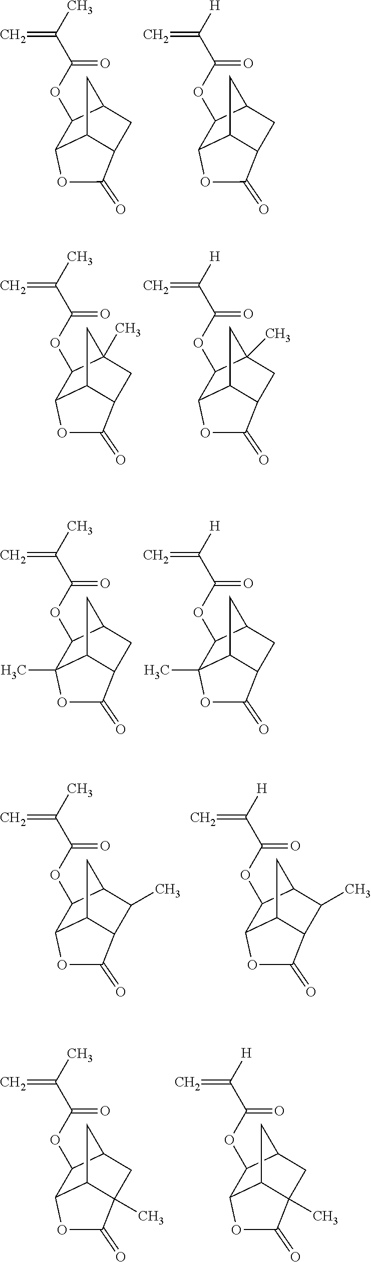

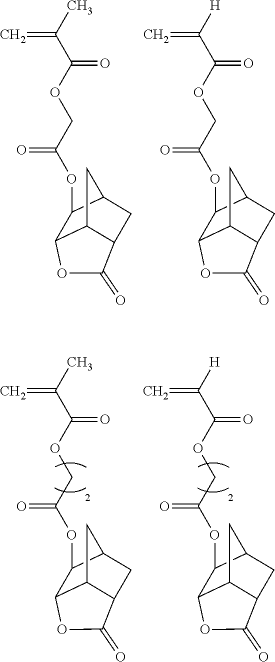

Examples of an acid-stable monomer (a3-3) which has a condensed ring of a γ-butylolactone ring and a cyclohexane ring include the following.

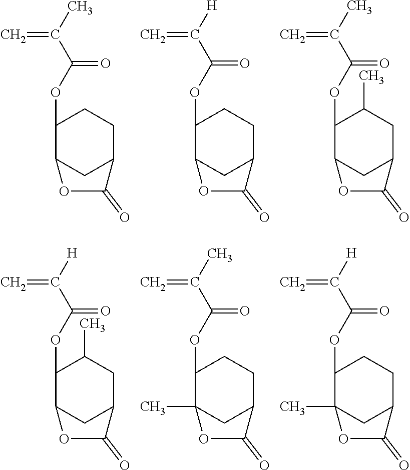 [SMILES: C=C(C)C(=O)OC1CCC2CC1OC2=O ; C=CC(=O)OC1CCC2CC1OC2=O ; C=C(C)C(=O)OC1C(C)CC2CC1OC2=O ; C=CC(=O)OC1C(C)CC2CC1OC2=O ; C=C(C)C(=O)OC1CCC2CC1(C)OC2=O ; C=CC(=O)OC1CCC2CC1(C)OC2=O]

Among acid-stable monomers (a3) which have a lactone ring, methacrylate esters such as (meth)acrylic acid (5-oxo-4-oxatricyclo[4.2.1.0_{3,7}]nonane-2-yl), (meth)acrylic acid tetrahydro-2-oxo-3-furyl, (meth)acrylic acid and 2-(5-oxo-4-oxatricyclo[4.2.1.0_{3,7}]nonane-2-yloxy)-2-oxoethyl are more preferable.

In a case where the resin (A) has a structural unit [a structural unit which is derived from the acid-stable monomer (a3)] which is selected from the group consisting of a structural unit which is derived from the monomer (a3-1), a structural unit which is derived from the monomer (a3-2), and a structural unit which is derived from the monomer (a3-3), the total content thereof is preferably in a range of 5 mol % to 60 mol % with respect to the total of the structural units (100 mol %) of the resin (A), a range of 5 mol % to 50 mol % is more preferable, a range of 10 mol % to 40 mol % is even more preferable, and a range of 15 mol % to 40 mol % is particularly preferable.

In addition, with regard to the content of structural units which are derived from the acid-stable monomer (a3) (preferably, each of the structural unit which is derived from the monomer (a3-1), the structural unit which is derived from the monomer (a3-2), and the structural unit which is derived from the monomer (a3-3)), a range of 5 mol % to 60 mol % is preferable with respect to the total of the structural units (100 mol %) of the resin (A), a range of 10 mol % to 55 mol % is more preferable, and a range of 20 mol % to 50 mol % is even more preferable.

Acid-Stable Monomer (a4)

Furthermore, examples of acid-stable monomers other than the acid-stable monomers (a2) and the acid-stable monomers (a3) (referred to below as “acid-stable monomer (a4)”) include maleic anhydride which is represented by Formula (a4-1), itaconic acid anhydride which is represented by Formula (a4-2), an acid-stable monomer which has a norbornene ring which is represented by Formula (a4-3) (referred to below as “acid-stable monomer (a4-3)”), and the like.

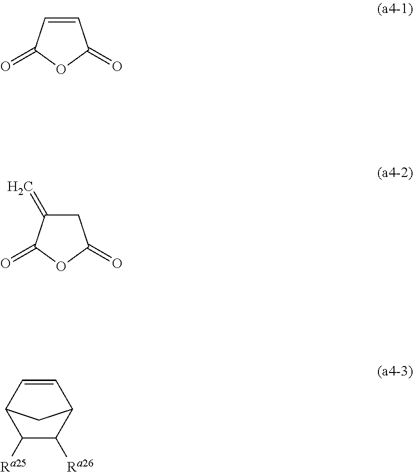

[In Formula (a4-3), R^{a25} and R^{a26} each independently represents a hydrogen atom, an aliphatic hydrocarbon group (preferably with 1 to 3 carbon atoms) which may have a hydroxy group, a cyano group, a carboxy group or —COOR^{a27} [Here, R^{a27} represents an aliphatic hydrocarbon group (preferably with 1 to 18 carbon atoms) or an alicyclic hydrocarbon group (preferably with 3 to 18 carbon atoms), and a methylene group which is included in the aliphatic hydrocarbon group and the alicyclic hydrocarbon group may be substituted with an oxy group or a carbonyl group. However, examples where —COOR^{a27} is an acid-unstable group are excluded (that is, R^{a27} does not include examples where a tertiary carbon atom is bonded with —O—).] or R^{a25} and R^{a26} are bonded with each other to form —CO—O—CO—.]

In R^{a25} and R^{a26} of the monomer (a4-3), examples of aliphatic hydrocarbon groups which may have a hydroxy group include a methyl group, an ethyl group, a propyl group, a hydroxymethyl group, 2-hydroxyethyl group, and the like.

An aliphatic hydrocarbon group of R^{a27} is preferably a group with 1 to 8 carbon atoms, and more preferably with 1 to 6 carbon atoms. An alicyclic hydrocarbon group is preferably a group with 4 to 18 carbon atoms, and more preferably with 4 to 12 carbon atoms. Examples of R^{a27} include a methyl group, an ethyl group, a propyl group, a 2-oxo-oxolane-3-yl group, a 2-oxo-oxolane-4-yl group, and the like.

Examples of an acid-stable monomer (a4-3) which has a norbornene ring include 2-norbornene, 2-hydroxy-5-norbornene, 5-norbornene-2-carbonic acid, 5-norbornene-2-carbonic acid methyl, 5-norbornene-2-carbonic acid 2-hydroxy-1-ethyl, 5-norbornene-2-methanol, 5-norbornene-2,3-dicarbonic acid anhydride, and the like.

In a case where the resin (A) has a structural unit [a structural unit which is derived from the acid-stable monomer (a4)] which is selected from the group consisting of a structural unit which is derived from maleic anhydride which is represented by Formula (a4-1), a structural unit which is derived from itaconic acid anhydride which is represented by Formula (a4-2), and a structural unit which is derived from the monomer (a4-3), the total content thereof is preferably in a range of 2 mol % to 40 mol % with respect to the total of the structural units (100 mol %) of the resin (A), a range of 3 mol % to 30 mol % is more preferable, and a range of 5 mol % to 20 mol % is even more preferable.

In addition, examples of the acid-stable monomer (a4) include an acid-stable monomer which has a sultone ring which is represented by Formula (a4-4) (referred to below as an “acid-stable monomer (a4-4)”) or the like.

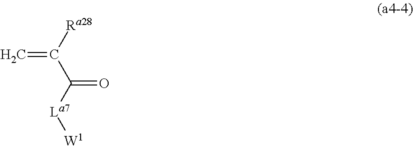

[In Formula (a4-4), L^{a7} represents —O— or *—O—(CH₂)ₖ₂—CO—O— and k2 represents an integer of 1 to 7. * represents an atomic bond with —CO—.

R^{a28} represents a hydrogen atom or a methyl group.

W¹ represents a residue which includes a sultone ring which may have a substituent.]

Examples of the sultone ring include the examples shown below. Examples of the residue which includes a sultone ring include a residue where one of hydrogen atoms in the sultone ring is substituted with an atomic bond with L^{a7}.

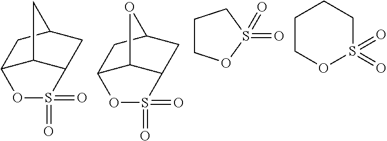

A residue which includes a sultone ring which may have a substituent is a residue where hydrogen atoms other than the hydrogen atom which is substituted with an atomic bond with L^{a7} are further substituted with a substituent, and examples of the substituent include a hydroxy group, a cyano group, an alkyl group with 1 to 6 carbon atoms, a fluorinated alkyl group with 1 to 6 carbon atoms, a hydroxyalkyl group with 1 to 6 carbon atoms, an alkoxy group with 1 to 6 carbon atoms, an alkoxycarbonyl group with 1 to 7 carbon atoms, an acyl group with 1 to 7 carbon atoms, an acyloxy group with 1 to 8 carbon atoms, and the like.

Examples of fluorinated alkyl groups include a difluoromethyl group, a trifluoromethyl group, a 1,1-difluoroethyl group, a 2,2-difluoroethyl group, a 2,2,2-trifluoroethyl group, a perfluoroethyl group, a 1,1,2,2-tetrafluoropropyl group, a 1,1,2,2,3,3-hexafluoropropyl group, a perfluoroethylmethyl group, a 1-(trifluoromethyl)-1,2,2,2-tetrafluoroethyl group, a perfluoropropyl group, a 1,1,2,2-tetrafluorobutyl group, a 1,1,2,2,3,3-hexafluorobutyl group, a 1,1,2,2,3,3,4,4-octafluorobutyl group, a perfluorobutyl group, a 1,1-bis(trifluoro)methyl-2-2-2-trifluoroethyl group, a 2-(perfluoropropyl)ethyl group, a 1,1,2,2,3,3,4,4-octafluoropentyl group, a perfluoropentyl group, a 1,1,2,2,3,3,4,4,5,5-decafluoropentyl group, a 1,1-bis(trifluoromethyl)-2,2,3,3,3-pentafluoropropyl group, a perfluoropentyl group, a 2-(perfluorobutyl)ethyl group, a 1,1,2,2,3,3,4,4,5,5-decafluorohexyl group, a 1,1,2,2,3,3,4,4,5,5,6,6-dodecafluorohexyl group, a perfluoropentylmethyl group, and a perfluorohexyl group. Among these, the number of carbon atoms is preferably 1 to 4, and a trifluoromethyl group, a perfluoroethyl group, and a perfluoropropyl group are more preferable, and a trifluoromethyl group is particularly preferable.

Examples of a hydroxyalkyl group include a hydroxymethyl group, a 2-hydroxyethyl group, and the like.

Specific examples of the acid-stable monomer (a4-4) will be shown below.

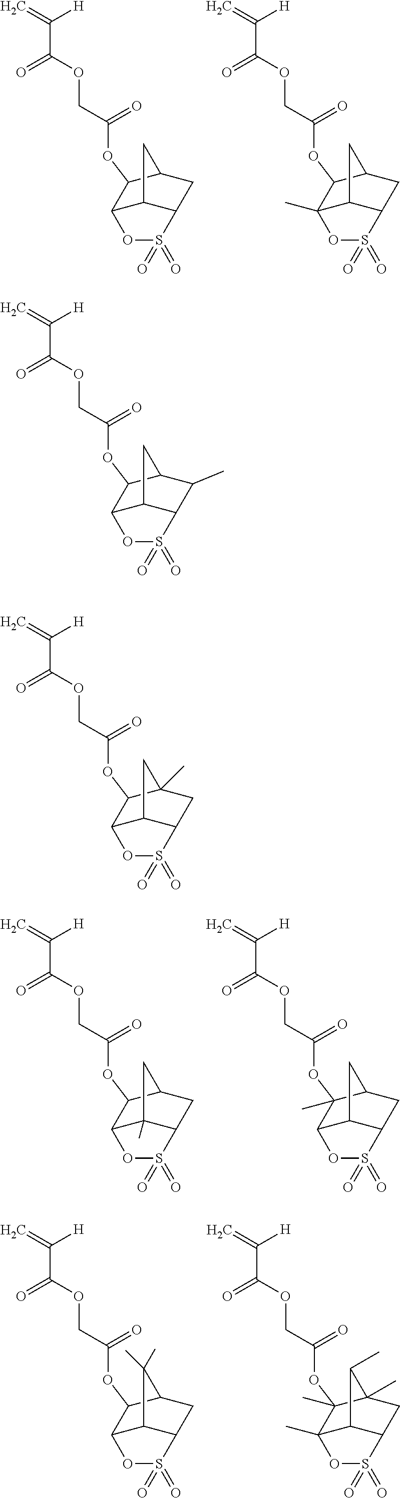

In a case where the resin (A) has a structural unit which is derived from the acid-stable monomer (a4-4), the content thereof is preferably 2 mol % to 40 mol % with respect to the total (100%) of the structural units of the resin (A), a range of 3 mol % to 35 mol % is more preferable, and a range of 5 mol % to 30 mol % is even more preferable.

A preferable resin (A) is a copolymer which is obtained by polymerizing a monomer (a1), an acid-stable monomer (a2), and/or an acid-stable monomer (a3). In the preferable copolymers, it is preferable to use at least one type of the monomer (a1-1) and the monomer (a1-2) described above as the monomer (a1), and it is more preferable to use the monomer (a1-1). An acid-stable monomer (a2-1) is preferable as the acid-stable monomer (a2), at least one type of the acid-stable monomer (a3-1) and the acid-stable monomer (a3-2) is preferable as the acid-stable monomer (a3), and it is more preferable to use both the acid-stable monomer (a3-1) and the acid-stable monomer (a3-2).

It is possible to manufacture the resin (A) by a polymerization method known in the art (for example, a radical polymerization method) using the monomer (a1) and as necessary, an acid-stable monomer which is selected from the group consisting of the acid-stable monomer (a2), the acid-stable monomer (a3), and the acid-stable monomer (a4), once the usage amounts thereof are adjusted such that the content thereof is favorable with respect to the total of the structural units of the resin (A) as described above.

The weight average molecular weight of the resin (A) is preferably 2,500 or more, more preferably 3,000 or more, and even more preferably 4,000 or more. The weight average molecular weight is preferably 50,000 or less, 30,000 or less is more preferable, and 10,000 or less is even more preferable. Here, the weight average molecular weight here is obtained as a standard polystyrene reference conversion value using gel permeation chromatography analysis. In the present invention, it is possible to obtain the weight average molecular weight (Mw) of the resin (A) using, for example, an HLC-8120 (manufactured by Tosoh corporation), using TSK gel Multipore HXL-M (manufactured by Tosoh corporation, 7.8 mm ID×30.0 cm) as the columns, and using tetrahydrofuran (THF) as an eluent.

Regarding the resin (A) of the present invention, one type may be used or a plurality of types may be used. In the present invention, the content ratio of the resin (A) in the entire actinic ray-sensitive or radiation-sensitive resin composition (the total amount in a case of using a plurality of types) is preferably 30 mass % to 99 mass % of the total solid content of the actinic ray-sensitive or radiation-sensitive resin composition, and more preferably 55 mass % to 95 mass %.

### (B) A Compound Which Generates Acid When Irradiated With Actinic Rays or Radiation (Referred to Below as Acid Generator (B))

It is possible to use a non-ion-based acid generator, an ion-based acid generator, or a combination thereof as an acid generator (B). Examples of non-ion-based acid generators include organic halogenides, sulfonate esters (for example, 2-nitrobenzyl ester, aromatic sulfonate, oxime sulfonate, N-sulfonyl oxyimide, sulfonyl oxyketone, and diazonaphthoquinone 4-sulfonate), sulfones (for example, disulfone, ketosulfone, and sulfonyl diazomethane), and the like. Examples of ion-based acid generators include onium salts which include onium cations (for example, diazonium salt, phosphonium salt, sulfonium salt, and iodonium salt), and the like. Examples of anions of the onium salt include sulfonic acid anions, sulfonyl imide anions, sulfonyl methide anions, and the like.

As the acid generator (B), not only may the acid generator which is used in the technical field of the present invention (particularly a photo-acid generator) be used, but compounds known in the art which generate acid through radiation (light) such as photo-cationic polymerization photoinitiators, light decoloring agents or light discoloring agents for pigments, or mixtures thereof may also be used. For example, compounds which generate acid through radiation as described in JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), U.S. Pat. No. 3,779,778A, U.S. Pat. No. 3,849,137A, DE3914407A, EP126712A, and the like may be used as the acid generator (B).

As the acid generator (B), a fluorine-containing acid generator which has fluorine atoms is preferable, and the acid generator (B) which is represented by the following Formula (B1) (referred to below as “acid generator (B1)”) is particularly preferable. With regard to a resist composition which includes the acid generator (B1) and a compound (I), there is an advantage in that not only is it possible to manufacture a resist pattern with favorable LER, but it is also possible to manufacture a resist pattern with favorable focus margin (DOF). Here, in description below, in the acid generators (B1), there are cases where Z+ which has a positive charge is referred to as an “organic cation” and Z+ which has a negative charge by removing the organic cation is referred to as a “sulfonic acid anion”.

The acid generator (B) may be in the form of a low molecular compound or may be in the form of being assembled in a part of a polymer. In addition, a form of a low molecular compound and a form of being assembled in a part of a polymer may be used together.

In a case where the acid generator (B) is in the form of a low molecular compound, a molecular weight is preferably 3000 or less, more preferably 2000 or less, and even more preferably 1000 or less.

In a case where the acid generator (B) is in the form of being assembled in a part of a polymer, the acid generator (B) may be assembled in a part of the acid decomposable resin described above, or may be assembled in a resin which is different from an acid decomposable resin.

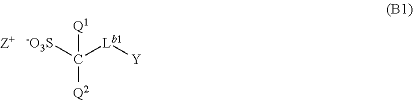

[In Formula (B1), Q¹ and Q² each independently represents a fluorine atom or a perfluoroalkyl group (preferably with 1 to 6 carbon atoms).

L^{b1} represents a single bond or a divalent saturated hydrocarbon group (preferably 1 to 17 carbon atoms) and, in a case where the divalent saturated hydrocarbon group has a methylene group, the methylene group may be substituted with an oxy group or a carbonyl group.

Y represents an aliphatic hydrocarbon group (with 1 to 18 carbon atoms) which may have a substituent or an alicyclic hydrocarbon group (preferably with 3 to 18 carbon atoms) which may have a substituent and, in a case where the aliphatic hydrocarbon group and the alicyclic hydrocarbon group include a methylene group, the methylene group may be substituted with an oxy group, —SO₂—, or a carbonyl group.

Z+ represents an organic cation.]

Examples of a perfluoroalkyl group of Q¹ and Q² include a trifluoromethyl group, a perfluoroethyl group, a perfluoropropyl group, a perfluoroisopropyl group, a perfluorobutyl group, a perfluoro sec-butyl group, a perfluoro tert-butyl group, a perfluoropentyl group, a perfluorohexyl group, and the like.

Q¹ and Q² are preferably each independently a trifluoromethyl group or a fluorine atom, and both Q¹ and Q² are more preferably fluorine atoms. By using the acid generator (B1) where both Q¹ and Q² are fluorine atoms for a resist composition which includes the compound (I), it is possible to manufacture a resist pattern with a wider focus margin.

Examples of the divalent saturated hydrocarbon group in L^{b1} include a linear alkanediyl group, a branched alkanediyl group, a monocyclic or polycyclic divalent alicyclic hydrocarbon group, and two or more types out of these groups may be combined. Examples thereof include linear alkanediyl groups such as a methylene group, an ethylene group, a propane-1,3-diyl group, a propane-1,2-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecan-1,12-diyl group, a tridecane-1,13-diyl group, a tetradecane-1,14-diyl group, a pentadecan-1,15-diyl group, a hexadecan-1,16-diyl group, a heptadecane-1,17-diyl group, an ethane-1,1-diyl group, a propane-1,1-diyl group, and a propane-2,2-diyl group; branched alkanediyl groups which have a side chain which is an alkyl group (in particular, an alkyl group with 1 to 4 carbon atoms such as a methyl group, an ethyl group, a propyl group, an isopropyl group, a butyl group, a sec-butyl group, and a tert-butyl group) in a linear alkanediyl group, for example, a butane-1,3-diyl group, 2-methylpropane-1,3-diyl group, a 2-methylpropane-1,2-diyl group, a pentane-1,4-diyl group, and a 2-methylbutane-1,4-diyl group; monocyclic divalent alicyclic hydrocarbon groups which are cycloalkanediyl groups such as a cyclobutane-1,3-diyl group, a 1,3-cyclopentane-1,3-diyl group, a cyclohexane-1,4-diyl group, and a cyclooctane-1,5-diyl group; polycyclic divalent alicyclic hydrocarbon groups such as a norbornane-1,4-diyl group, a norbornane-2,5-diyl group, a 1,5-adamantane-1,5-diyl group, and an adamantane-2,6-diyl group; and the like.

Examples where a methylene group which is included in the divalent saturated hydrocarbon group in L^{b1} is substituted with an oxy group or a carbonyl group include groups which are shown by any of Formula (b1-1) to Formula (b1-6) below. L^{b1} is preferably a group which is shown by any of Formula (b1-1) to Formula (b1-4) below, and more preferably a group which is shown by Formula (b1-1) or a group which is shown by Formula (b1-2). Here, in the description, the left and right parts of Formula (b1-1) to Formula (b1-6) match Formula (B1), and an atomic bond * on the left side is bonded with C(Q¹)(Q²) and an atomic bond * on the right side is bonded with Y. The same applies to specific examples of Formula (b1-1) to Formula (b1-6) below.

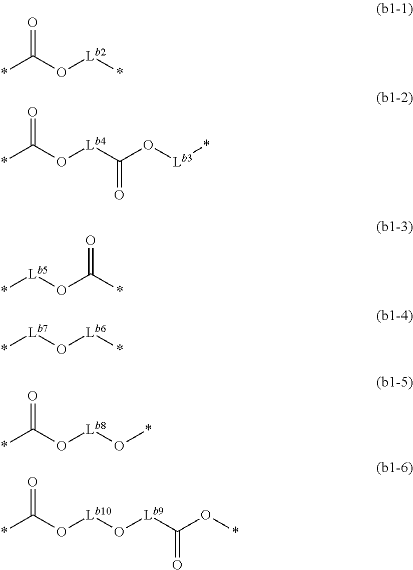

[In Formula (b1-1) to Formula (b1-6), L^{b2} represents a single bond or a divalent saturated hydrocarbon group (preferably with 1 to 15 carbon atoms).

Lb³ represents a single bond or a divalent saturated hydrocarbon group (preferably with 1 to 12 carbon atoms).

Lb⁴ represents a divalent saturated hydrocarbon group (preferably with 1 to 13 carbon atoms). However, the upper limit of the total number of carbon atoms of L^{b3} and L^{b4} is 13.

Lb⁵ represents a divalent saturated hydrocarbon group (preferably with 1 to 15 carbon atoms).

L^{b6} and L^{b7} each independently represents a divalent saturated hydrocarbon group (preferably with 1 to 15 carbon atoms). However, the upper limit of the total number of carbon atoms of L^{b6} and L^{b7} is 16.

L^{b8} represents a divalent saturated hydrocarbon group (preferably with 1 to 14 carbon atoms). L^{b9} and L¹⁰ each independently represents a divalent saturated hydrocarbon group (preferably with 1 to 11 carbon atoms).

However, the upper limit of the total number of carbon atoms of L^{b9} and L¹⁰ is 12.]

Among these, an acid generator (B1) which has a divalent group which is represented by Formula (b1-1) as L^{b1} is preferable, and an acid generator (B1) which has a divalent group which is represented by Formula (b1-1) where L^{b2} is a single bond or a methylene group is more preferable.

Examples of the divalent group which is represented by Formula (b1-1) include the following.

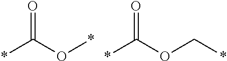

Examples of the divalent group which is represented by Formula (b1-2) include the following.

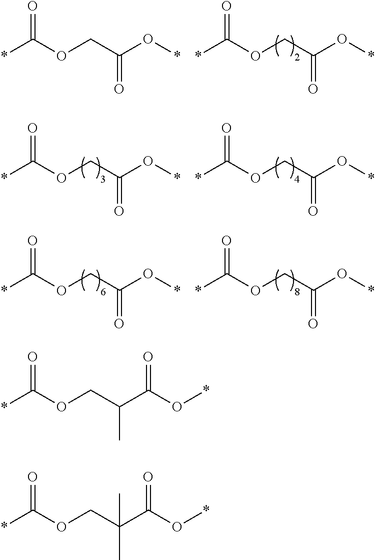

Examples of the divalent group which is represented by Formula (b1-3) include the following.

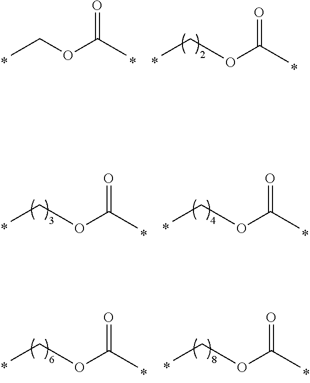

Examples of the divalent group which is represented by Formula (b1-4) include *—CH₂—O—CH₂—*.

Examples of the divalent group which is represented by Formula (b1-5) include the following.

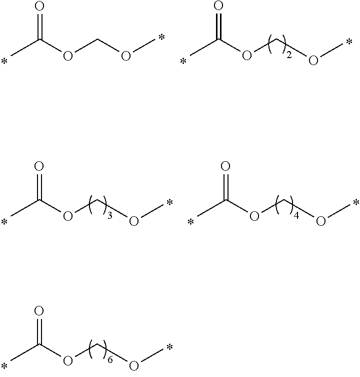

Examples of the divalent group which is represented by Formula (b1-6) include the following.

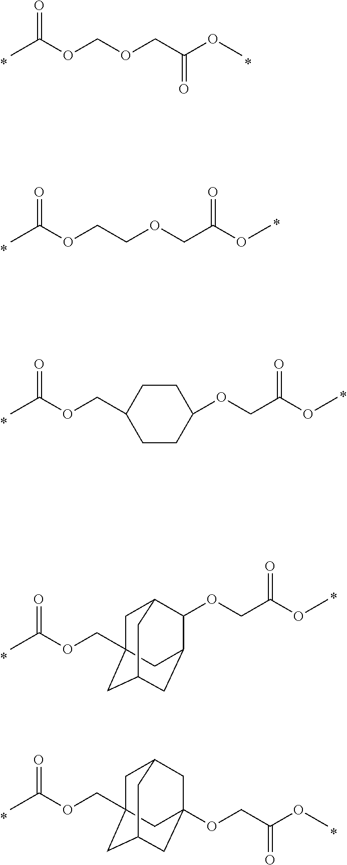

The divalent saturated hydrocarbon group of L^{b1} may have a substituent. Examples of the substituent include a halogen atom, a hydroxy group, a carboxy group, an aromatic hydrocarbon group with 6 to 18 carbon atoms, an aralkyl group with 7 to 21 carbon atoms, an acyl group with 2 to 4 carbon atoms, a glycidyloxy group, and the like.

Examples of aralkyl groups include a benzyl group, a phenethyl group, a phenylpropyl group, a trithyl group, a naphthylmethyl group, a naphthylethyl group, and the like.

As an aliphatic hydrocarbon group of Y in Formula (B1), an alkyl group is preferable, and an alkyl group with 1 to 6 carbon atoms is more preferable. In addition, with regard to the aliphatic hydrocarbon group of Y, a cycloalkyl group is preferable, and a cycloalkyl group with 3 to 12 carbon atoms is more preferable. The cycloalkyl group may be monocyclic or polycyclic. In addition, the cycloalkyl group includes not only cycloalkyl groups which have carbon atoms only as the atoms which configure a ring, but also groups formed by an alkyl group being bonded with carbon atoms which are atoms which configure a ring.

An aliphatic hydrocarbon group and an alicyclic hydrocarbon group of Y may optionally have a substituent. Here, an “aliphatic hydrocarbon group which has a substituent” has the meaning of a group where a hydrogen atom which is included in the aliphatic hydrocarbon group is substituted with a substituent. On the other hand, an “alicyclic hydrocarbon group which has a substituent” has the meaning of a group where a hydrogen atom which is included in the alicyclic hydrocarbon group is substituted with a substituent. Examples of the substituents include a halogen atom (here, excluding a fluorine atom), a hydroxy group, an alkoxy group with 1 to 12 carbon atoms, an aromatic hydrocarbon group with 6 to 18 carbon atoms, an aralkyl group with 7 to 21 carbon atoms, an acyl group with 2 to 4 carbon atoms, a glycidyloxy group, a group which is represented by —(CH₂)ⱼ₂—O—CO—R^{b1} (in the formula, R^{b1} represents an aliphatic hydrocarbon group with 1 to 16 carbon atoms, an alicyclic hydrocarbon group with 3 to 16 carbon atoms, and an aromatic hydrocarbon group with 6 to 18 carbon atoms, and j2 represents an integer of 0 to 4.), and the like.

An alicyclic hydrocarbon group, an aromatic hydrocarbon group, and an aralkyl group which are substituents may have, for example, an alkyl group, a halogen atom, or a hydroxy group. In addition, an optional substituent of an aliphatic hydrocarbon group may be an alicyclic hydrocarbon group with 3 to 16 carbon atoms.

A methylene group which is included in an aliphatic hydrocarbon group or an alicyclic hydrocarbon group of Y may be substituted with an oxy group, a sulfonyl group (—SO₂—), or a carbonyl group. Examples of groups where a methylene group which is included in an alicyclic hydrocarbon group is substituted with an oxy group, a sulfonyl group, or a carbonyl group include a cyclic ether group (a group where one or two methylene groups which are included in the alicyclic hydrocarbon group are substituted with oxy groups), a cyclic ketone group (a group where one or two methylene groups which are included in the alicyclic hydrocarbon group are substituted with carbonyl groups), a sultone ring group (a group where two adjacent methylene groups out of the methylene groups which are included in the alicyclic hydrocarbon group are respectively substituted with an oxy group and a sulfonyl group), a lactone ring group (a group where two adjacent methylene groups out of the methylene groups which are included in the alicyclic hydrocarbon group are respectively substituted with an oxy group and a carbonyl group), and the like.

Examples of an alicyclic hydrocarbon group of Y include a group which is represented by any of Formula (Y1) to Formula (Y26) below. Out of these, examples of a group which is substituted with a divalent group where 1 to 3 of methylene groups which are included in the alicyclic hydrocarbon group are each selected from the group consisting of —O—, —SO₂—, and —CO— include groups which are represented by Formula (Y12) to Formula (Y26). Here, in the groups which are represented by Formula (Y1) to Formula (Y26), * represents an atomic bond which is bonded with L^{b1}.

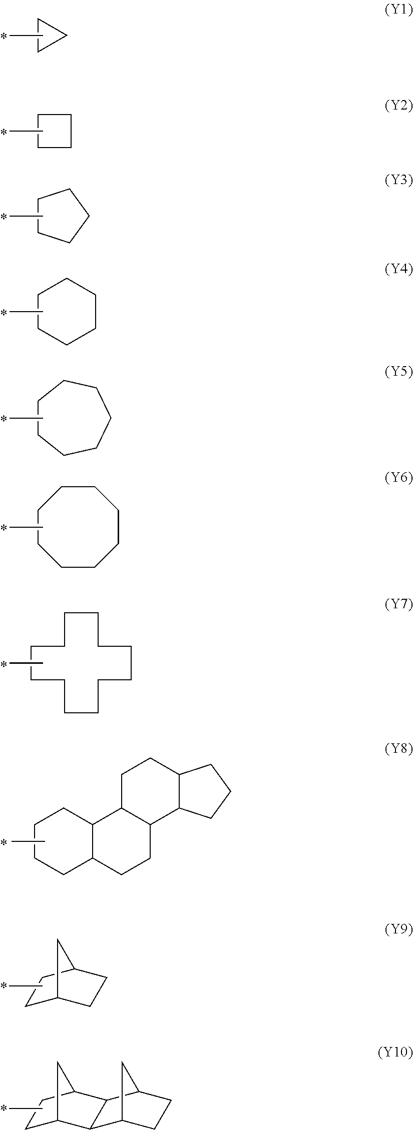

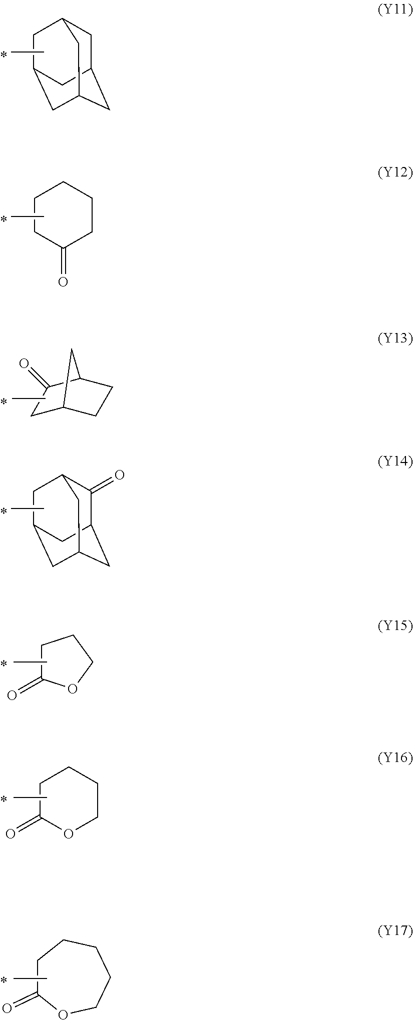

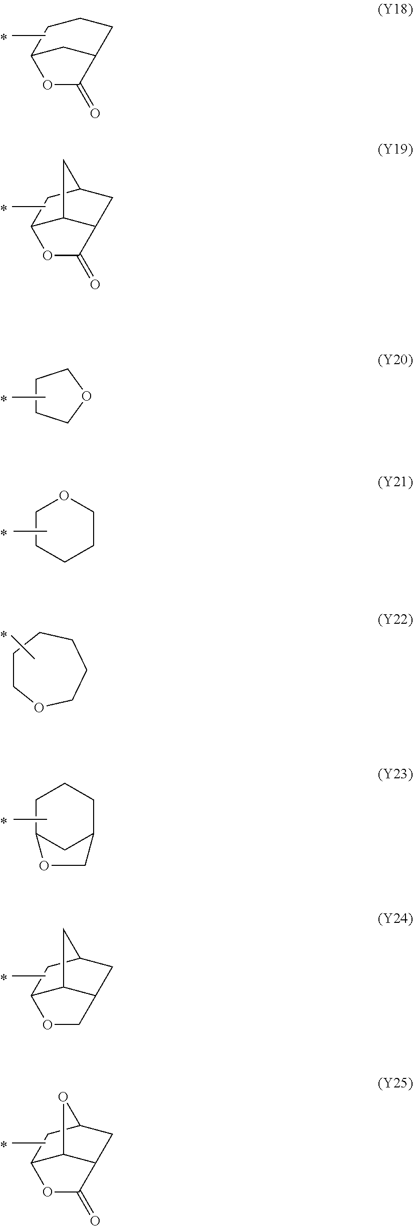

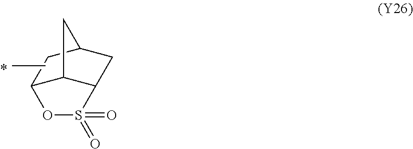

Among these examples, as Y, a group which is represented by any of Formula (Y1) to Formula (Y19) is preferable, a group which is represented by Formula (Y11), Formula (Y14), Formula (Y15), or Formula (Y19) is more preferable, and a group which is represented by Formula (Y11) or Formula (Y14) is even more preferable.

Examples of alicyclic hydrocarbon groups formed by alkyl groups being bonded with carbon atoms, which are atoms which configure a ring, include the following.

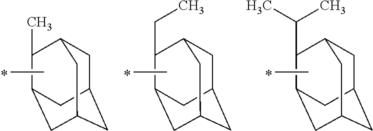

Examples of alicyclic hydrocarbon groups which have a hydroxy group include the following.

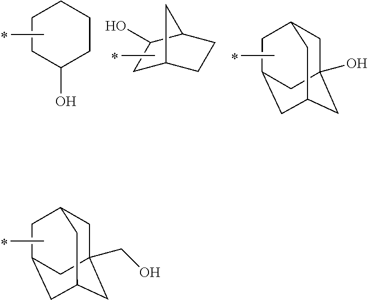

Examples of alicyclic hydrocarbon groups which have an aromatic hydrocarbon group include the following.

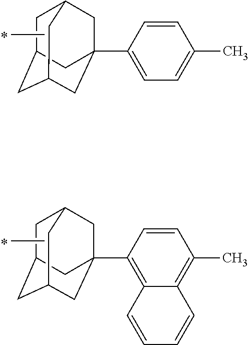

Examples of alicyclic hydrocarbon groups which have a group which is represented by —(CH₂)ⱼ₂—O—CO—R^{b1} include the following.

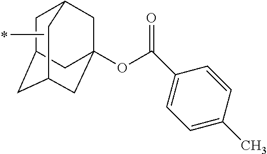

Y is preferably an adamantyl group which may have a hydroxy group or the like as a substituent, and specifically, preferably an adamantyl group or a hydroxyadamantyl group.

Examples of sulfonic acid anions include sulfonic acid anions which are represented by Formula (b1-1-1) to Formula (b1-1-9) below. In the sulfonic acid anions which are represented by any of Formula (b1-1-1) to Formula (b1-1-9), L^{b1} is preferably a group which is represented by Formula (b1-1). In addition, R^{b2} and R^{b3} are each independently the same as the examples of substituents which an aliphatic hydrocarbon group or an alicyclic hydrocarbon group of Y may have, and an aliphatic hydrocarbon group with 1 to 4 carbon atoms and a hydroxy group are preferable, and a methyl group and a hydroxy group are more preferable.

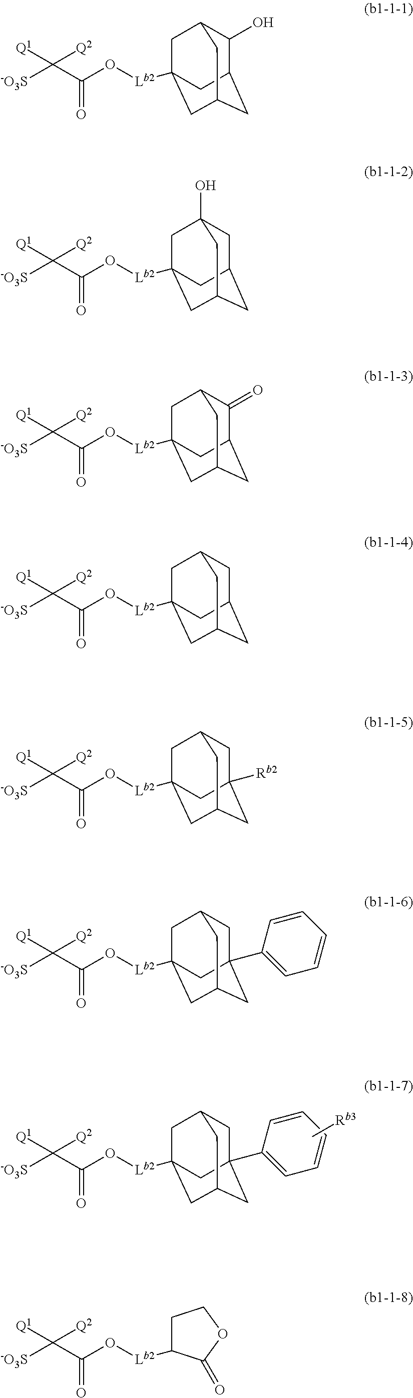

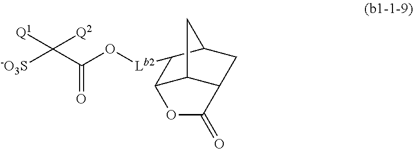

Examples of sulfonic acid anions where Y is an unsubstituted aliphatic hydrocarbon group or an unsubstituted alicyclic hydrocarbon group, and L^{b1} is a group which is represented by Formula (b1-1) include the following.

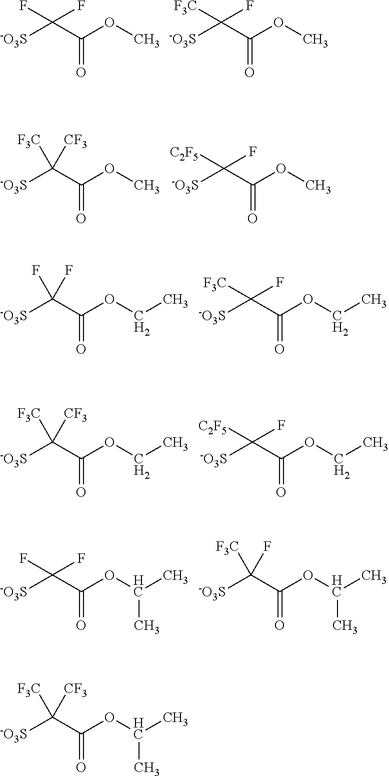

Examples of sulfonic acid anions where Y is an unsubstituted alicyclic hydrocarbon group or an alicyclic hydrocarbon group which has an aliphatic carbon group as a substituent, and L^{b1} is a group which is represented by Formula (b1-1) include the following.

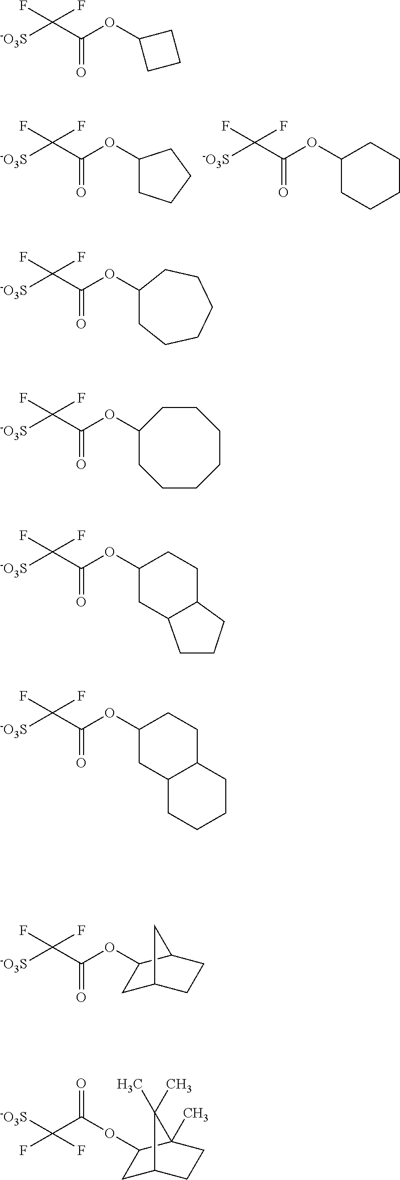

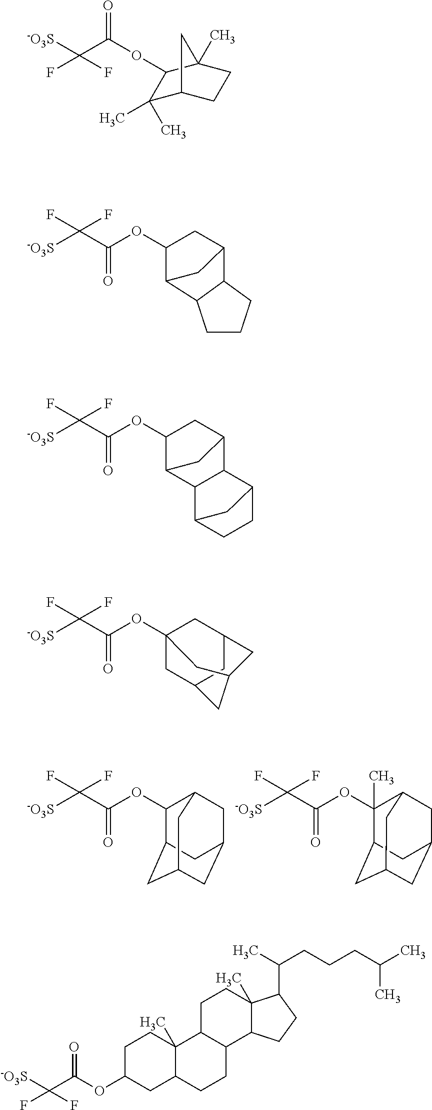

Examples of sulfonic acid anions where Y is an alicyclic hydrocarbon group which has a group which is represented by —(CH₂)ⱼ₂—O—CO—R^{b1} and L^{b1} is a group which is represented by Formula (b1-1) include the following.

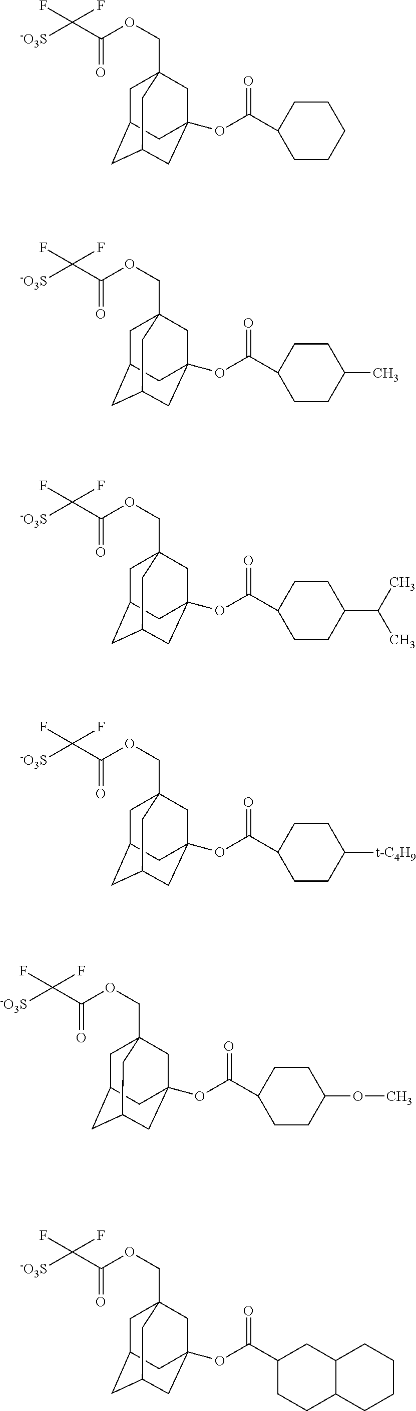

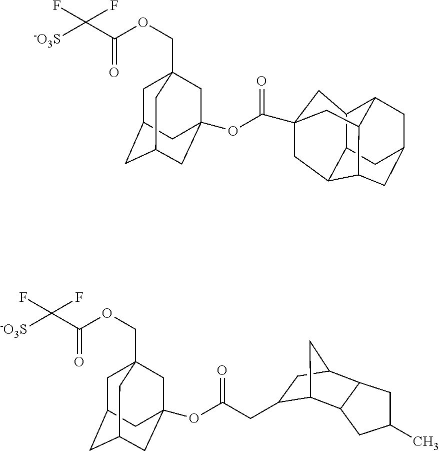

Examples of sulfonic acid anions where Y is an alicyclic hydrocarbon group which has a hydroxy group and L^{b1} is a group which is represented by Formula (b1-1) include the following.

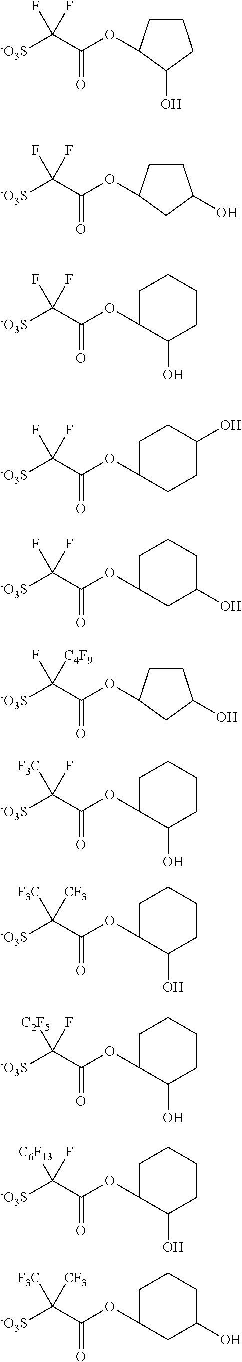

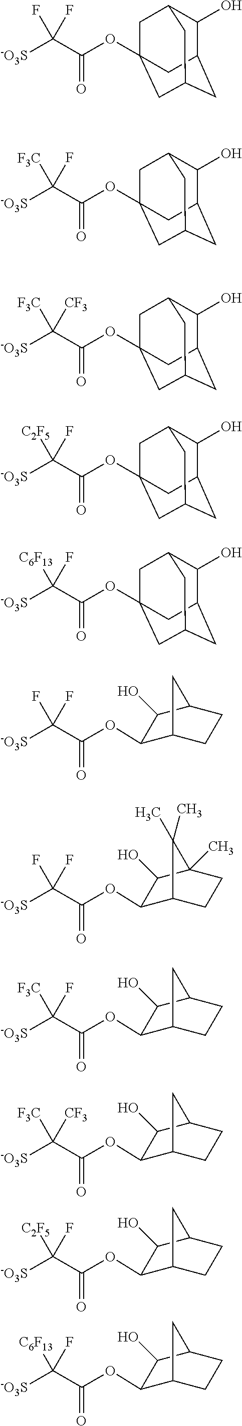

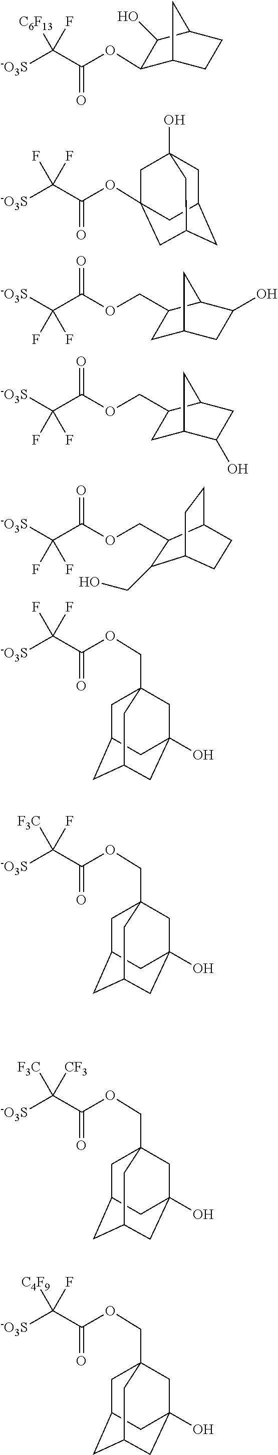

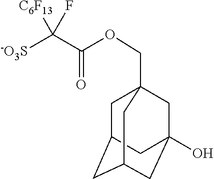

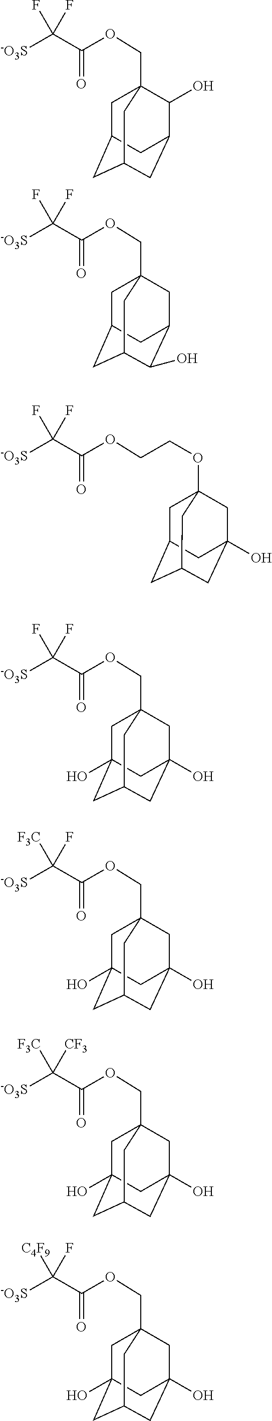

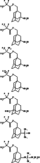

Examples of sulfonic acid anions where Y is an aromatic hydrocarbon group or an alicyclic hydrocarbon group which has an aralkyl group and L^{b1} is a group which is represented by Formula (b1-1) include the following.

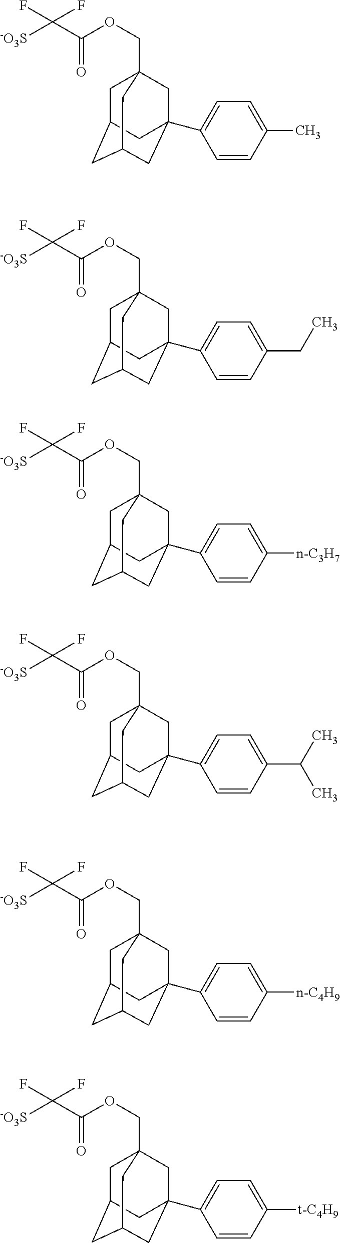

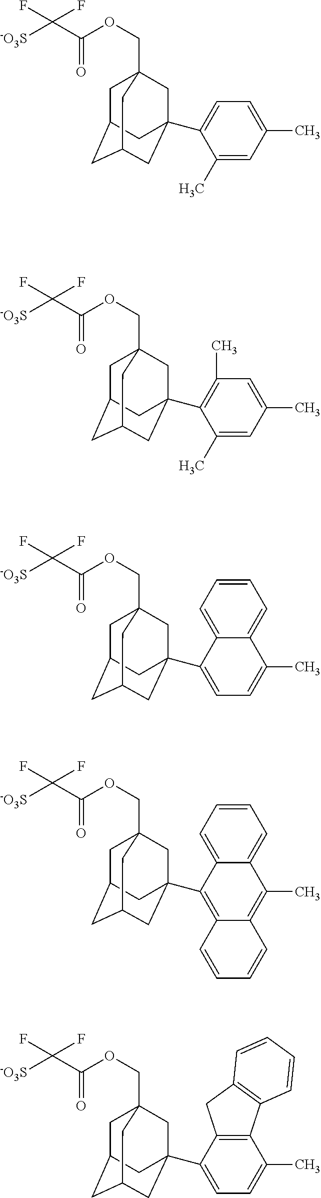

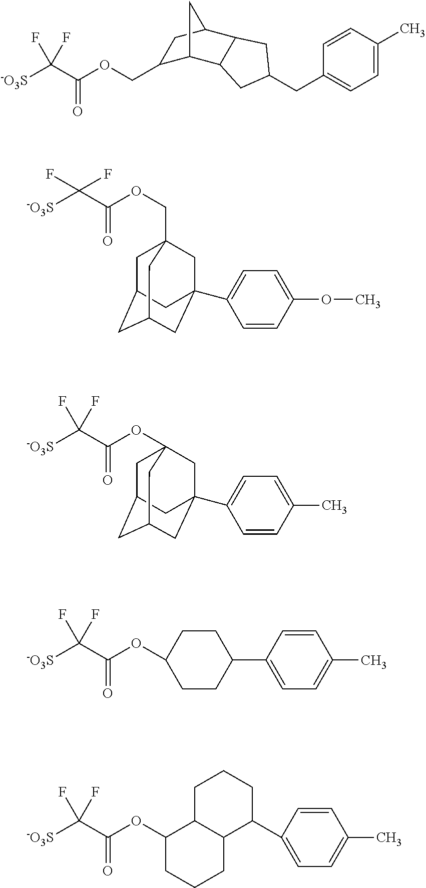

Examples of sulfonic acid anions where Y is a group which includes the cyclic ether structure and L^{b1} is a group which is represented by Formula (b1-1) include the following.

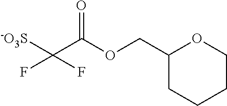

Examples of sulfonic acid anions where Y is a group which includes the lactone ring structure and L^{b1} is a group which is represented by Formula (b1-1) include the following.

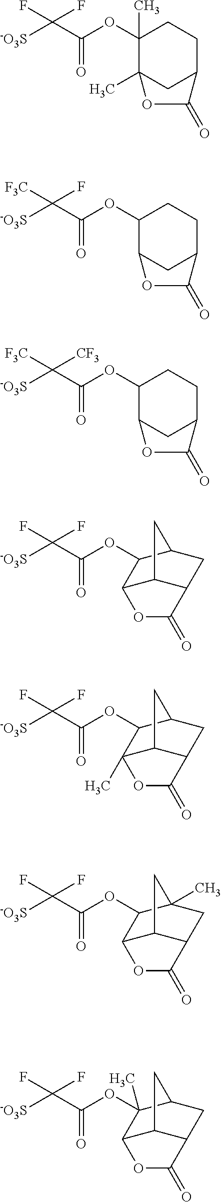

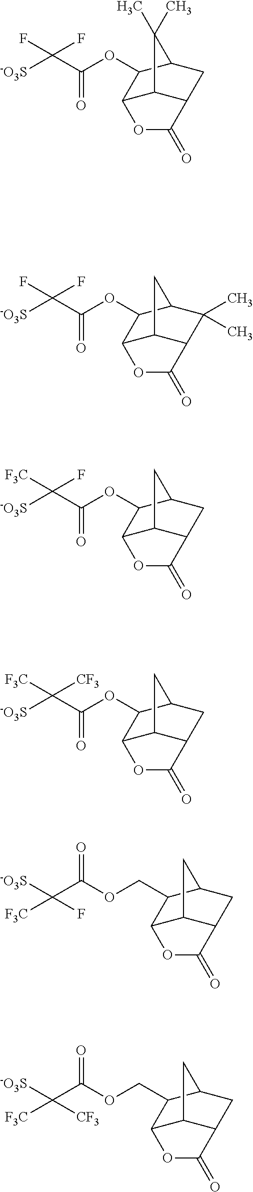

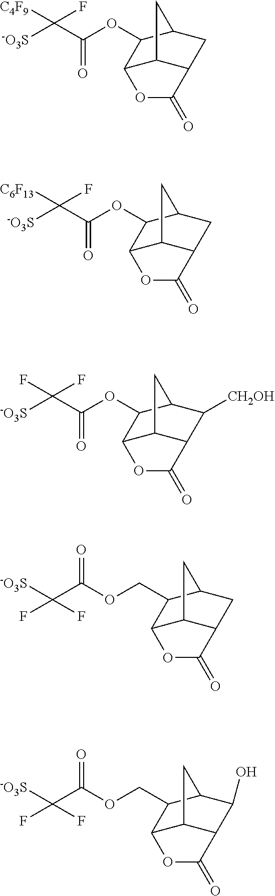

Examples of sulfonic acid anions where Y is a group which includes a cyclic ketone structure and L^{b1} is a group which is represented by Formula (b1-1) include the following.

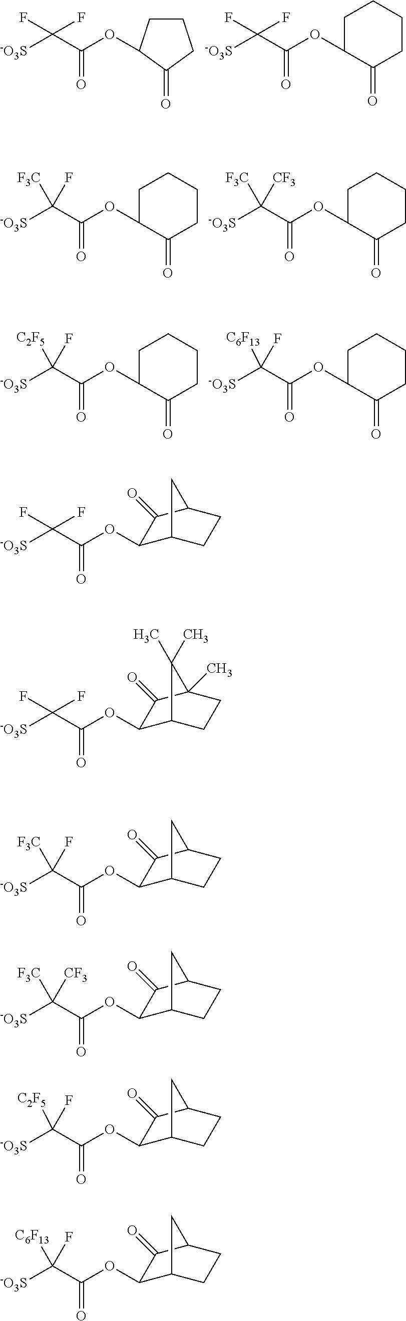

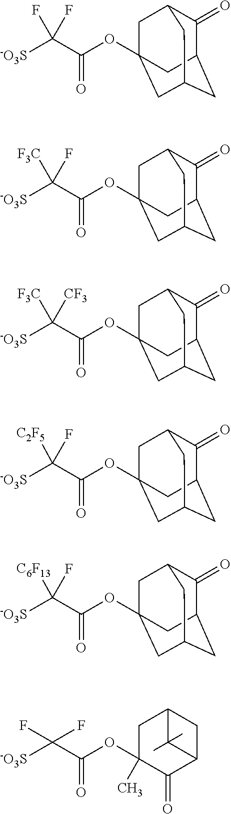

Examples of sulfonic acid anions where Y is a group which includes the sultone ring structure and L^{b1} is a group which is represented by Formula (b1-1) include the following.

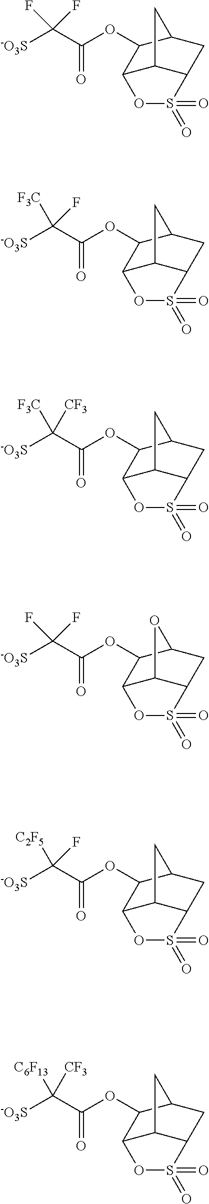

Examples of sulfonic acid anions where Y is an aliphatic hydrocarbon group or an unsubstituted alicyclic hydrocarbon group and L^{b1} is a group which is represented by Formula (b1-2) include the following.

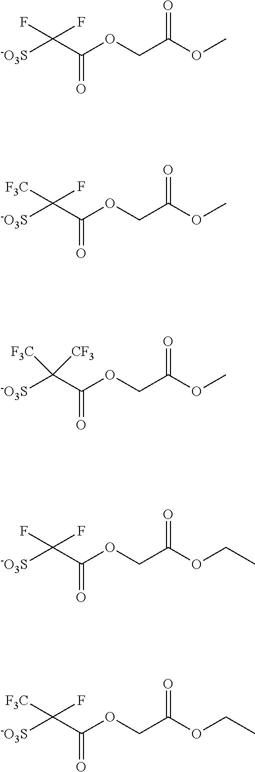

Examples of sulfonic acid anions where Y is an alicyclic hydrocarbon group which has a group which is represented by —(CH₂)ⱼ₂—O—CO—R^{b1} and L^{b1} is a group which is represented by Formula (b1-2) include the following.

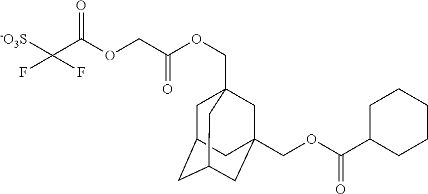

Examples of sulfonic acid anions where Y is an alicyclic hydrocarbon group which has a hydroxy group and L^{b1} is a group which is represented by Formula (b1-2) include the following.

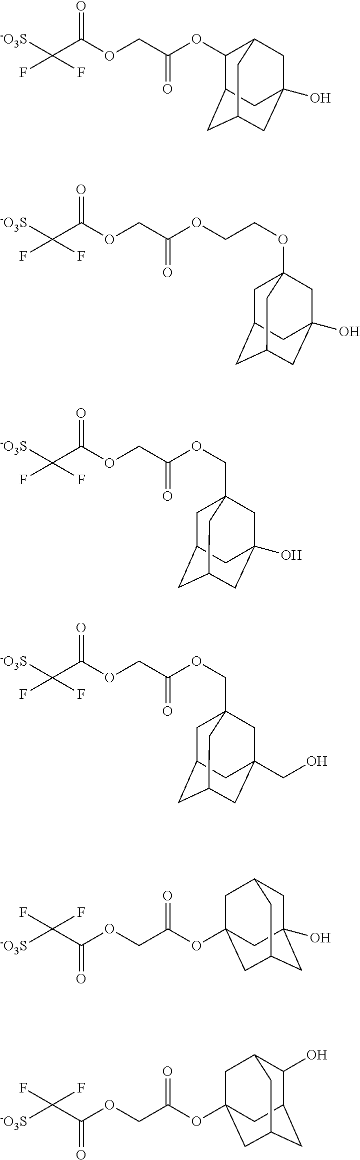

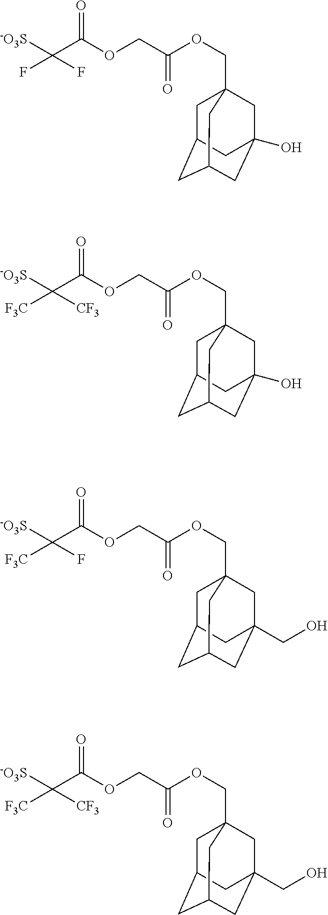

Examples of sulfonic acid anions where Y is an alicyclic hydrocarbon group which has an aromatic hydrocarbon group and L^{b1} is a group which is represented by Formula (b1-2) include the following.

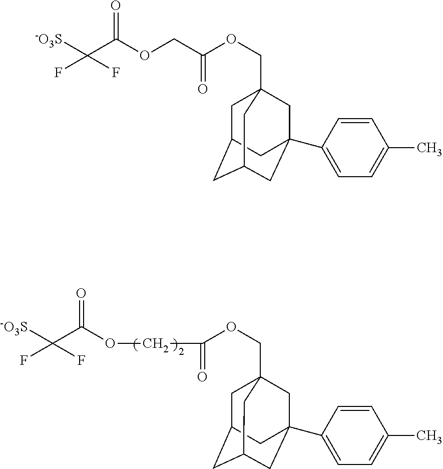

Examples of sulfonic acid anions where Y is a group which includes a cyclic ether structure and L^{b1} is a group which is represented by Formula (b1-2) include the following.

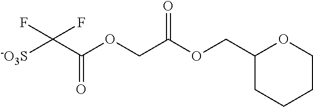

Examples of sulfonic acid anions where Y is a group which includes the lactone ring structure and L^{b1} is a group which is represented by Formula (b1-2) include the following.

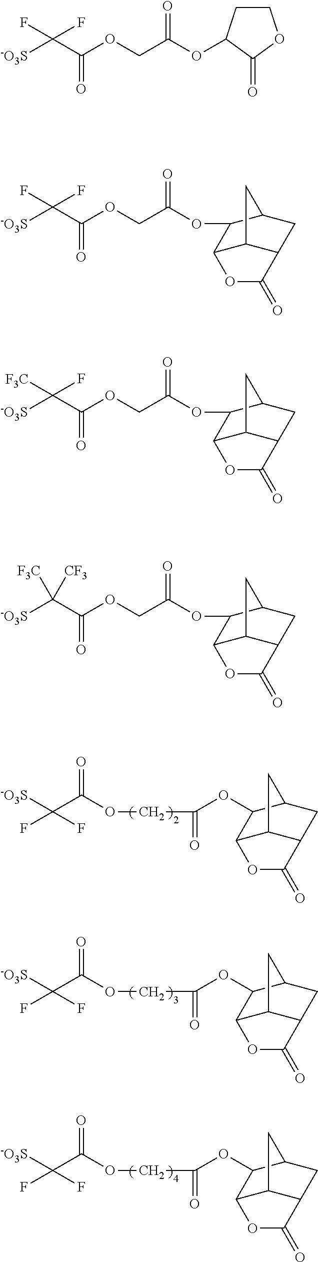

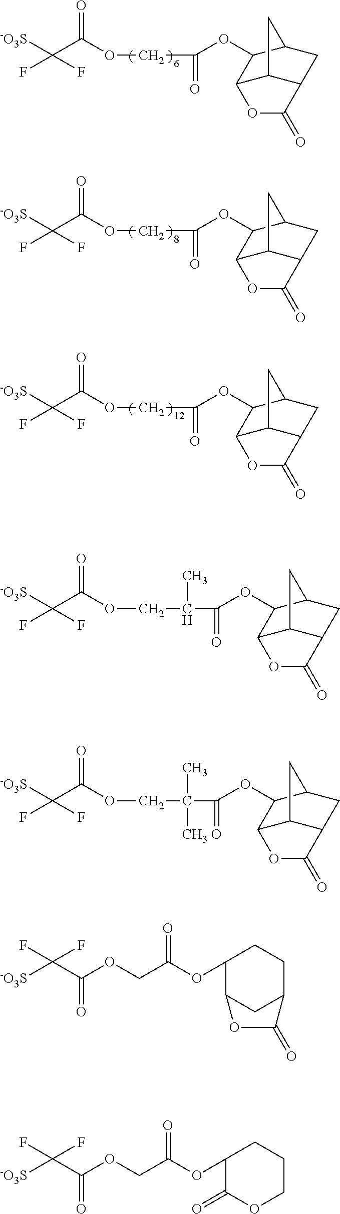

Examples of sulfonic acid anions where Y is a group which includes the cyclic ketone structure and L^{b1} is a group which is represented by Formula (b1-2) include the following.

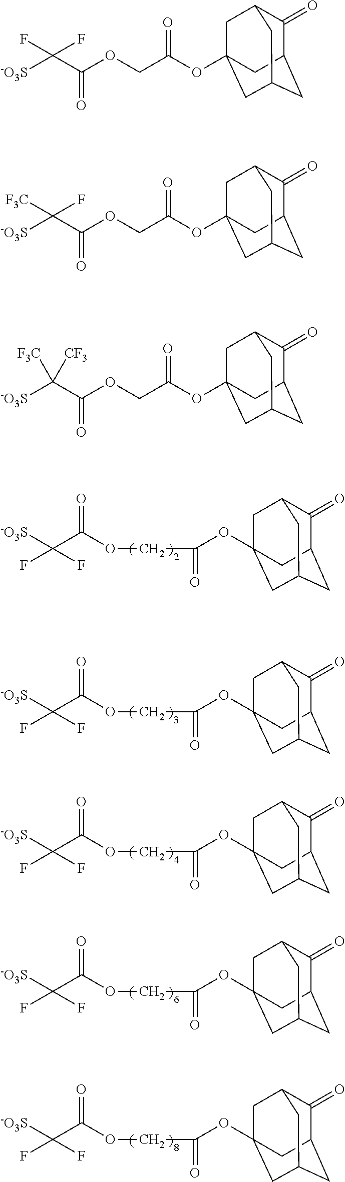

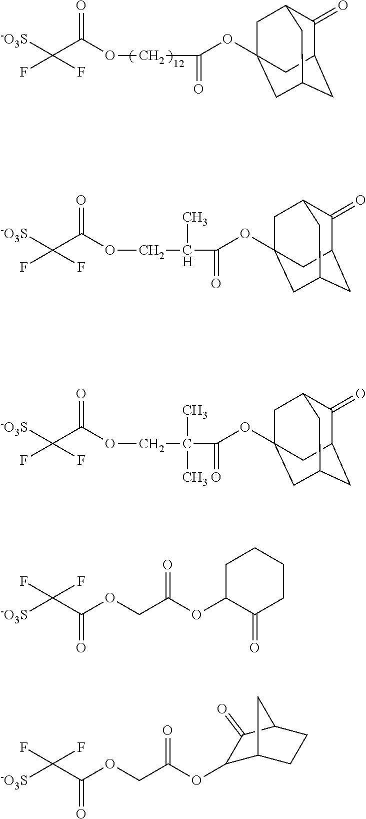

Examples of sulfonic acid anions where Y is a group which includes the sultone ring structure and L^{b1} is a group which is represented by Formula (b1-2) include the following.

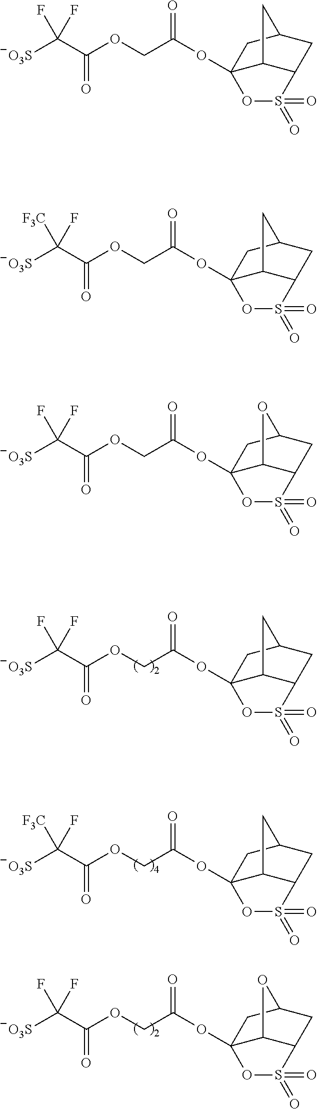

Examples of sulfonic acid anions where Y is an aliphatic hydrocarbon group and L^{b1} is a divalent group which is represented by Formula (b1-3) include the following.

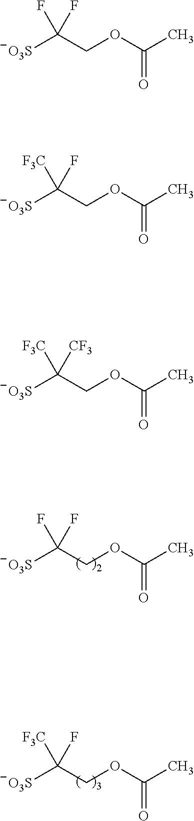

Examples of sulfonic acid anions where Y is an alicyclic hydrocarbon group which has an alkoxy group and L^{b1} is a group which is represented by Formula (b1-3) include the following.

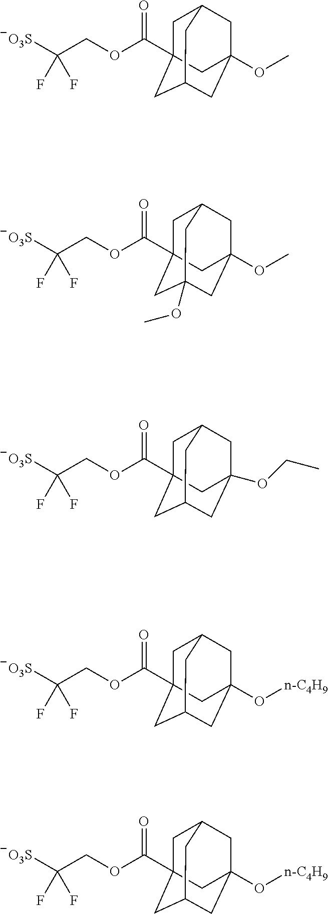

Examples of sulfonic acid anions where Y is an alicyclic hydrocarbon group which has a hydroxy group and L^{b1} is a divalent group which is represented by Formula (b1-3) include the following.

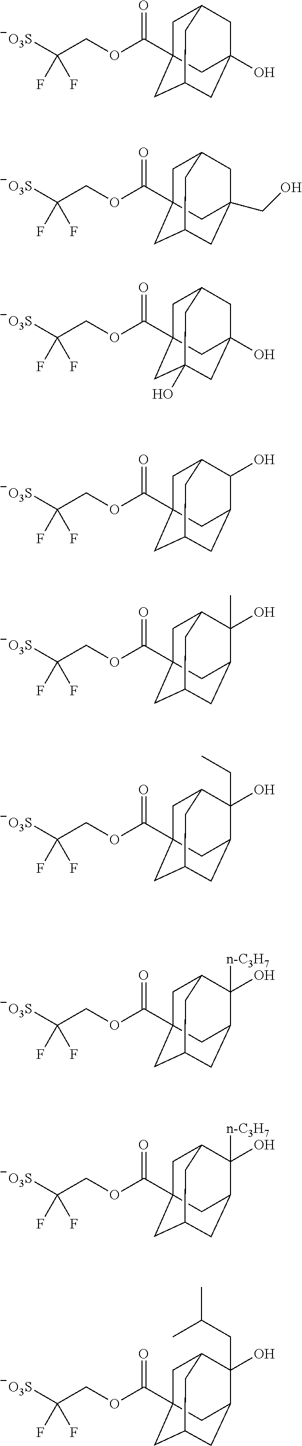

Examples of sulfonic acid anions where Y is a group which includes the cyclic ketone structure and L^{b1} is a group which is represented by Formula (b1-3) include the following.

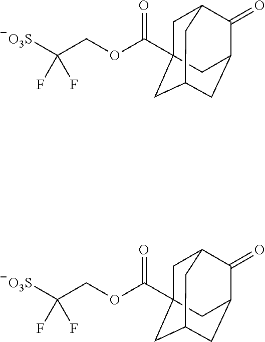

Examples of sulfonic acid anions where Y is an alicyclic hydrocarbon group and L^{b1} is a group which is represented by Formula (b1-4) include the following.

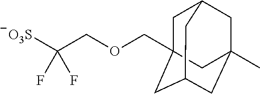

Examples of sulfonic acid anions where Y is an alicyclic hydrocarbon group which has an alkoxy group and L^{b1} is a group which is represented by Formula (b1-4) include the following.

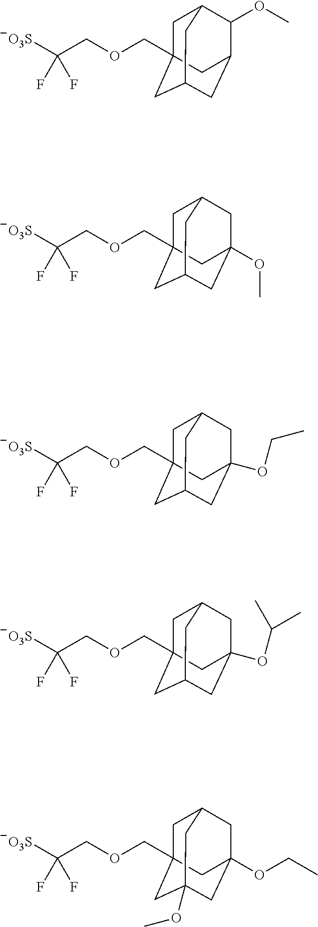

Examples of sulfonic acid anions where Y is an alicyclic hydrocarbon group which has a hydroxy group and L^{b1} is a group which is represented by Formula (b1-4) include the following.

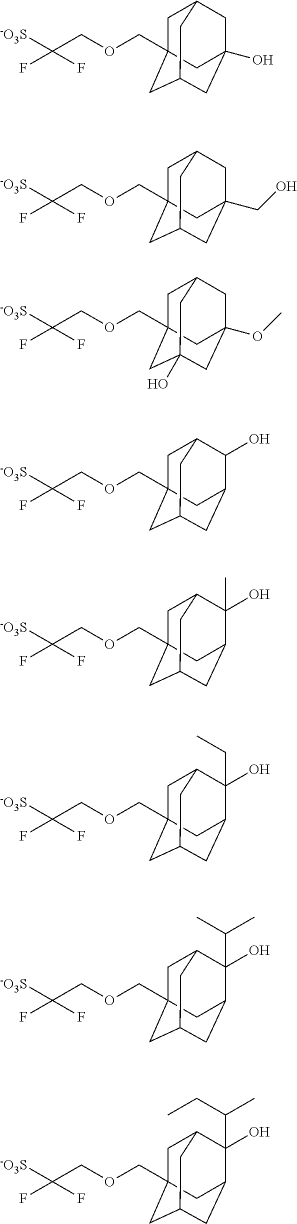

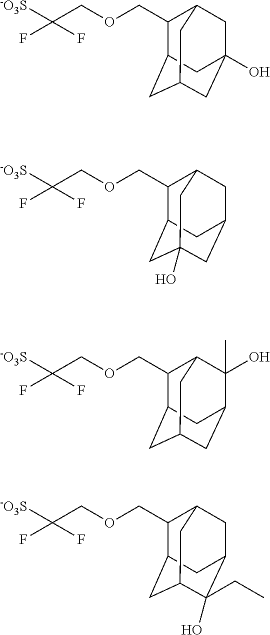

Examples of sulfonic acid anions where Y is a group which includes the cyclic ketone structure and L^{b}' is a divalent group which is represented by Formula (b1-4) include the following.

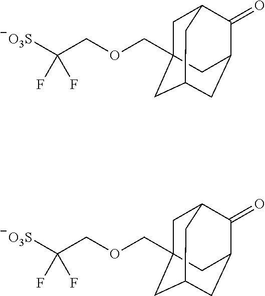

Among the examples of sulfonic acid anions described above, sulfonic acid anions where L^{b1} is a group which is represented by Formula (b1-1) are preferable. More preferable sulfonic acid anions will be shown below.

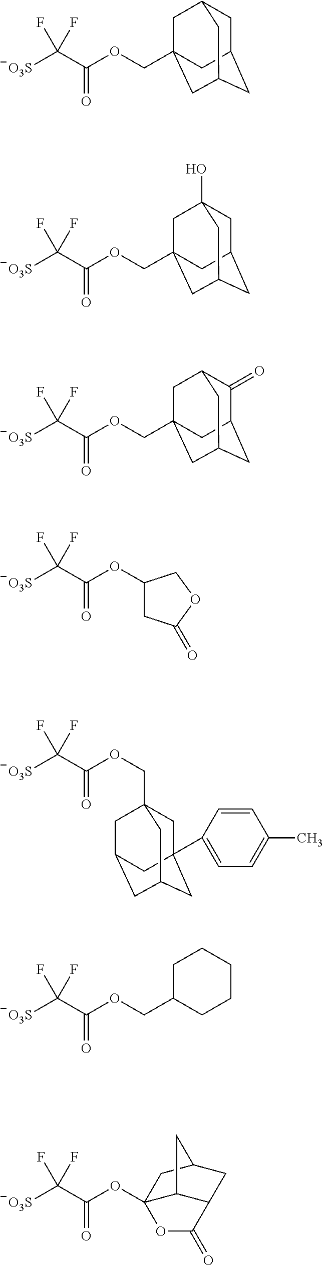

Examples of cations which are included in an acid generator include onium cations, sulfonium cations, iodonium cations, ammonium cations, benzothiazolium cations, phosphonium cations, and the like. Among these, sulfonium cations and iodonium cations are preferable, and arylsulfonium cations are more preferable.

Sulfonium cations and iodonium cations are also preferable as organic cations (Z+) in the acid generator (B1), and organic cations which are represented by any of Formula (b2-1) to Formula (b2-4) below [referred to below as “cations (b2-1)”, “cations (b2-2)”, “cations (b2-3)”, and “cations (b2-4)” according to the number of each formula] are more preferable.

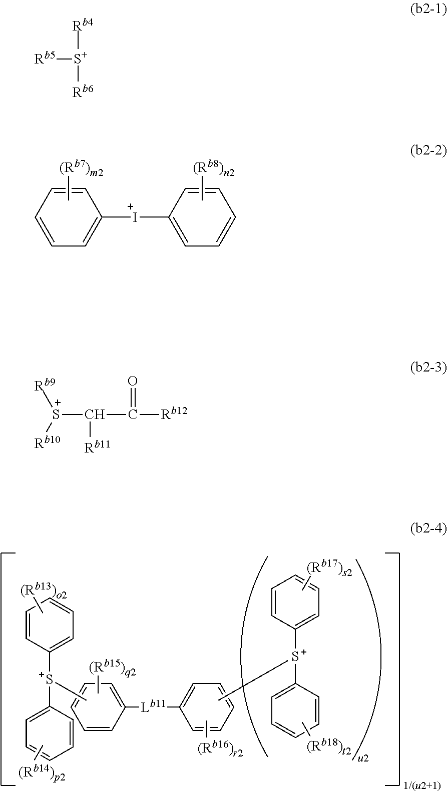

[In Formula (b2-1) to Formula (b2-4), R^{b4}, R^{b5}, and R^{b6} each independently represents an aliphatic hydrocarbon group (preferably with 1 to 30 carbon atoms), an alicyclic hydrocarbon group (preferably with 3 to 18 carbon atoms), or an aromatic hydrocarbon group (preferably with 6 to 18 carbon atoms). A hydrogen atom which is included in the aliphatic hydrocarbon group may be substituted with a hydroxy group, an alkoxy group (preferably with 1 to 12 carbon atoms), or an aromatic hydrocarbon group (preferably with 6 to 18 carbon atoms), a hydrogen atom which is included in the alicyclic hydrocarbon group may be substituted with a halogen atom, an acyl group (preferably with 2 to 4 carbon atoms), or a glycidyloxy group, and the aromatic hydrocarbon group may be substituted with a halogen atom, a hydroxy group, an aliphatic hydrocarbon group (preferably with 1 to 18 carbon atoms), an alicyclic hydrocarbon group (preferably with 3 to 18 carbon atoms), or an alkoxy group (preferably with 1 to 12 carbon atoms).

R^{b7} and R^{b8} each independently represents a hydroxy group, an aliphatic hydrocarbon group (preferably with 1 to 12 carbon atoms), or an alkoxy group (preferably with 1 to 12 carbon atoms).

m2 and n2 each independently represents an integer of 0 to 5.

R^{b9} and R^{b10} each independently represents an aliphatic hydrocarbon group (preferably with 1 to 18 carbon atoms) or an alicyclic hydrocarbon group (preferably with 3 to 18 carbon atoms).

R^{b11} represents a hydrogen atom, an aliphatic hydrocarbon group (preferably with 1 to 18 carbon atoms), an alicyclic hydrocarbon group (preferably with 3 to 18 carbon atoms), or an aromatic hydrocarbon group (preferably with 6 to 18 carbon atoms).

R^{b9} to R^{b11} are each independently an aliphatic hydrocarbon group or an alicyclic hydrocarbon group, and in a case where these are aliphatic hydrocarbon groups, the number of carbon atoms is preferably 1 to 12, and in a case where these are alicyclic hydrocarbon groups, the number of carbon atoms is preferably 3 to 18, and more preferably 4 to 12.

R^{b12} represents an aliphatic hydrocarbon group (preferably with 1 to 12 carbon atoms), an alicyclic hydrocarbon group (preferably with 3 to 18 carbon atoms), or an aromatic hydrocarbon group (preferably with 6 to 18 carbon atoms). A hydrogen atom which is included in the aromatic hydrocarbon group may be substituted with an aliphatic hydrocarbon group (preferably 1 to 12 carbon atoms), an alkoxy group (preferably 1 to 12 carbon atoms), an alicyclic hydrocarbon group (preferably 3 to 18 carbon atoms), or an alkylcarbonyloxy group (preferably 1 to 12 carbon atoms).

R^{b9} and R^{b10} may be bonded with each other to form a 3- to 12-membered alicyclic hydrocarbon ring (preferably, a 3- to 7-membered ring) with a sulfur atom with which these are bonded, and a methylene group which is included in the alicyclic hydrocarbon ring may be substituted with an oxy group, a thioxy group, or a carbonyl group.

R^{b13}, R^{b14}, R^{b15}, R^{b16}, R^{b17}, an_{d R}^{b18} (described below as “R^{b13} to R^{b18}”) each independently represents a hydroxy group, an aliphatic hydrocarbon group with 1 to 12 carbon atoms, or an alkoxy group with 1 to 12 carbon atoms.

L^{b11} represents —S— or —O—.

o2, p2, s2, and t2 each independently represents an integer of 0 to 5.

q2 and r2 each independently represents an integer of 0 to 4.

u2 represents 0 or 1.

A plurality of R^{b13} may be the same as or different from each other when o2 is 2 or more, a plurality of R^{b14} may be the same as or different from each other when p2 is 2 or more, a plurality of R^{b15} may be the same as or different from each other when s2 is 2 or more, and a plurality of R^{b18} may be the same as or different from each other when t2 is 2 or more.]

Examples of alkoxy groups include a methoxy group, an ethoxy group, a propoxy group, a butoxy group, a pentyloxy group, a hexyloxy group, a heptyloxy group, an octyloxy group, a decyloxy group, a dodecyloxy group, and the like.

Examples of halogen atoms include a fluorine atom, a chlorine atom, a bromine atom, an iodine atom, and the like.

Examples of acyl groups include an acetyl group, a propionyl group, a butylyl group, and the like.

Examples of alkylcarbonyloxy groups include a methylcarbonyloxy group, an ethylcarbonyloxy group, an n-propylcarbonyloxy group, an isopropylcarbonyloxy group, an n-butylcarbonyloxy group, a sec-butylcarbonyloxy group, a tert-butylcarbonyloxy group, a pentylcarbonyloxy group, a hexylcarbonyloxy group, an octylcarbonyloxy group, a 2-ethylhexylcarbonyloxy group, and the like.

Preferable alkyl groups are a methyl group, an ethyl group, an n-propyl group, an isopropyl group, an n-butyl group, a sec-butyl group, a tert-butyl group, a pentyl group, a hexyl group, an octyl group, and a 2-ethylhexyl group and, in particular, the alkyl group of R^{b9} to R^{b12} preferably has 1 to 12 carbon atoms.

Preferable alicyclic hydrocarbon groups are a cyclopropyl group, a cyclobutyl group, a cyclopentyl group, a cyclohexyl group, a cycloheptyl group, a cyclodecyl group, a 2-alkyladamantane-2-yl group, 1-(adamantane-1-yl)-1-alkyl group, an isobornyl group, and the like. In particular, an alicyclic hydrocarbon group of R^{b9} to R^{b11} preferably has 3 to 18 carbon atoms, and more preferably has 4 to 12 carbon atoms.

Preferable aromatic hydrocarbon groups are a phenyl group, a 4-methylphenyl group, a 4-ethylphenyl group, a 4-tert-butylphenyl group, a 4-cyclohexylphenyl group, a 4-methoxyphenyl group, a biphenylyl group, a naphthyl group, and the like.

An aromatic hydrocarbon group which is substituted with an alkyl group is typically an aralkyl group and examples thereof include a benzyl group, a phenethyl group, a phenylpropyl group, a trityl group, a naphthylmethyl group, a naphthylethyl group, and the like.

Examples of a ring which R^{b9} and R^{b10} form with a sulfur atom bonded therewith include thiolane-1-ium ring (a tetrahydrothiophenium ring), a thiane-1-ium ring, a 1,4-oxathiane-4-ium ring, and the like.

Examples of a ring which R^{b11} and R^{b12} form with —CH—CO— bonded therewith include an oxocycloheptane ring, an oxocyclohexane ring, an oxonorbornane ring, an oxoadamantane ring, and the like.

Among these, cations (b2-1) are preferable, organic cations which are represented by Formula (b2-1-1) below [referred to below as “cation (b2-1-1)”] are more preferable, and triphenylsulfonium cations (in Formula (b2-1-1), v2=w2=x2=0) or tritolylsulfonium cations (in Formula (b2-1-1), v2=w2=x2=1, R^{b19}, R^{b20}, and R^{b21} are all a methyl group) are even more preferable.

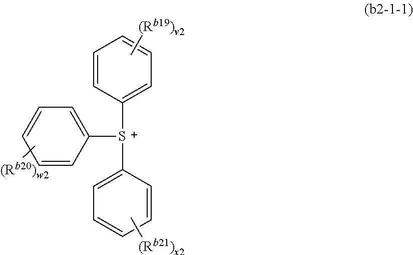

In Formula (b2-1-1), R^{b19} to R^{b21} each independently represents a halogen atom (more preferably a fluorine atom) hydroxy group, an alkyl group (preferably 1 to 12 carbon atoms), an alkoxy group (preferably 1 to 12 carbon atoms), or an alicyclic hydrocarbon group (preferably 3 to 18 carbon atoms).

v2, w2, and x2 each independently represents an integer of 0 to 5 (preferably 0 or 1).

A plurality of R^{b19} may be the same as or different from each other when v2 is 2 or more, a plurality of R^{b20} may be the same as or different from each other when w2 is 2 or more, and a plurality of R^{b21} may be the same as or different from each other when x2 is 2 or more.

Among these, R^{b19}, R^{b20}, and R^{b21} are preferably each independently a halogen atom (more preferably a fluorine atom), a hydroxy group, an alkyl group (preferably 1 to 12 carbon atoms), or an alkoxy group (preferably 1 to 12 carbon atoms).

Specific examples of cations (b2-1-1) include the following.

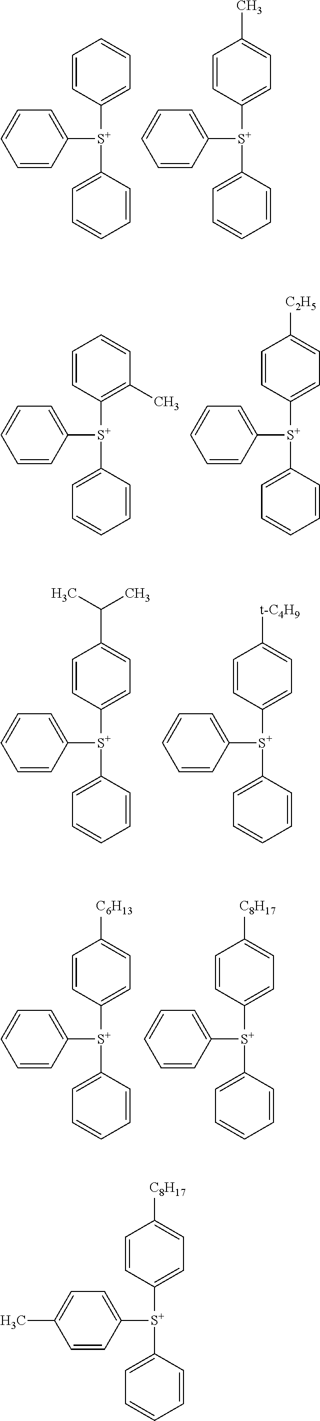

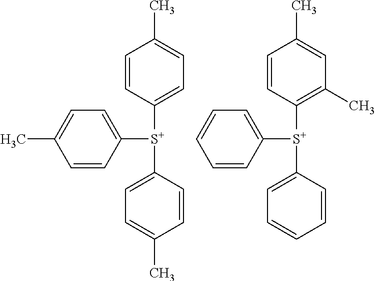 [SMILES: Cc1ccc([S+](c2ccc(C)cc2)c2ccc(C)cc2)cc1 ; Cc1ccc([S+](c2ccccc2)c2ccccc2)c(C)c1]

A resist composition of the present invention, which includes the acid generator (B1) having such organic cations and the compound (I), is able to produce a resist pattern with a more favorable focus margin.

Specific examples of cations (b2-2) include the following.

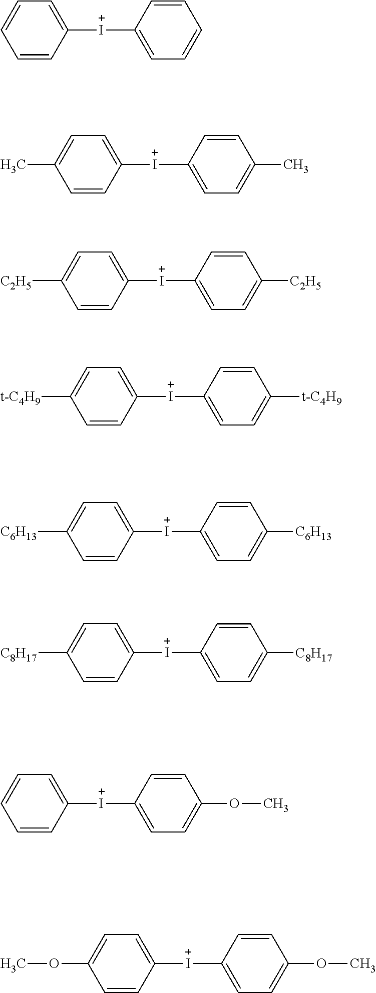

Specific examples of cations (b2-3) include the following.

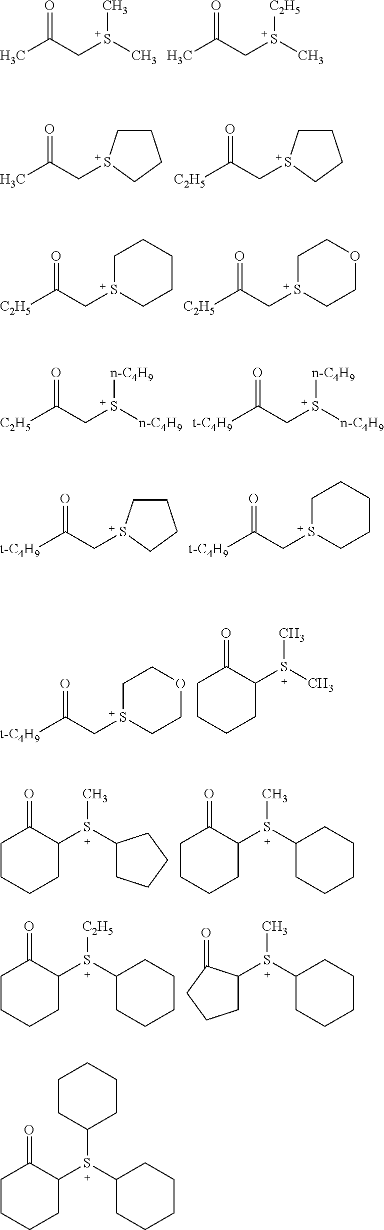

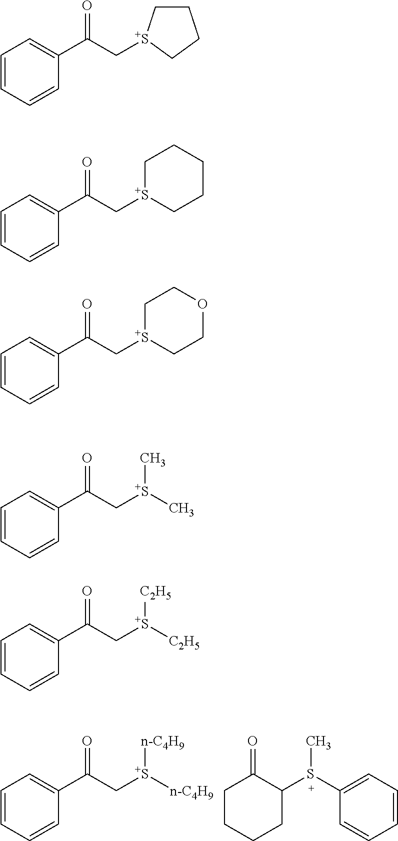

Specific examples of cations (b2-4) include the following.

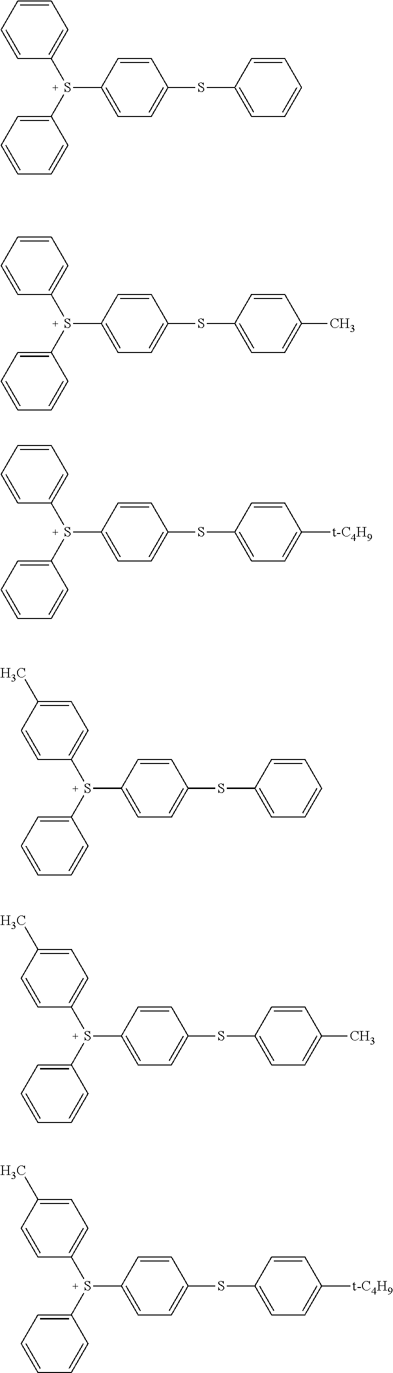

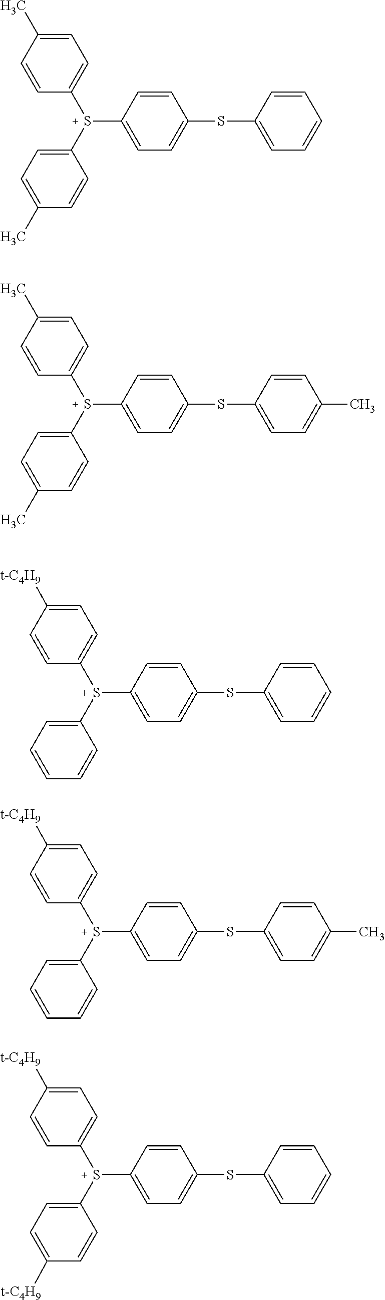

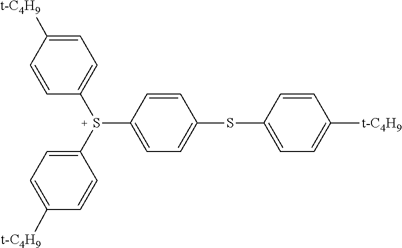

With regard to the acid generator (B1), it is possible to arbitrarily combine the sulfonic acid anions and the organic anions. Among these, an acid generator (B1) which is a combination of sulfonic acid anions which are represented by any of Formula (b1-1-1) to Formula (b1-1-9) and cations (b2-1-1) and an acid generator (B1) which is a combination of sulfonic acid anions which are represented by any of Formula (b1-1-3) to Formula (b1-1-5) and cations (b2-3) are preferable. A resist composition which includes the acid generator (B1) and the compound (I) is able to produce a resist pattern with an even wider focus margin.

Examples of a preferable acid generator (B1) include acid generators which are represented by any of Formula (B1-1) to Formula (B1-17) below. Among these, an acid generator which is the acid generator (B1) which includes triphenylsulfonium cations or tritolylsulfonium cations and which is represented by any of Formula (B1-1), Formula (B1-2), Formula (B1-6), Formula (B1-11), Formula (B1-12), Formula (B1-13), and Formula (B1-14), and an acid generator which is represented by Formula (B1-3) are more preferable.

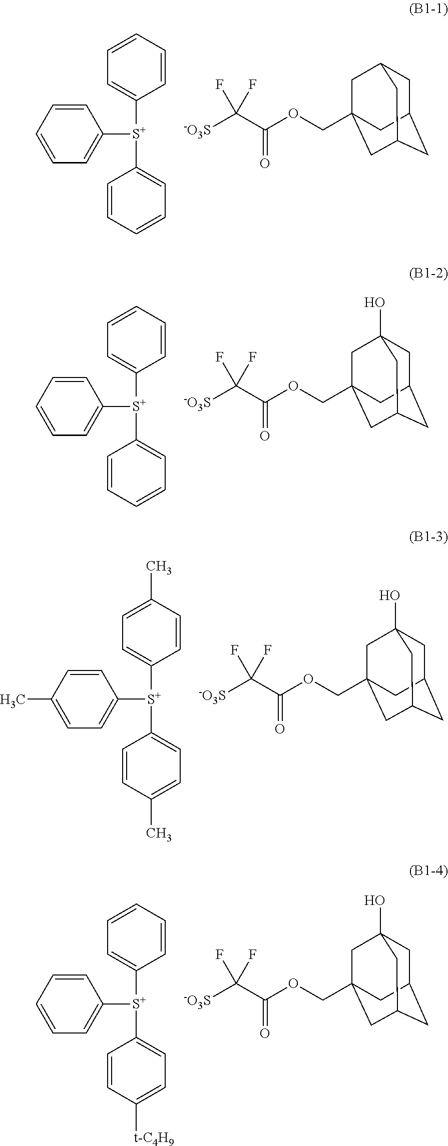

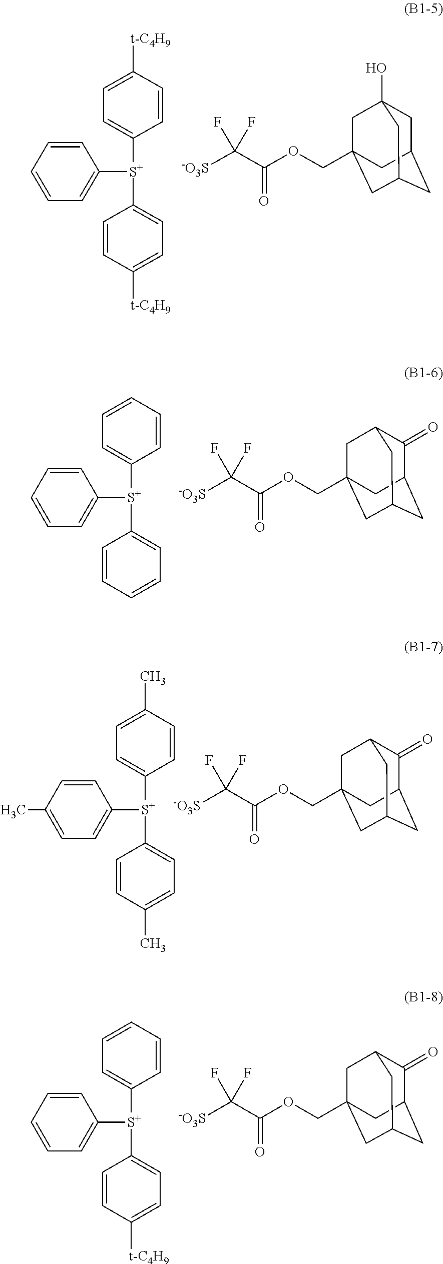

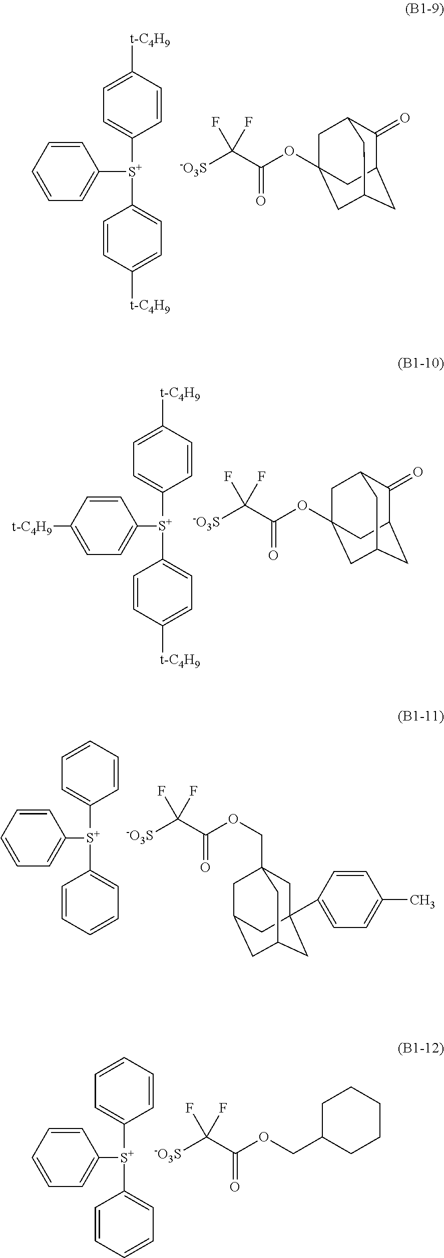

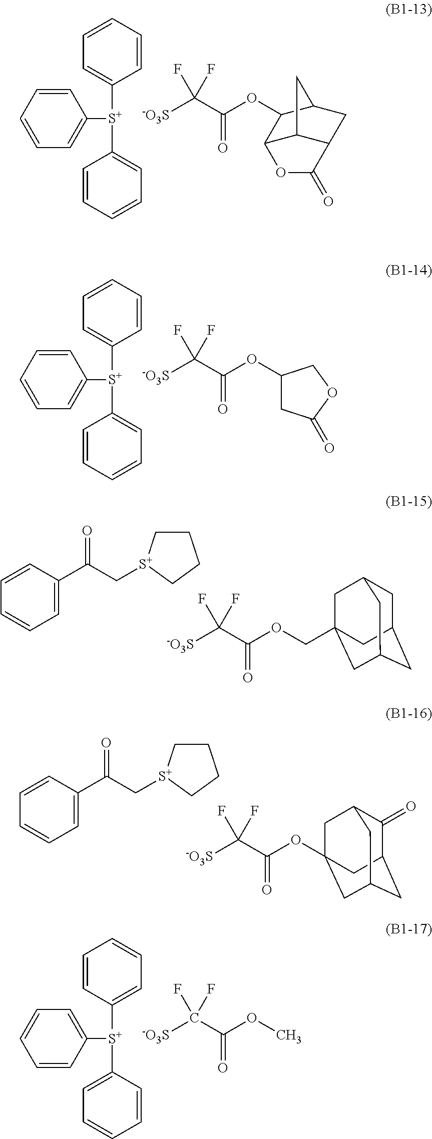

The acid generator (B) may be used as one type, or a plurality of types may be used. The content (the total amount in the case of using a plurality of types) of the acid generator (B) in an actinic ray-sensitive or radiation-sensitive resin composition is preferably 0.1 mass % to 30 mass %, more preferably 0.5 mass % to 25 mass %, even more preferably 3 mass % to 20 mass %, and particularly preferably 3 mass % to 15 mass % using the total solid content of the actinic ray-sensitive or radiation-sensitive resin composition as a reference.

(C) A Compound Which has a Cation Site and an Anion Site in the Same Molecule With the Cation Site and the Anion Site Being Linked With Each Other by a Covalent Bond (Also Referred to Below as Compound (C))

An actinic ray-sensitive or radiation-sensitive resin composition which is used in the present invention contains (C) a compound which has a cation site and an anion site in the same molecule with the cation site and the anion site being linked with each other by a covalent bond.

The compound (C) is preferably a compound which is represented by any of general Formulas (C-1) to (C-4) below.

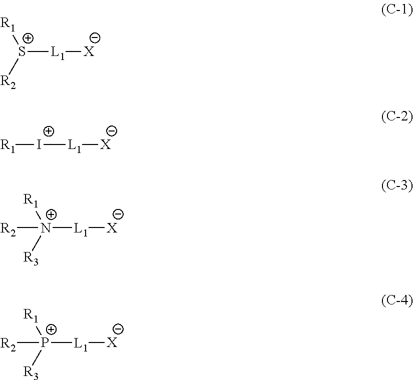

In general Formulas (C-1) to (C-4), R₁, R₂, and R₃ each independently represents a substituent with 1 or more carbon atoms.

L₁ represents a divalent linking group or a single bond which links a cation site and an anion site.

—X⁻ represents an anion site which is selected from —COO⁻, —SO₃⁻, —SO₂⁻, and —N—R₄. R₄ represents a monovalent substituent which has a group which is selected from a carbonyl group: —C(═O)—, a sulfonyl group: —S(═O)₂—, and a sulfinyl group: —S(═O)— in a linking site with an adjacent N atom.

Two or more groups which are selected from R₁, R₂, and L₁ in general Formula (C-1) may be linked to form a ring structure (L₁ represents a trivalent linking group in a case where R₁, R₂, and L₁ are linked to form a ring and L₁ represents a tetravalent linking group in a case where R₁, R₂, and L₁ are linked to form a ring structure).

R₁ and L₁ in general Formula (C-2) may be linked to form a ring structure (L₁ represents a trivalent linking group in a case where R₁ and L₁ are linked to form a ring structure).

Two or more groups which are selected from R₁, R₂, R₃, and L₁ in general Formula (C-3) may be linked to form a ring structure (L₁ represents a trivalent linking group in a case where one of R₁, R₂, and R₃ and L₁ are linked to form a ring structure, L₁ represents a tetravalent linking group in a case where two of R₁, R₂, and R₃ and L₁ are linked to form a ring structure, and L₁ represents a pentavalent linking group in a case where all of R₁, R₂, and R₃ and L₁ are linked to form a ring structure).

Two or more groups which are selected from R₁, R₂, R₃, and L₁ in general Formula (C-4) may be linked to form a ring structure (L₁ represents a trivalent linking group in a case where one of R₁, R₂, and R₃ and L₁ are linked to form a ring structure, L₁ represents a tetravalent linking group in a case where two of R₁, R₂, and R₃ and L₁ are linked to form a ring structure, and L₁ represents a pentavalent linking group in a case where all of R₁, R₂, and R₃ and L₁ are linked to form a ring structure).

Examples of substituents with 1 or more carbon atoms in R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbony group, and the like. An alkyl group, a cycloalkyl group, and an aryl group are preferable.

Examples of L₁ as a divalent linking group include a linear or branched alkylene group, a cycloalkylene group, an arylene group, a carbonyl group, an ether bond, an ester bond, an amid bond, an urethane bond, an urea bond, a group formed by combining two or more types thereof, and the like. L₁ is more preferably an alkylene group, an arylene group, an ether bond, an ester bond, and a group formed by combining two or more types thereof.

Specific examples and preferable examples of L₁ as a trivalent to pentavalent linking group include a linking group formed by respectively excluding 1 to 3 arbitrary hydrogen atoms from the specific examples and preferable examples of L₁ as a divalent linking group described above.

As a ring which two groups which are selected from R₁, R₂, and L₁ in general Formula (C-1) may be linked to form, a sulfur-containing hetero-ring is preferable. The sulfur-containing hetero-ring structure may be monocyclic, polycyclic, or a spiro-ring and is preferably a monocyclic sulfur-containing hetero-ring structure and the number of carbon atoms thereof is preferably 3 to 10. Among these, a dibenzothiophene ring or a dibenzothioxane ring is preferable.

As a ring which R₁ and L₁ in general Formula (C-2) may be linked to form, an iodine-containing hetero-ring is preferable. The iodine-containing hetero-ring structure may be monocyclic, polycyclic, or a spiro-ring and is preferably a monocyclic iodine-containing hetero-ring structure and the number of carbon atoms thereof is preferably 3 to 10.

As a ring which two or more groups which are selected from R₁, R₂, R₃, and L₁ in general Formula (C-3) may be linked to form, a nitrogen-containing hetero-ring is preferable. The nitrogen-containing hetero-ring structure may be monocyclic, polycyclic, or a spiro-ring and is preferably a monocyclic nitrogen-containing hetero-ring structure and the number of carbon atoms thereof is preferably 3 to 10.

As a ring which two or more groups which are selected from R₁, R₂, R₃, and L₁ in general Formula (C-4) may be linked to form, a phosphorus-containing hetero-ring is preferable. The phosphorus-containing hetero-ring structure may be monocyclic, polycyclic, or a spiro-ring and is preferably a monocyclic phosphorus-containing hetero-ring structure and the number of carbon atoms thereof is preferably 3 to 10.

As a compound (C), a compound which is represented by Formula (I1) below is preferable.

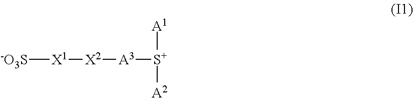

[In Formula (I1), A¹ and A² each independently represents a monovalent aliphatic hydrocarbon group (preferably with 1 to 18 carbon atoms) or a monovalent aromatic hydrocarbon group (preferably with 6 to 18 carbon atoms) and A³ represents a divalent aliphatic hydrocarbon group (preferably with 1 to 18 carbon atoms) or a divalent aromatic hydrocarbon group (preferably with 6 to 18 carbon atoms).

A¹ and A² or A³ may be bonded with each other to form a hetero-ring (preferably with 3 to 20 carbon atoms) with a sulfur atom with which these are bonded. A hydrogen atom which is included in the monovalent aliphatic hydrocarbon group and the divalent aliphatic hydrocarbon group may be substituted with a hydroxy group and hydrogen atoms which are included in the monovalent aromatic hydrocarbon group, the divalent aromatic hydrocarbon group, and the hetero-ring may be substituted with a hydroxy group, an aliphatic hydrocarbon group (preferably with 1 to 12 carbon atoms), or an alkoxy group (preferably with 1 to 12 carbon atoms). In addition, a methylene group which configures the monovalent aliphatic hydrocarbon group and the divalent aliphatic hydrocarbon group may be substituted with an oxygen atom or a carbonyl group.

X¹ represents a divalent aliphatic saturated hydrocarbon group (preferably with 1 to 10 carbon atoms). X² represents an oxylcarbonyl group, a carbonyloxy group, or an oxygen atom.]

A monovalent aliphatic hydrocarbon group of A¹ and A² is typically an alkyl group or an alicyclic hydrocarbon group and specific examples thereof include the examples already illustrated in a range of 18 or less carbon atoms. Among these, an aliphatic hydrocarbon group (preferably with 1 to 12 carbon atoms) is preferable.

Specific examples of a monovalent aromatic hydrocarbon group of A¹ and A² include the examples already illustrated in a range of with 6 to 18 carbon atoms. The monovalent aromatic hydrocarbon group may, for example, include an alkyl group and the number of carbon atoms of the aromatic hydrocarbon group of A¹ and A² includes the number of carbon atoms of the alkyl group. Specific examples of aromatic hydrocarbon groups and aromatic hydrocarbon groups which have an alkyl group include a phenyl group, a naphthyl group, an anthranil group, a p-methylphenyl group, a p-tert-butylphenyl group, a p-adamantylphenyl group, a tolyl group, a xylyl group, a cumenyl group, a mesityl group, a biphenyl group, an anthryl group, a phenanetolyl group, a 2,6-diethylphenyl group, a 2-methyl-6-ethylphenyl, and the like.

A³ represents a divalent aliphatic hydrocarbon group or a divalent aromatic hydrocarbon group. Specific examples of the divalent aliphatic hydrocarbon group and the divalent aromatic hydrocarbon group include the examples already illustrated in a range of each number of carbon atoms. Here, the methylene group which configures a divalent aliphatic hydrocarbon group of A³ may be substituted with an oxygen atom or a carbonyl group.

In addition, specific examples of a case where A¹ and A² are bonded with each other to form a hetero-ring with a sulfur atom with which these are bonded are included in Formula (I1).

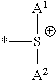

Examples thereof include cases where the partial structure shown by the formula described above is any of the following structure.

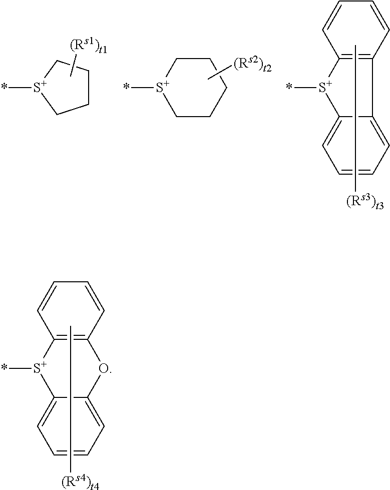

In these formulas, R^{s1}, R^{s2}, R^{s3}, and R^{s4} each independently represents a hydroxy group, an alkyl group with 1 to 12 carbon atoms, an alkoxy group (preferably with 1 to 12 carbon atoms), or an alicyclic hydrocarbon group (preferably with 3 to 12 carbon atoms). In addition, t1 represents an integer of 0 to 4, t2 represents an integer of 0 to 5, t3 represents an integer of 0 to 8, and t4 represents an integer of 0 to 8. Here, the alkyl group, the alkoxy group, and the alicyclic hydrocarbon group include the examples already illustrated where each number of carbon atoms is in each range.

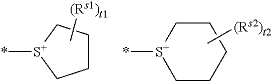

With regard to the partial structure described above out of these, one or two methylene groups which configure a ring may be substituted with an oxygen atom or a carbonyl group.

Here, the number of carbon atoms of a hetero-ring formed by A¹ and A² bonding with each other is more preferably in a range of 4 to 6.

On the other hand, specific examples of a case where A¹ and A³ are bonded with each other to form a hetero-ring with a sulfur atom with which these are bonded include

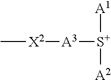

a case where a partial structure which is shown by Formula (I1) above is any of the following structures.

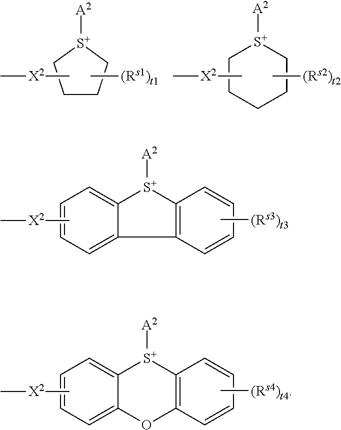

In these formulas, R^{s1}, R^{s2}, R^{s3}, R^{s4}, t1, t2, t3, t4, A², and X² represent the same meanings as above.

A monovalent aromatic hydrocarbon group of A¹ and A², a divalent aromatic hydrocarbon group of A³, or a hetero-ring which is formed by A¹ and A² or A³ being bonded may have an aliphatic hydrocarbon group such as an alkyl group and an alicyclic hydrocarbon group, or an alkoxy group as described above. Specific examples of the aliphatic hydrocarbon group and the alkoxy group here include the examples already illustrated in a range of each number of carbon atoms and the number of carbon atoms of the aromatic hydrocarbon group and the hetero-ring includes the number of carbon atoms in the substituent.

Description was given above of A¹ to A³ of Formula (I1) while showing the specific examples; however, at least one of A¹ to A³ is preferably a group which includes an aromatic ring.

A¹ and A² are more preferably each independently a phenyl group or a naphthyl group and both A¹ and A² are even more preferably a phenyl group.

A³ is more preferably a phenylene group and even more preferably a p-phenylene group.

Specific examples of a compound which is represented by Formula (I1) will be shown below.

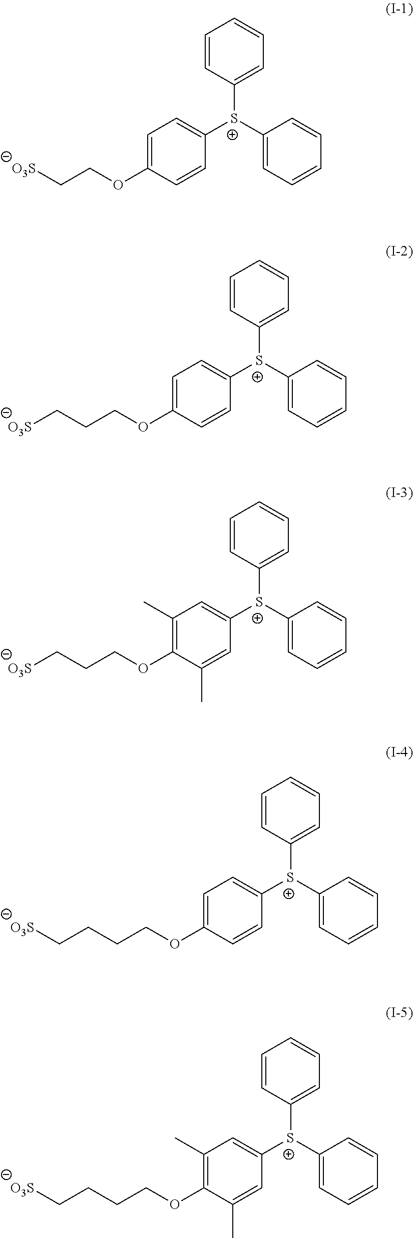

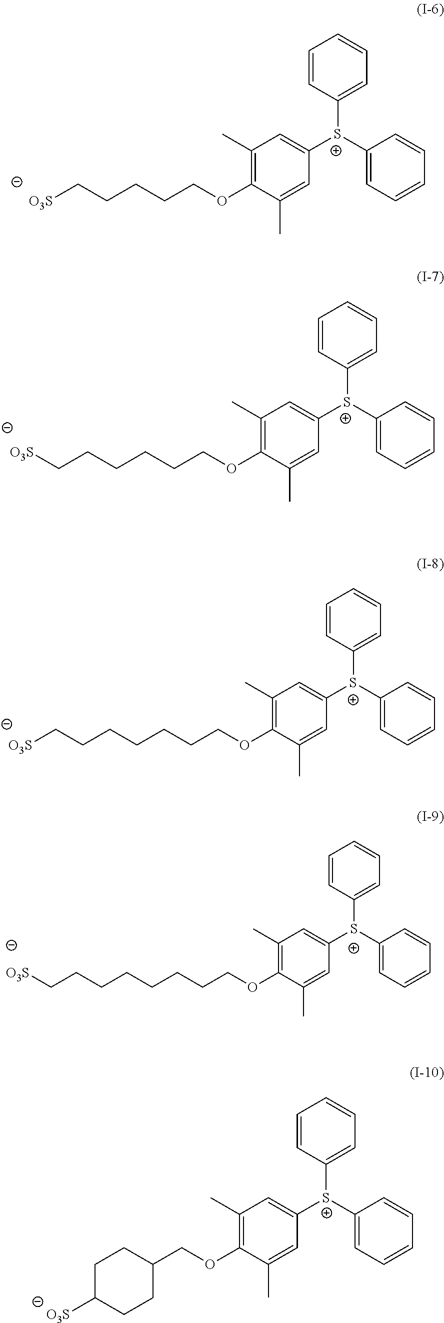

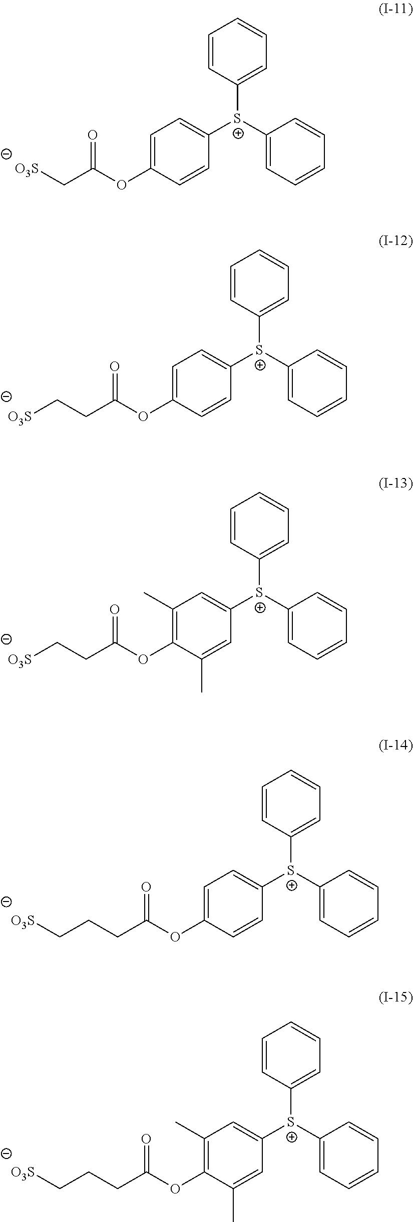

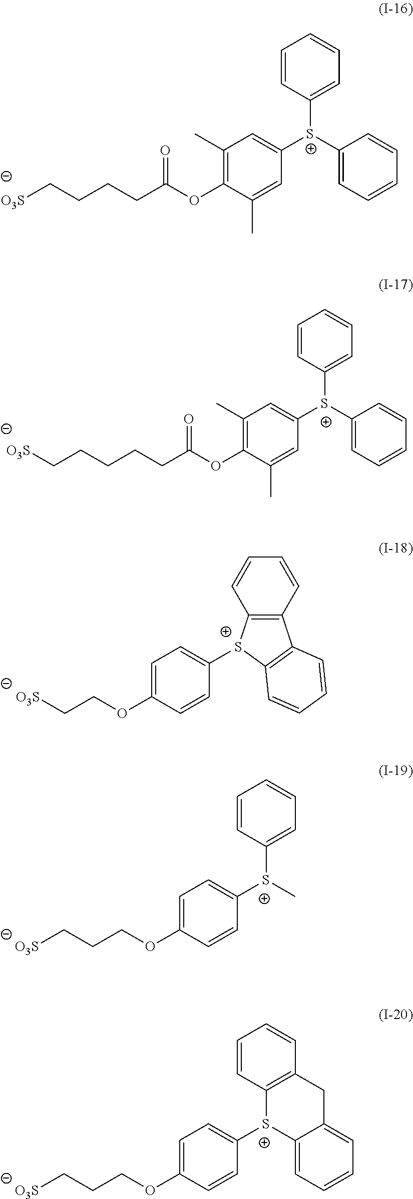

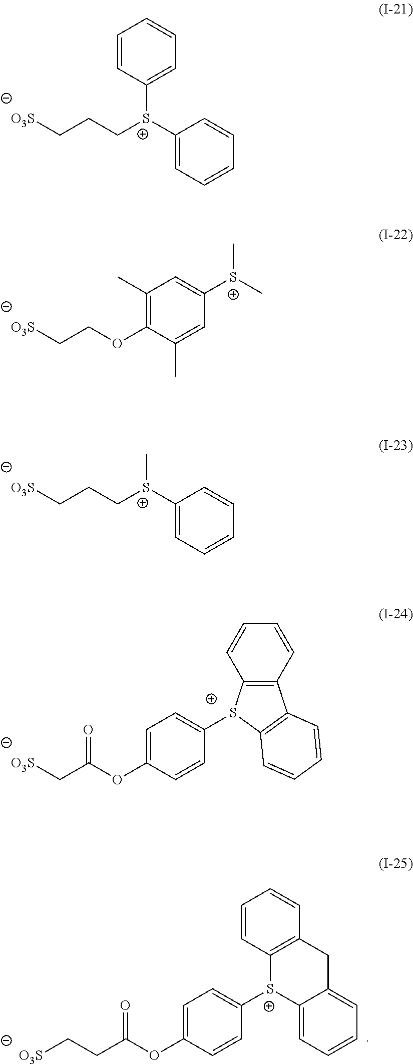

As the compound (C), a compound which is represented by Formula (I2) described below is also preferable.

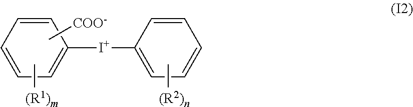

[In Formula (I2), R¹ and R² each independently represents a hydrocarbon group (preferably with 1 to 12 carbon atoms), an alkoxy group (preferably with 1 to 6 carbon atoms), an acyl group (preferably with 2 to 7 carbon atoms), an acyloxy group (preferably with 2 to 7 carbon atoms), an alkoxycarbonyl group (preferably with 2 to 7 carbon atoms), a nitro group, or a halogen atom. m and n each independently represents an integer of 0 to 4 and a plurality of R¹ may be the same or may be different in a case where m is 2 or more, and a plurality of R² may be the same or may be different in a case where n is 2 or more.]

Examples of a hydrocarbon group of R¹ and R² include an aliphatic hydrocarbon group, an alicyclic hydrocarbon group, an aromatic hydrocarbon group, or combinations thereof.

Examples of the aliphatic hydrocarbon group include alkyl groups such as a methyl group, an ethyl group, a propyl group, an isopropyl group, a butyl group, an isobutyl group, a t-butyl group, a pentyl group, a hexyl group, and a nonyl group.

The alicyclic hydrocarbon group may be either monocyclic or polycyclic and may be either saturated or unsaturated. Examples thereof include cycloalkyl groups such as a cyclopropyl group, a cyclobutyl group, a cyclopentyl group, a cyclohexyl group, a cyclononyl group, and a cyclododecyl group, a norbornyl group, an adamantyl group, and the like. In particular, an alicyclic hydrocarbon is preferable.

Examples of the aromatic hydrocarbon groups include aryl groups such as a phenyl group, a 1-naphthyl group, a 2-naphthyl group, a 2-methylphenyl group, a 3-methylphenyl group, a 4-methylphenyl group, a 4-ethylphenyl group, a 4-propylphenyl group, a 4-isopropylphenyl group, a 4-butylphenyl group, a 4-t-butylphenyl group, a 4-hexylphenyl group, a 4-cyclohexylphenyl group, an anthranil group, p-adamantylphenyl group, a tolyl group, a xylyl group, a cumenyl group, a mesityl group, a biphenyl group, an anthryl group, a phenanetolyl group, a 2,6-diethylphenyl group, and 2-methyl-6-ethylphenyl, and the like.

Examples of combinations thereof include an alkyl-cycloalkyl group, a cycloalkyl-alkyl group, an aralkyl group (for example, a phenylmethyl group, a 1-phenylethyl group, a 2-phenylethyl group, a 1-phenyl-1-propyl group, a 1-phenyl-2-propyl group, a 2-phenyl-2-propyl group, a 3-phenyl-1-propyl group, a 4-phenyl-1-butyl group, a 5-phenyl-1-pentyl group, a 6-phenyl-1-hexyl group, and the like), and the like.

Examples of the alkoxy group include a methoxy group, an ethoxy group, and the like.

Examples of the acyl group include an acetyl group, a propanoyl group, a benzoyl group, a cyclohexanecarbonyl group, and the like.

Examples of the acyloxy group include a group where an oxy group (—O—) is bonded with the acyl group described above and the like.

Examples of the alkoxycarbonyl group include a group where a carbonyl group (—CO—) is bonded with the alkoxy group described above and the like.

Examples of the halogen atom include a fluorine atom, a chlorine atom, a bromine atom, and the like.

In Formula (I2), R¹ and R² are each independently preferably an alkyl group with 1 to 8 carbon atoms, a cycloalkyl group with 3 to 10 carbon atoms, an alkoxy group with 1 to 6 carbon atoms, an acyl group with 2 to 4 carbon atoms, an acyloxy group with 2 to 4 carbon atoms, an alkoxycarbonyl group with 2 to 4 carbon atoms, a nitro group, or a halogen atom.

m and n are each independently preferably an integer of 0 to 2.

Examples of the compound which is represented by Formula (I2) include the compounds below.

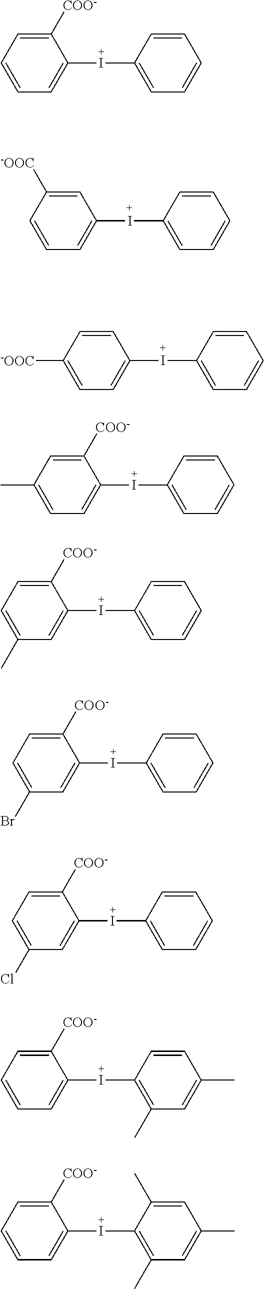

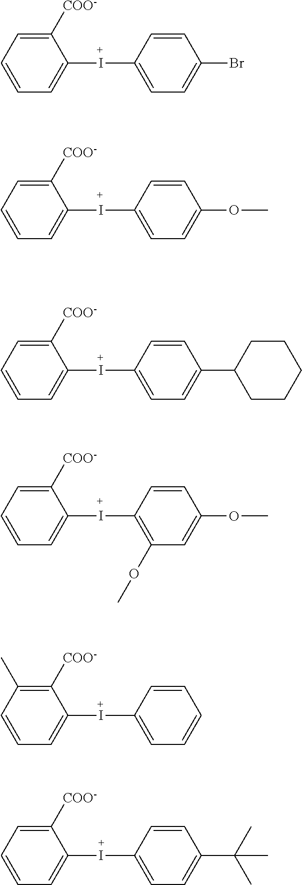

As the compound (C), a compound which is represented by Formula (I3) below is also preferable.

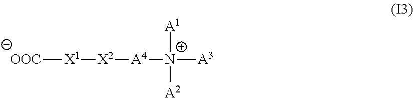

[In Formula (I3), A¹, A², and A³ each independently represents a hydrogen atom, a monovalent aliphatic hydrocarbon group (preferably with 1 to 18 carbon atoms), or a monovalent aromatic hydrocarbon group (preferably with 6 to 18 carbon atoms) and A⁴ represents a divalent aliphatic hydrocarbon group (preferably with 1 to 18 carbon atoms) or a divalent aromatic hydrocarbon group (preferably with 6 to 18 carbon atoms). A² and A³ or A⁴ may be bonded with each other to form a hetero-ring (preferably with 3 to 20 carbon atoms) with a nitrogen atom with which these are bonded. A hydrogen atom which is included in the monovalent aliphatic hydrocarbon group and the divalent aliphatic hydrocarbon group may be substituted with a hydroxy group and hydrogen atoms which are included in the monovalent aromatic hydrocarbon group, the divalent aromatic hydrocarbon group, and the hetero-ring may be substituted with a hydroxy group, an aliphatic hydrocarbon group (preferably with 1 to 12 carbon atoms), or an alkoxy group (preferably with 1 to 12 carbon atoms). In addition, a methylene group which configures the monovalent aliphatic hydrocarbon group and the divalent aliphatic hydrocarbon group may be substituted with an oxygen atom or a carbonyl group.

X¹ represents a divalent aliphatic hydrocarbon group (preferably with 1 to 10 carbon atoms).

X² represents a single bond, an oxycarbonyl group, a carbonyloxy group, or an oxygen atom.]

A monovalent aliphatic hydrocarbon group of A¹, A², and A³ is typically an alkyl group or an alicyclic hydrocarbon group and specific examples thereof include the examples already illustrated in a range of 18 or less carbon atoms. Among these, an aliphatic hydrocarbon group with 1 to 12 carbon atoms is preferable.

Specific examples of a monovalent aromatic hydrocarbon group of A¹, A², and A³ include the examples already illustrated in a range of 6 to 18 carbon atoms. The monovalent aromatic hydrocarbon group, for example, may have an alkyl group and the number of carbon atoms of the aromatic hydrocarbon group includes the number of carbon atoms of the alkyl group. Specific examples of aromatic hydrocarbon groups and aromatic hydrocarbon groups which have an alkyl group include a phenyl group, a naphthyl group, an anthranil group, a p-methylphenyl group, a p-tert-butylphenyl group, a p-adamantylphenyl group, a tolyl group, a xylyl group, a cumenyl group, a mesityl group, a biphenyl group, an anthryl group, a phenanetolyl group, a 2,6-diethylphenyl group, a 2-methyl-6-ethylphenyl, and the like.

A⁴ represents a divalent aliphatic hydrocarbon group or a divalent aromatic hydrocarbon group. Specific examples of the divalent aliphatic hydrocarbon group and the divalent aromatic hydrocarbon group include the examples already illustrated in a range of each number of carbon atoms. Here, the methylene group which configures a divalent aliphatic hydrocarbon group of A⁴ may be substituted with an oxygen atom or a carbonyl group.

In addition, specific examples of a case where A² and A³ are bonded with each other to form a hetero-ring with a nitrogen atom with which these are bonded are included in Formula (I3).

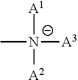

Examples thereof include a case where the partial structure shown by the formula described above is any of the following structures.

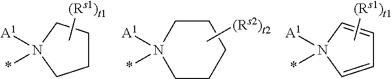

In these formulas, R^{s1} and R^{s2} each independently represents a hydroxy group, an alkyl group (preferably with 1 to 12 carbon atoms), an alkoxy group (preferably with 1 to 12 carbon atoms), or an alicyclic hydrocarbon group (preferably with 3 to 12 carbon atoms). In addition, t1 represents an integer of 0 to 4 and t2 represents an integer of 0 to 5. Here, specific examples of each of the alkyl group, the alkoxy group, and the alicyclic hydrocarbon group include the examples already illustrated where each number of carbon atoms is in each range. In addition, with regard to the partial structure below out of these,

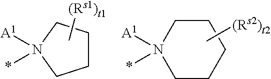

One or two methylene groups which configure a ring may be substituted with an oxygen atom or a carbonyl group. Here, the number of carbon atoms of a hetero-ring formed by A² and A³ bonding with each other is more preferably in a range of 4 to 6.

On the other hand, specific examples of a case where A² and A⁴ are bonded with each other to form a hetero-ring with a sulfur atom with which these are bonded include cases of any of the following structures.

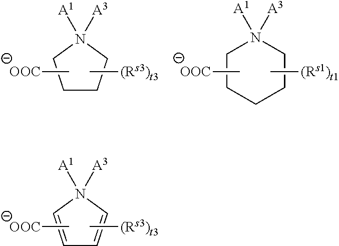

In these formulas, R^{s1} and t1 represent the same meanings as above. R^{s3} represents a hydroxy group, an alkyl group (preferably with 1 to 12 carbon atoms), an alkoxy group (preferably with 1 to 12 carbon atoms), or an alicyclic hydrocarbon group (preferably with 3 to 12 carbon atoms). In addition, t3 represents an integer of 0 to 2.

On the other hand, specific examples of a case where A², A³, and A⁴ are bonded with each other to form a hetero-ring with a sulfur atom with which these are bonded include cases of any of the following structures.

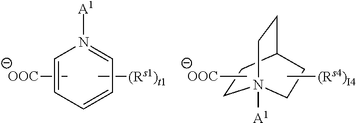

In these formulas, R^{s1} and t2 represent the same meanings as above. R^{s4} represents a hydroxy group, an alkyl group (preferably with 1 to 12 carbon atoms), an alkoxy group (preferably with 1 to 12 carbon atoms), or an alicyclic hydrocarbon group (preferably with 3 to 12 carbon atoms). In addition, t4 represents an integer of 0 to 6.

A monovalent aromatic hydrocarbon group of A¹ and A², a divalent aromatic hydrocarbon group of A³, or a hetero-ring which is formed by A¹ and A² or A³ being bonded may have an aliphatic hydrocarbon group such as an alkyl group and an alicyclic hydrocarbon group, or an alkoxy group as described above. Specific examples of each of the aliphatic hydrocarbon group and the alkoxy group here include the examples already illustrated in a range of each number of carbon atoms and the number of carbon atoms of the aromatic hydrocarbon group and the hetero-ring includes the number of carbon atoms of the substituent.

Description was given above of A¹ to A³ in the compound which is represented by Formula (I3) while showing specific examples thereof; however, A¹ is preferably a hydrogen atom or a methyl group.

A² and A³ are preferably each independently a methyl group, an ethyl group, a propyl group, or a butyl group and it is more preferable to be a methyl group, an ethyl group, or a propyl group.

Specific examples of a compound which is represented by Formula (I3) will be shown below.

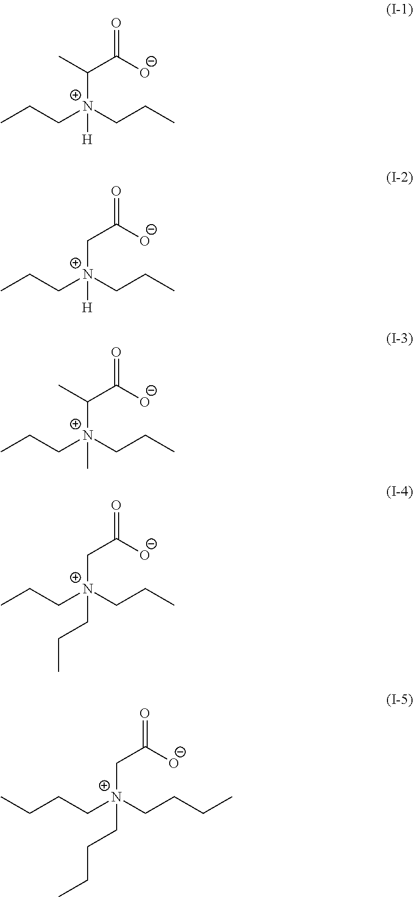

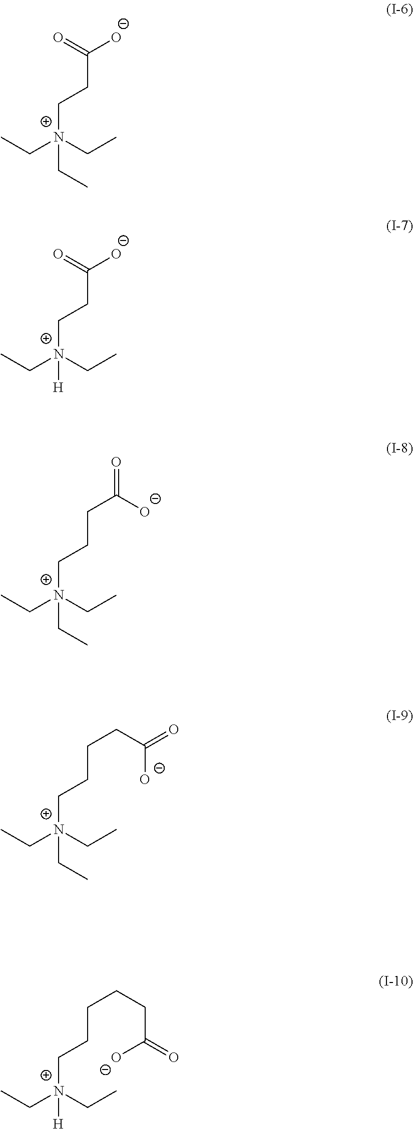

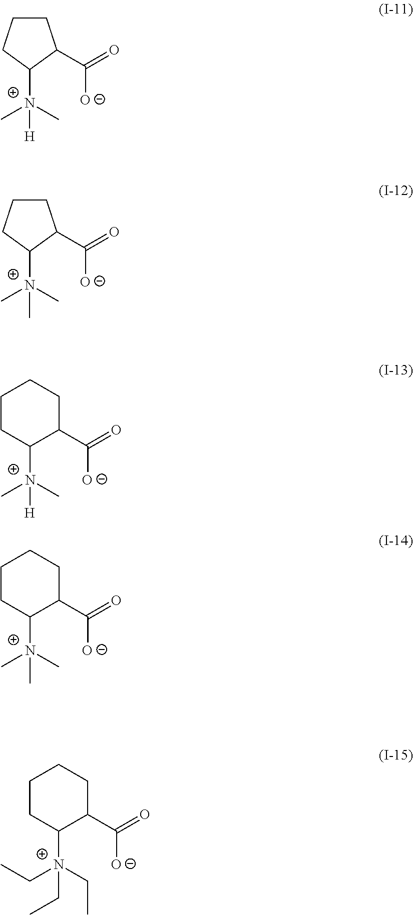

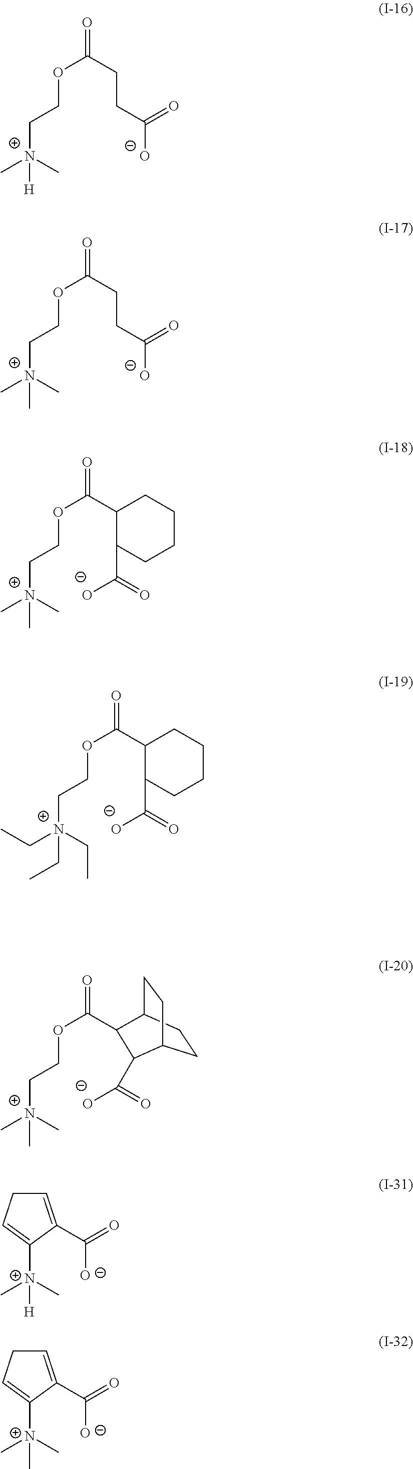

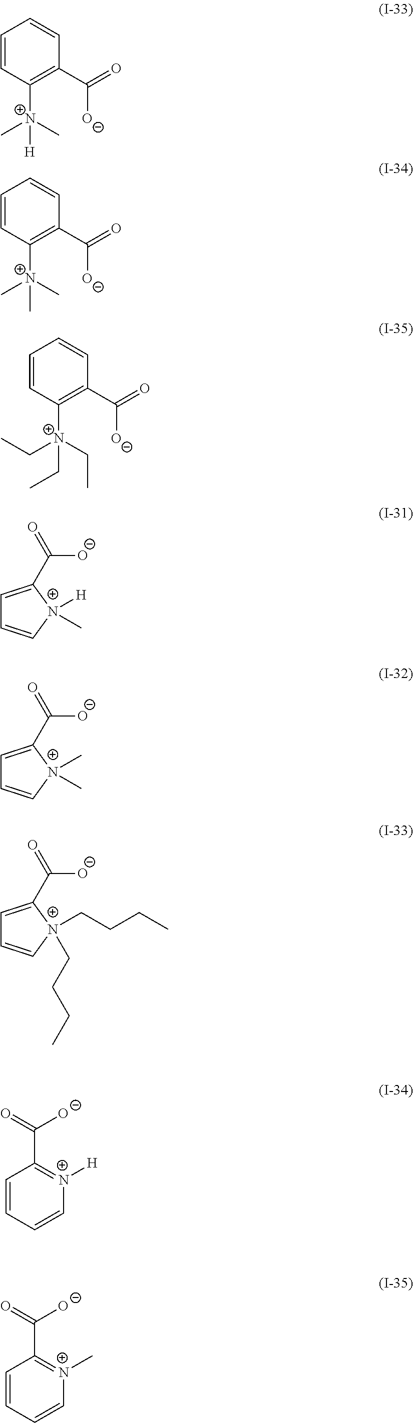

Specific examples of a compound which is represented by general Formula (C-4) described above include the compounds below.

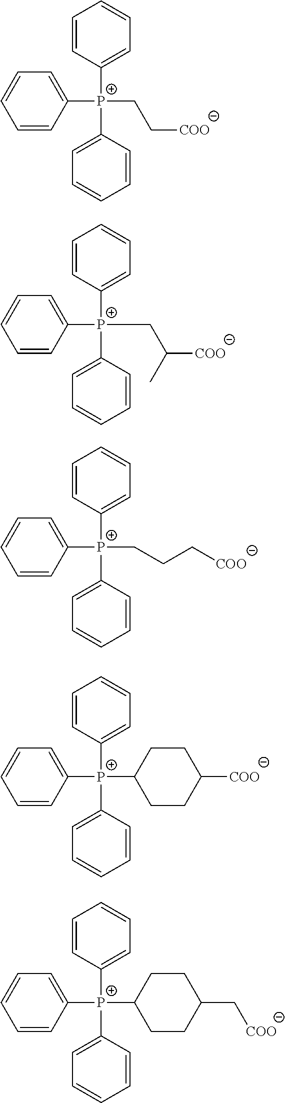

The compound (C) may be used as one type, or a plurality of types may be used. The content of the compound (C) in an actinic ray-sensitive or radiation-sensitive resin composition (the total amount in a case of using a plurality of types) is preferably 0.01 mass % to 15 mass %, more preferably 0.05 mass % to 10 mass %, even more preferably 0.1 mass % to 5 mass %, and particularly preferably 0.03 mass % to 3 mass % using the total solid content of the actinic ray-sensitive or radiation-sensitive resin composition as a reference.

(HR) Hydrophobic Resin

The actinic ray-sensitive or radiation-sensitive resin composition of the present invention may contain a hydrophobic resin (also referred to below as a “hydrophobic resin (HR)”) when particularly applied to liquid immersion exposure. The hydrophobic resin (HR) is a resin where the surface free energy is relatively small compared to the resin (A) and due to this, the hydrophobic resin (HR) is unevenly distributed in the surface of a resist film and, in a case where the liquid immersion medium is water, it is possible to improve the static/dynamic contact angle of the resist film surface with respect to the water and improve liquid immersion liquid conformance.

The hydrophobic resin (HR) is unevenly distributed in an interface as described above; however, unlike a surfactant, it is not necessary to have a hydrophilic group in a molecule or to contribute to the uniform mixing of polar/nonpolar substances.

The hydrophobic resin (HR) preferably includes a fluorine atom and/or a silicon atom. The fluorine atom and/or the silicon atom in the hydrophobic resin (HR) may be included in the main chain of a resin or may be included in a side chain. In addition, the hydrophobic resin (HR) also preferably has a hydrophobic group such as a branched alkyl group or a long chain alkyl group (preferably with 4 or more carbon atoms, more preferably with 6 or more carbon atoms, and particularly preferably with 8 or more carbon atoms).

Use is possible by appropriately adjusting the content of the hydrophobic resin (HR) in the actinic ray-sensitive or radiation-sensitive resin composition such that a receding contact angle of an actinic ray-sensitive or radiation-sensitive resin film is within this range; however, 0.01 mass % to 20 mass % is preferable, 0.1 mass % to 15 mass % is more preferable, 0.1 mass % to 10 mass % is even more preferable, and 0.2 mass % to 8 mass % is particularly preferable using the total solid content of the actinic ray-sensitive or radiation-sensitive resin composition as a reference. The hydrophobic resin (HR) may be used as one type, or a plurality of types may be used.

The hydrophobic resin (HR) may have a structural unit which is derived from a compound which is represented by Formula (a) (referred to below as “compound (a)”).

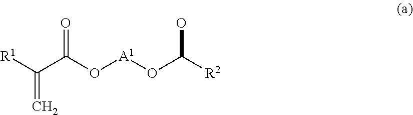

[In Formula (a), R¹ represents a hydrogen atom or a methyl group.

R² represents an aliphatic hydrocarbon group (preferably with 1 to 18 carbon atoms) which may have a substituent.

A¹ represents an alkanediyl group (preferably with 1 to 6 carbon atoms) which may have a substituent, or a group which is represented by Formula (a-g1).

-A¹⁰X¹⁰-A¹¹_{S}X¹¹-A¹²- (a-g1)

(In Formula (a-g1), s represents 0 or 1.

A¹⁰ and A¹² each independently represents an aliphatic hydrocarbon group (preferably 1 to 5 carbon atoms) which may have a substituent.

A¹¹ represents an aliphatic hydrocarbon group (preferably with 1 to 5 carbon atoms) which may have a substituent or a single bond. X¹⁰ and X¹¹ each independently represents an oxygen atom (the oxygen atom may be shown with “—O—” in the present specification), a carbonyl group (the carbonyl group may be shown with “—CO—” in the present specification), a carbonyloxy group (the carbonyloxy group may be shown with “—CO—O—” in the present specification), or an oxycarbonyl group (the oxycarbonyl group may be shown with “—O—CO—” in the present specification).

However, the total number of the carbon atoms of A¹⁰, A¹¹, A¹², X¹⁰, and X¹¹ is 6 or less.)]

A¹ is a group which is represented by an alkanediyl group with 1 to 6 carbon atoms or by Formula (a-g1) (referred to below as “group (a-g1)”).

An alkanediyl group of A¹ may be linear or branched and examples thereof include a methylene group, an ethylene group, a propanediyl group, a butanediyl group, a pentanediyl group, a hexanediyl group, and the like.

A hydrogen atom which configures the alkanediyl group may be substituted with a substituent. Examples of the substituent include a hydroxy group, an alkoxy group with 1 to 6 carbon atoms, and the like.

Below, specific examples of a group (a-g1) will be shown. In the description of the specific examples, the left and right match Formula (a) and, out of the two atomic bonds which are each shown with *, the atomic bond on the left side is bonded with an oxygen atom on R¹ side and the atomic bond on the right side is bonded with an oxygen atom on R² side.

Examples of a group (a-g1) which has an oxygen atom include

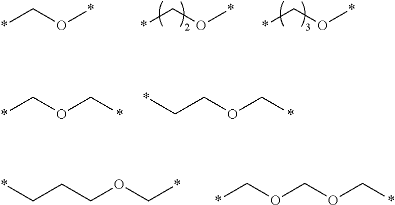

and the like (* represents an atomic bond).

Examples of a group (a-g1) which has a carbonyl group include

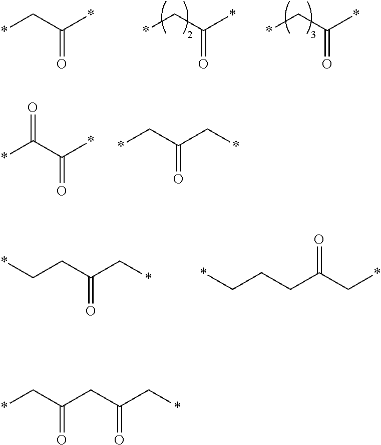

and the like (* represents an atomic bond).

Examples of a group (a-g1) which has a carbonyloxy group include the following group,

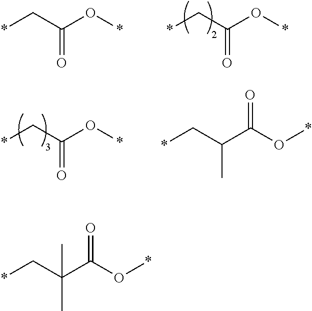

and the like (* represents an atomic bond).

Examples of a group (a-g1) which has an oxycarbonyl group include the following group,

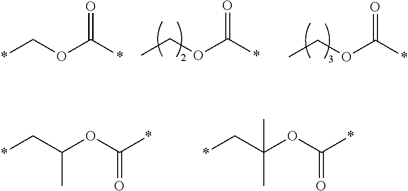

and the like (* represents an atomic bond).

Among these, A¹ is preferably an alkanediyl group, an alkanediyl group which does not have a substituent is more preferable, an alkanediyl group with 1 to 4 carbon atoms is even more preferable, and an ethylene group is particularly preferable.

An aliphatic hydrocarbon group of R² may have a carbon-carbon unsaturated bond; however, an aliphatic saturated hydrocarbon group is preferable.

Examples of the aliphatic saturated hydrocarbon groups include an alkyl group (the alkyl group may be straight-chain or branched), an alicyclic hydrocarbon group, an aliphatic hydrocarbon group combining an alkyl group and an alicyclic hydrocarbon group, and the like.

Examples of the alkyl group include a methyl group, an ethyl group, a propyl group, a butyl group, a pentyl group, a hexyl group, a heptyl group, an octyl group, and the like.

The alicyclic hydrocarbon group may be either monocyclic or polycyclic. Examples of the monocyclic alicyclic hydrocarbon group include cycloalkyl groups such as a cyclopentyl group, a cyclohexyl group, a methylcyclohexyl group, dimethylcyclohexyl group, a cycloheptyl group, and a cyclooctyl group. Examples of the polycyclic alicyclic hydrocarbon group include a decahydronaphthyl group, an adamantyl group, a norbornyl group, a methylnorbornyl group, groups which are shown below, and the like.

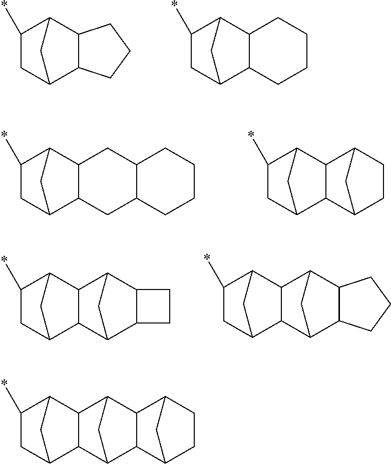

An aliphatic hydrocarbon group of R² may have or may not have a substituent; however, R² is preferably an aliphatic hydrocarbon group which has a substituent.

As the substituent of R², a halogen atom or a group which is represented by Formula (a-g3) (referred to below as a “group (a-g3)”) is preferable.

—X¹²-A¹⁴ (a-g3)

(In Formula (a-g3), X¹² represents an oxygen atom, a carbonyl group, a carbonyloxy group, or an oxycarbonyl group.

A¹⁴ represents an aliphatic hydrocarbon group (preferably with 3 to 17 carbon atoms) which may have a halogen atom.)

An aliphatic hydrocarbon group which has a halogen atom is typically an alkyl group which has a halogen atom or an alicyclic hydrocarbon group which has a halogen atom (preferably a cycloalkyl group which has a halogen atom).

An alkyl group which has a halogen atom is an alkyl group where a hydrogen atom which configures the alkyl group is substituted with a halogen atom. In the same manner, an alicyclic hydrocarbon group which has a halogen atom is an alicyclic hydrocarbon group where a hydrogen atom which configures the alicyclic hydrocarbon group is substituted with a halogen atom.

Examples of the halogen atom include a fluorine atom, a chlorine atom, a bromine atom, or an iodine atom, and a fluorine atom is preferable.

The aliphatic hydrocarbon group which has a halogen atom of R² is preferably a perfluoroalkyl group where all of the hydrogen atoms which configure an alkyl group are substituted with fluorine atoms, or a perfluorocycloalkyl group where all of the hydrogen atoms which configure a cycloalkyl group are substituted with fluorine atoms. Among these, a perfluoroalkyl group is preferable, a perfluoroalkyl group with 1 to 6 carbon atoms is more preferable, and a perfluoroalkyl group with 1 to 3 carbon atoms is even more preferable. Examples of the perfluoroalkyl group include a trifluoromethyl group, perfluoroethyl group, a perfluoropropyl group, a perfluorobutyl group, a perfluoropentyl group, a perfluorohexyl group, a perfluoroheptyl group, a perfluorooctyl group, and the like.

X¹²′ is preferably a carbonyloxy group or an oxycarbonyl group.

Examples of a compound (a) where R² is an aliphatic hydrocarbon group which has a fluorine atom and A¹ is an ethylene group include compounds which are represented by Formula (a1) to Formula (a16) below.

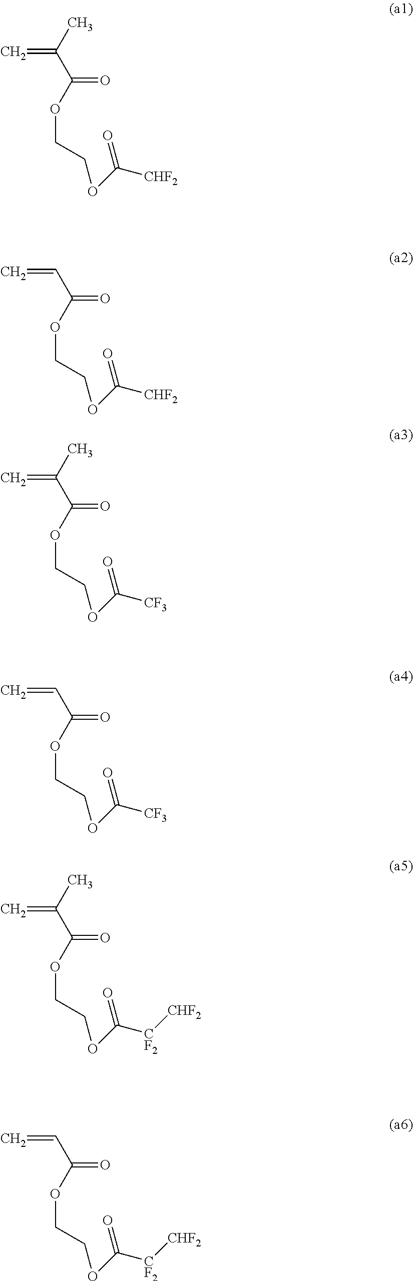

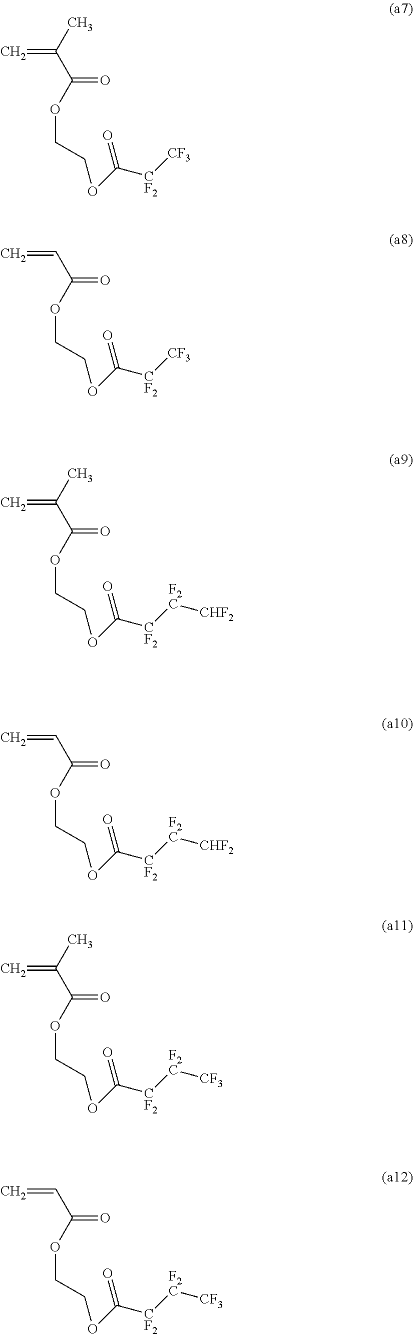 [SMILES: C=C(C)C(=O)OCCOC(=O)C(F)(F)C(F)(F)F ; C=CC(=O)OCCOC(=O)C(F)(F)C(F)(F)F ; C=C(C)C(=O)OCCOC(=O)C(F)(F)C(F)(F)C(F)F ; C=CC(=O)OCCOC(=O)C(F)(F)C(F)(F)C(F)F ; C=C(C)C(=O)OCCOC(=O)C(F)(F)C(F)(F)C(F)(F)F ; C=CC(=O)OCCOC(=O)C(F)(F)C(F)(F)C(F)(F)F]

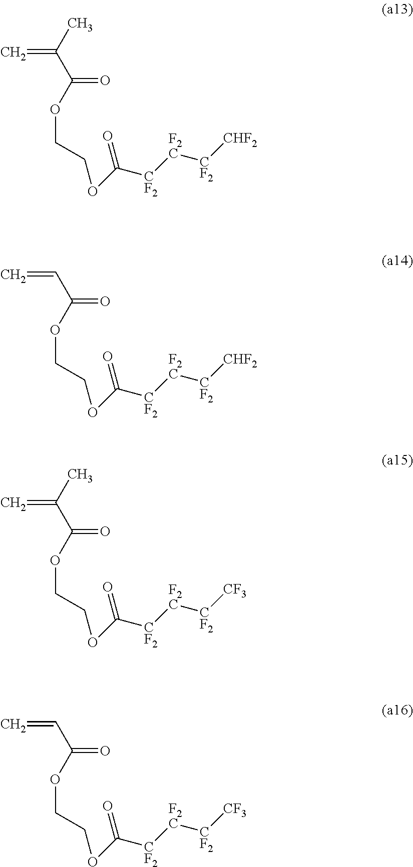 [SMILES: C=C(C)C(=O)OCCOC(=O)C(F)(F)C(F)(F)C(F)(F)C(F)F ; C=CC(=O)OCCOC(=O)C(F)(F)C(F)(F)C(F)(F)C(F)F ; C=C(C)C(=O)OCCOC(=O)C(F)(F)C(F)(F)C(F)(F)C(F)(F)F ; C=CC(=O)OCCOC(=O)C(F)(F)C(F)(F)C(F)(F)C(F)(F)F]

A compound (a) where R² is a perfluoroalkyl group or a perfluorocycloalkyl group corresponds to compounds which are represented by any of Formula (a3), Formula (a4), Formula (a7), Formula (a8), Formula (a11), Formula (a12), Formula (a15), and Formula (a16) in the specific examples described above.

An aliphatic hydrocarbon group which has a group which is represented by Formula (a-g3) may have one or a plurality of groups (a-g3); however, including the number of carbon atoms which are included in the groups (a-g3), the total number of carbon atoms of the aliphatic hydrocarbon group is preferably 15 or less, and more preferably 12 or less. In order to satisfy the preferable total number of carbon atoms, a group which has one group (a-g3) is preferable as R².

An aliphatic hydrocarbon group which has a group (a-g3), that is, R² which has a group (a-g3), is preferably a group which is represented by Formula (a-g2) below (referred to below as “group (a-g2)”).

-A¹³-X¹²-A¹⁴ (a-g2)

(In Formula (a-g2), A¹³ represents an aliphatic hydrocarbon group which may have a halogen atom (preferably with 3 to 17 carbon atoms).

X¹² represents a carbonyloxy group or an oxycarbonyl group.

A¹⁴ represents an aliphatic hydrocarbon group (preferably with 3 to 17 carbon atoms) which may have a halogen atom.

However, the total number of carbon atoms of A¹³, A¹⁴, and X¹² is 18 or less.)

Preferable examples of the group (a-g2) (* is an atomic bond with a carbonyl group) include the structures below.

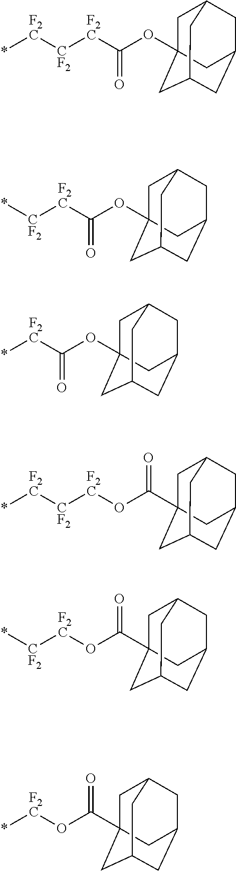 [SMILES: *C(F)(F)C(F)(F)C(F)(F)C(=O)OC12CC3CC(CC(C3)C1)C2 ; *C(F)(F)C(F)(F)C(=O)OC12CC3CC(CC(C3)C1)C2 ; *C(F)(F)C(=O)OC12CC3CC(CC(C3)C1)C2 ; *C(F)(F)C(F)(F)C(F)(F)OC(=O)C12CC3CC(CC(C3)C1)C2 ; *C(F)(F)C(F)(F)OC(=O)C12CC3CC(CC(C3)C1)C2 ; *C(F)(F)OC(=O)C12CC3CC(CC(C3)C1)C2]

A compound (a) where R² is an aliphatic hydrocarbon group which has one group which is represented by Formula (a-g3), that is, a compound (a) where R² is a group which is represented by Formula (a-g2) is specifically a compound which is represented by Formula (a′) below (referred to below as “compound (a′)”).

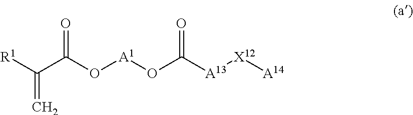

[In Formula (a′), A¹³ represents an aliphatic hydrocarbon group which may have a halogen atom (preferably with 3 to 17 carbon atoms).

X¹² represents a carbonyloxy group or an oxycarbonyl group.

A¹⁴ represents an aliphatic hydrocarbon group (preferably with 3 to 17 carbon atoms) which may have a halogen atom.

However, the total number of carbon atoms of A¹³ and A¹⁴ is 17 or less.

A1 and R1 have the same meaning as in the above description.]

The compound (a′) is a compound which is useful as a raw material for manufacturing a hydrophobic resin (HR) which is contained in the resist composition and the present invention includes inventions relating to the compound (a′).

In the compound (a′), there are cases where both A¹³ and A¹⁴ have a halogen atom; however, an aliphatic hydrocarbon group where only A¹³ has a halogen atom, or an aliphatic hydrocarbon group where only A¹⁴ has a halogen atom is preferable. Furthermore, aliphatic hydrocarbon groups where only A¹³ has a halogen atom are preferable, and among these, an alkanediyl group where A¹³ has a fluorine atom is more preferable, and a perfluoroalkanediyl group is even more preferable. Here, the “perfluoroalkanediyl group” refers to an alkanediyl group where all the hydrogen atoms are substituted with fluorine atoms.

Examples of a compound (a′) where R² is a perfluoroalkanediyl group and A¹ is an ethylene group include compounds which are represented by Formula (a′1) to Formula (a′10) below.

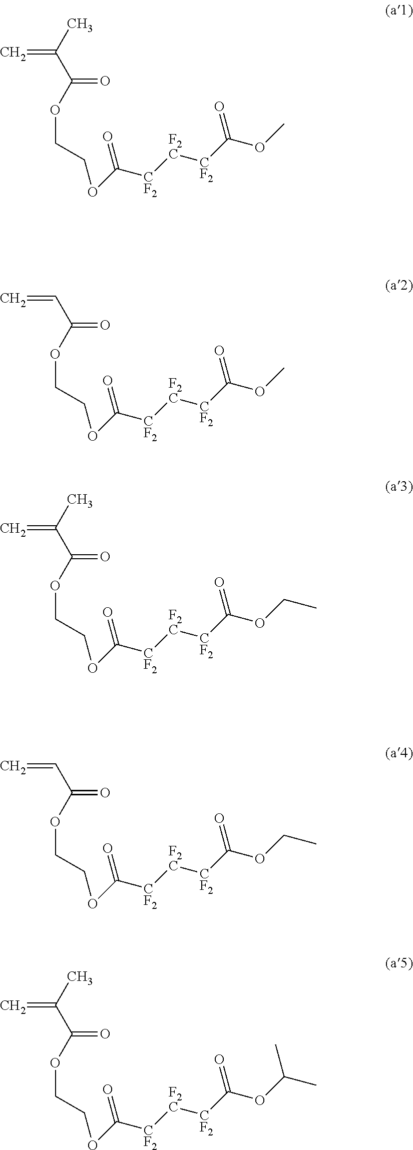

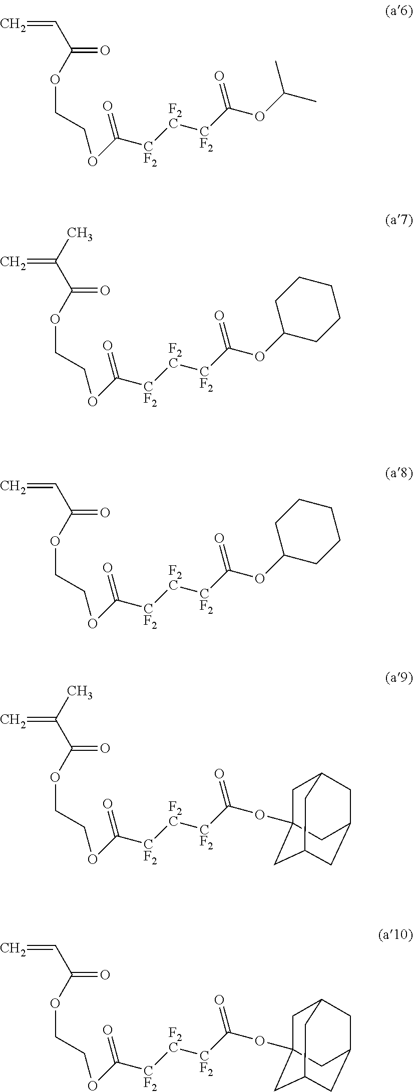

A¹³ and A¹⁴ are arbitrarily selected in a range where the total number of carbon atoms is 17 or less; however, the number of carbon atoms of A¹³ is preferably 1 to 6, and more preferably 1 to 3. The number of carbon atoms of A¹⁴ is preferably 4 to 15, and more preferably 5 to 12. More preferable A¹⁴ is an alicyclic hydrocarbon group with 6 to 12 carbon atoms and a cyclohexyl group and an adamantyl group are preferable as the alicyclic hydrocarbon group.

Basic Compound (Referred to Below as “Basic Compound (E)”)

The resist composition may further contain a basic compound (E) (however, this is different from the compound (C)). The “basic compound” here has the meaning of a compound which has a characteristic which captures acid, in particular, a compound which has a characteristic which captures acid which is generated from the acid generator described above.

A basic compound may be an ionic compound formed of onium cations and weak acid anions such as carbonic acid.

The basic compound (E) is preferably a basic nitrogen-containing organic compound and examples thereof include amine and ammonium hydroxyide. The amine may be an aliphatic amine or an aromatic amine. It is possible to use any of a primary amine, a secondary amine, or a tertiary amine for the aliphatic amine The aromatic amine may be any of an aromatic amine where an amino group is bonded with an aromatic ring such as aniline, or a hetero aromatic amine such as pyridine. Examples of the favorable basic compound (E) include an aromatic amine which is represented by Formula (E2) below, in particular, anilines which are represented by Formula (E2-1).

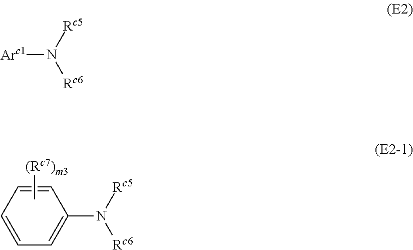

In Formula (E2) and Formula (E2-1), Ar^{c1} represents an aromatic hydrocarbon group.

R^{c5} and R^{c6} each independently represents a hydrogen atom, an aliphatic hydrocarbon group (preferably an aliphatic hydrocarbon group with approximately 1 to 6 carbon atoms, and more preferably an alkyl group with approximately 1 to 6 carbon atoms), an alicyclic hydrocarbon group (preferably an alicyclic hydrocarbon group with approximately 5 to 10 carbon atoms), or an aromatic hydrocarbon group (preferably an aromatic hydrocarbon group with approximately 6 to 10 carbon atoms). However, a hydrogen atom which is included in the aliphatic hydrocarbon group, the alicyclic hydrocarbon group, and the aromatic hydrocarbon group may be substituted with a hydroxy group, an amino group, or an alkoxy group with 1 to 6 carbon atoms, and the amino group may further have an alkyl group with 1 to 4 carbon atoms.

R^{c7} represents an aliphatic hydrocarbon group (preferably an aliphatic hydrocarbon group with approximately 1 to 6 carbon atoms, and more preferably an alkyl group with approximately 1 to 6 carbon atoms), an alkoxy group with approximately 1 to 6 carbon atoms, an alicyclic hydrocarbon group (preferably an alicyclic hydrocarbon group with approximately 5 to 10 carbon atoms, and more preferably a cycloalkyl group with approximately 5 to 10 carbon atoms), or an aromatic hydrocarbon group (preferably an aromatic hydrocarbon group with approximately 6 to 10 carbon atoms). However, a hydrogen atom which is included in the aliphatic hydrocarbon group, the alkoxy group, the alicyclic hydrocarbon group, and the aromatic hydrocarbon group may also be substituted with a hydroxy group, an amino group, or an alkoxy group with 1 to 6 carbon atoms, and the amino group may further have an alkyl group with 1 to 4 carbon atoms.

m3 represents an integer of 0 to 3. When m3 is 2 or more, plurality of R^{c7} may be the same as or may be different from each other.

Examples of an aromatic amine which is represented by Formula (E2) include 1-naphthylamine, 2-naphthylamine, and the like.

Anilines which are represented by Formula (E2-1) include aniline, diisopropylaniline, 2-, 3-, or 4-methylaniline, 4-nitroaniline, N-methylaniline, N,N-dimethylaniline, diphenylamine, and the like.

In addition, a compound which is represented by any of the following Formula (E3), Formula (E4), Formula (E5), Formula (E6), Formula (E7), Formula (E8), Formula (E9), Formula (E10), and Formula (E11) (these compounds are described below as “compound (E3)” to “compound (E11)” according to the formula number) may be used.

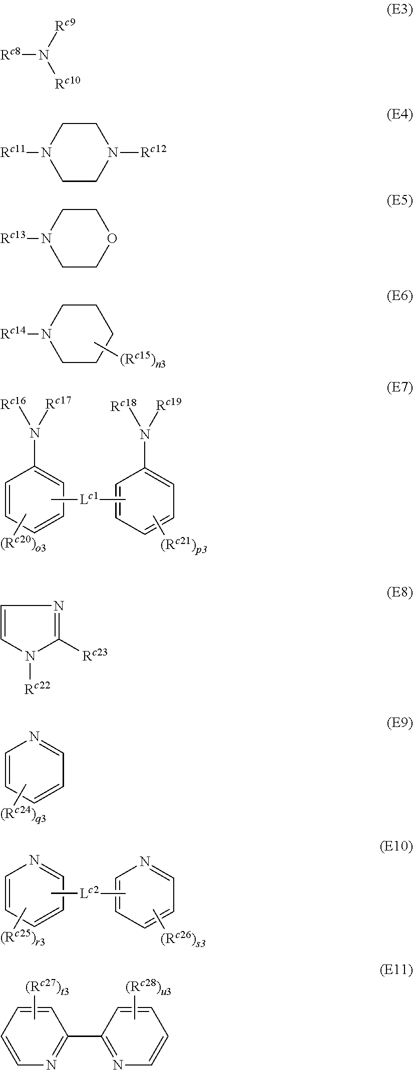

In Formula (E3) to Formula (E11), R^{c8} represents any of the groups described in R^{c7} described above.

R^{c20}, R^{c21}, R^{c23}, R^{c24}, R^{c25}, R^{c26}, R^{c27}, and R^{c28} represent any of the groups described in R^{c7} described above.

R^{c9}, R^{c10}, R^{c11}, R^{c12}, R^{c13}, R^{c14}, R^{c16}, R^{c17}, R^{c18}, R^{c19}, and R^{c22} which bond with the nitrogen atom are each independent and represent any of the groups described in R^{c5} and R^{c6} described above.

o3, p3, q3, r3, s3, t3, and u3 each independently represents an integer of 0 to 3.

A plurality of R^{c20} may be the same as or different from each other when o3 is 2 or more, a plurality of R^{c21} may be the same as or different from each other when p3 is 2 or more, a plurality of R^{c24} may be the same as or different from each other when q3 is 2 or more, a plurality of R^{c25} may be the same as or different from each other when r3 is 2 or more, a plurality of R^{c26} may be the same as or different from each other when s3 is 2 or more, a plurality of R^{c27} may be the same as or different from each other when t3 is 2 or more, and a plurality of R^{c28} may be the same as or different from each other when u3 is 2 or more.

R^{c15} represents an aliphatic hydrocarbon group (preferably an aliphatic hydrocarbon group with approximately 1 to 6 carbon atoms), an alicyclic hydrocarbon group (preferably an alicyclic hydrocarbon group with approximately 3 to 6 carbon atoms), or an alkanoyl group (preferably an alkanoyl group with approximately 2 to 6 carbon atoms).

n3 represents an integer of 0 to 8. When n3 is 2 or more, a plurality of R^{c15} may be the same as or different from each other.

L^{c1} and L^{c2} each independently represents a divalent aliphatic hydrocarbon group (preferably an aliphatic hydrocarbon group with approximately 1 to 6 carbon atoms, and more preferably an alkylene group with approximately 1 to 6 carbon atoms), a carbonyl group, —C(═NH)—, —C(NR^{c3})— (here, R^{c3} represents an alkyl group with 1 to 4 carbon atoms), —S—, —S—S—, or a combination thereof.

An aliphatic hydrocarbon group of R^{c15} preferably has approximately 1 to 6 carbon atoms and an alicyclic hydrocarbon group preferably has approximately 3 to 6 carbon atoms.

Examples of alkanoyl groups include an acetyl group, a 2-methylacetyl group, a 2,2-dimethylacetyl group, a propionyl group, a butylyl group, an isobutylyl group, a pentanoyl group, a 2,2-dimethylpropionyl group, and the like, and the number of carbon atoms is preferably approximately 2 to 6.

Examples of the compound (E3) include hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methylhexylamine, methyldicyclohexylamine, methyldiheptylamine, methyldioctylamine, methyldinonylamine, methyl didecylamine, ethyldibutylamine, ethyldipentylamine, ethyl dihexyl amine, ethyldiheptylamine, ethyldioctylamine, ethyldinonylamine, ethyldidecylamine, dicyclohexylmethylamine, tris[2-(2-methoxyethoxy)ethyl]amine, triisopropanolamine ethylenediamine, tetramethylenediamine, hexamethylenediamine, 4,4′-diamino-1,2-diphenyl ethane, 4,4′-diamino-3,3′dimethyldiphenylmethane, 4,4′-diamino-3,3′-diethyldiphenylmethane, and the like.

Examples of the compound (E4) include piperazine and the like.

Examples of the compound (E5) include morpholine and the like.

Examples of the compound (E6) include piperizine, a hindered amine compound which has a piperizine skeleton which is described in JP1999-52575A (JP-H11-52575A), and the like.

Examples of the compound (E7) include 2,2′-methylenebisaniline and the like.

Examples of the compound (E8) include imidazole, 4-methylimidazole, and the like.

Examples of the compound (E9) include pyridine, 4-methylpyridine, and the like.

Examples of the compound (E10) include 1,2-di(2-pyridyl)ethane, 1,2-di(4-pyridyl)ethane, 1,2-di(2-pyridyl)ethene, 1,2-di(4-pyridyl)ethene, 1,3-di(4-pyridyl)propane, 1,2-di(4-pyridyloxy)ethane, di(2-pyridyl)ketone, 4,4′-dipyridylsulfide, 4,4′-dipyridyldisulfide, 2,2′-dipyridylamine, 2,2′-dipicolylamine, and the like.

Examples of the compound (E11) include dipyridine and the like.

Examples of ammonium hydroxide include tetramethyl ammonium hydroxide, tetraisopropyl ammonium hydroxide, tetrabutyl ammonium hydroxide, tetrahexyl ammonium hydroxide, tetraoctyl ammonium hydroxide, phenyltrimethyl ammonium hydroxide, 3-(trifluoromethyl)phenyltrimethyl ammonium hydroxide, choline, and the like.

As the basic compound (E), diisopropylanilines are preferable, and 2,6-diisopropylaniline is particularly preferable among these.

The basic compound (E) may be used as one type or two or more types may be used. The actinic ray-sensitive or radiation-sensitive resin composition of the present invention may or may not contain the basic compound (E); however, when contained, the content ratio of the basic compound (the total in a case where a plurality of types are contained) is 0.001 mass % to 10 mass % and preferably 0.01 to 5 mass % using the solid content of the actinic ray-sensitive or radiation-sensitive resin composition as a reference.

Solvent (Referred to Below as “Solvent (D)”)

A solvent (D) may be contained in the resist composition. It is possible to appropriately select a suitable solvent for the solvent (D) from the viewpoint of a favorable coating property when coating the resist composition of the present invention onto a substrate when manufacturing a resist pattern which will be further described below according to the type and the amount of the compound (C) to be used, the type and the amount of the resin (A), and the type and the amount of the acid generator (B).

Examples of the solvent (D) include glycol ether esters such as ethylcellosolve acetate, methylcellosolve acetate, and propylene glycol monomethyl ether acetate (PGMEA); glycol ethers such as propylene glycol monomethyl ether (PGME); esters such as ethyl lactate, butyl acetate, amyl acetate, and ethyl pyruvate; ketones such as acetone, methylisobutyl ketone, 2-heptanone, and cyclohexanone; cyclic esters such as γ-butyrolactone, carbonates such as propylene carbonate, and the like. Only one type of the solvent (D) may be used or two or more types may be used together. Examples of favorable solvents include propylene glycol monomethyl ether acetate, propylene glycol monomethyl ether, 2-heptanone, cyclohexanone, and γ-butyrolactone. A solvent which includes at least one type of 2-heptanone and γ-butyrolactone is preferable, and a mixed solvent of two or more types which includes 2-heptanone and γ-butyrolactone is particularly preferable.

In detail, a two-type mixed solvent which is selected from PGMEA/ethyl lactate, PGMEA/PGME, and PGMEA/cyclohexanone, a three-type mixed solvent which is selected from PGMEA/ethyl lactate/γ-butyrolactone, PGMEA/cyclohexanone/γ-butyrolactone, PGMEA/2-heptanone/propylene carbonate, PGME/cyclohexanone/propylene carbonate, and PGMEA/PGME/γ-butyrolactone, a four-type mixed solvent of PGMEA/PGME/cyclohexanone/γ-butyrolactone, and the like are preferable.

Other Components

The resist composition may include constituent components other than the compound (C), the resin (A), the acid generator (B), the solvent (D), and the basic compound (E) as necessary. The constituent components are referred to as “components (F)”. The components (F) is not particularly limited and examples thereof include additive agents known in the art in the field of resists such as a sensitizer, a dissolution inhibitor, a surfactant, a stabilizer, a dye, and the like.

Pattern Forming Method

Next, description will be given of the pattern forming method according to the present invention.

The pattern forming method (a negative tone pattern forming method) of the present invention includes at least (a) a step of forming a film (a resist film) which includes the actinic ray-sensitive or radiation-sensitive resin composition of the present invention, (b) a step of irradiating the film with actinic rays or radiation, and (c) a step of developing the film which is irradiated with the actinic rays and radiation described above using a developer which includes an organic solvent.

The exposure in the step (b) described above may be liquid immersion exposure.

The pattern forming method of the present invention preferably includes (d) a heating step after (b) the exposure step.

The pattern forming method of the present invention may further include (e) a step of developing using an alkali developer. Portions with weak exposure strength are removed by a step of developing which uses a developer which contains an organic solvent; however, portions with strong exposure strength are also removed by further performing an alkali developing step. In this manner, since it is possible to perform pattern forming without dissolving only a region with intermediate exposure strength by a multiplex developing process in which development is performed in plural, it is expected that it will be possible to form a pattern which is finer than normal (the same mechanism as paragraph <0077> of JP2008-292975A).

It is possible to perform (e) the step of developing using an alkali developer either before or after (c) the step of developing using a developer which includes an organic solvent; however, it is more preferably performed before (c) the step of developing using a developer which includes an organic solvent.

The pattern forming method of the present invention may include (b) the exposure step in plural.

The pattern forming method of the present invention may include (d) the heating step in plural.

The resist film of the present invention is formed of the actinic ray-sensitive or radiation-sensitive resin composition of the present invention described above and more specifically, is preferably a film which is formed by coating the actinic ray-sensitive or radiation-sensitive resin composition onto a base material. In the pattern forming method of the present invention, it is possible to perform a step of forming a film on a substrate using the actinic ray-sensitive or radiation-sensitive resin composition, a step of exposing the film, and a step of developing using methods which are generally known.

It is also preferable to include a preheating step (PB; Prebake) after film-forming and before the exposure step.

In addition, it is also preferable to include a post-exposure heating step (PEB; Post Exposure Bake) after the exposure step and before the developing step.

Both PB and PEB are preferably performed at a heating temperature of 70° C. to 130° C., and more preferably at 80° C. to 120° C.

The heating time is preferably 30 seconds to 300 seconds, more preferably 30 seconds to 180 seconds, and even more preferably 30 seconds to 90 seconds.

It is possible to perform the heating with means which is provided in a general exposure and developing machine, and a hot plate or the like may be used.

Due to the baking, the reaction of an exposed section is promoted and the sensitivity or pattern profile is improved.

There is no limit on the wavelength of the light source which is used for the exposure apparatus in the present invention; however, examples thereof include infrared light, visible light, ultraviolet light, far ultraviolet light, extreme ultraviolet light, X-rays, electron beams, and the like, and far ultraviolet light with a wavelength of preferably 250 nm or less, more preferably 220 nm or less, and particularly preferably 1 nm to 200 nm, specifically, a KrF excimer laser (248 nm), an ArF excimer laser (193 nm), an F2 excimer laser (157 nm), X-rays, EUV (13 nm), electron beams, and the like, and a KrF excimer laser, an ArF excimer laser, EUV, or electron beams are preferable, and an ArF excimer laser is more preferable.

In addition, it is possible to apply a liquid immersion exposure method in the step of performing exposure of the present invention.

The liquid immersion exposure method is a technique which carries out exposure by filling a liquid with high refractive index (also referred to below as a “liquid immersion liquid”) between a projection lens and a sample as a technique for increasing resolution.

As described above, for the “effect of liquid immersion”, when λ₀ is the wavelength of the exposure light in air, n is the refractive index of the liquid immersion liquid with respect to air, θ is a light ray condensing half angle, and NA₀=sin θ, in the case of liquid immersion, it is possible to represent the resolution and depth of focus (DOF) by the following formula. Here, k₁ and k₂ are coefficients relating to processing.

(resolution)=k₁·(λ₀/n)/NA₀

(DOF)=±k₂·(λ₀/n)/NA₀²

That is, the effect of liquid immersion is equivalent to using an exposure wavelength with a wavelength of 1/n. In other words, in a case of the same NA projection optical system, it is possible to multiply the focus depth by n times according to the liquid immersion. This is effective with respect to all types of pattern shapes and additionally, combination is possible with super-resolution techniques such as phase shift methods and modified lighting methods currently being researched.

In a case of performing liquid immersion exposure, a step of cleaning the surface of the film with a water-based chemical liquid may be carried out (1) after forming the film on a substrate and before an exposure step, and/or (2) after a step of carrying out exposure on a film via a liquid immersion liquid and before a step of heating the film.

The liquid immersion liquid is preferably a liquid which is transparent with respect to the exposure wavelength and where the temperature coefficient of the refractive index is as small as possible in order to keep deformation of an optical image which is projected on a film to a minimum; however, in particular, in a case where the exposure light source is an ArF excimer laser (wavelength; 193 nm), it is preferable to use water in terms of ease of availability and ease of handling in addition to the points of view described above.

In a case of using water, an additive agent (a liquid) which increases surface activity in addition to reducing the surface tension of the water may be added in a small ratio. The additive agent preferably does not dissolve a resist layer on a wafer and any influence with respect to an optical coating on a lower surface of a lens element is negligible.

The additive agent is preferably an aliphatic alcohol which has substantially the same refractive index as water and specific examples thereof include methyl alcohol, ethyl alcohol, an isopropyl alcohol, and the like. By adding alcohol which has substantially the same refractive index as water, even when the alcohol components in water are evaporated and the content concentration changes, it is possible to obtain an advantage in that it is possible to make the refractive index change for the liquid as a whole extremely small.

On the other hand, since deformation of the optical image which is projected on the resist is caused in a case where a substance which is opaque with respect to 193 nm light or impurities where the refractive index is greatly different from water are mixed into a liquid immersion liquid, distilled water is preferable as the water to be used. Furthermore, pure water where filtering is performed through an ion exchange filter and the like may also be used.

The electrical resistance of the water which is used as the liquid immersion liquid is desirably 18.3 MΩcm or more, the TOC (organic concentration) is desirably 20 ppb or less, and a degassing process is desirably carried out.

In addition, it is possible to increase the lithographic performance by increasing the refractive index of the liquid immersion liquid. From this point of view, an additive agent which increases the refractive index may be added to the water, or heavy water (D₂O) may be used instead of water.

The receding contact angle of a resist film which is formed using the actinic ray-sensitive or radiation-sensitive resin composition in the present invention is preferably 70° or more at a temperature of 23±3° C. and a humidity of 45±5%, which is favorable in a case of exposing via a liquid immersion medium, more preferably 75° or more, and even more preferably 75° to 85°.

When the receding contact angle is excessively small, favorable use is not possible in a case of exposure via a liquid immersion medium and it is not possible to sufficiently exhibit the effect of reducing defects due to remaining water (water marks).

In a case where the resin (A) substantially does not contain a fluorine atom and a silicon atom, by the actinic ray-sensitive or radiation-sensitive resin composition in the present invention containing the hydrophobic resin (HR), it is possible to improve the receding contact angle of the resist film surface.

From the point of view of improving the receding contact angle, the hydrophobic resin (HR) preferably has at least one of repeating units which are represented by general Formula (II) or (III). In addition, from the point of view of improving the receding contact angle, a Clog P value of the hydrophobic resin (HR) is preferably 1.5 or more. Furthermore, from the point of view of improving the receding contact angle, a mass content ratio taken up by a CH₃ partial structure of a side chain portion in the hydrophobic resin (HR) is preferably 12.0% or more in the hydrophobic resin (HR).

In the liquid immersion exposure step, since it is necessary for the liquid immersion liquid to move on a wafer following the movement of an exposure head scanning on the wafer at a high speed and forming exposure patterns, the contact angle of the liquid immersion liquid with respect to the resist film in a dynamic state is important and there is a demand for the resist to have a performance which follows the high speed scanning of the exposure head without liquid droplets remaining.

The substrate which forms the film in the present invention is not particularly limited, and it is possible to use a substrate which is generally used in a step of manufacturing a semiconductor such as IC such as an inorganic substrate such as silicon, SiN, SiO₂ or SiN or a coating based inorganic substrate such as SOG, a step of manufacturing a circuit substrate such as liquid crystal or a thermal head, in addition to a lithography step for other types of photofabrication. Furthermore, an organic antireflection film may be formed between a film and a substrate as necessary.

In a case where the pattern forming method of the present invention further has a step of developing using an alkali developer, it is possible to use, for example, inorganic alkalis such as sodium hydroxide, potassium hydroxide, sodium carbonate, sodium silicate, sodium metasilicate, and ammonia water, prime amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethyl ammonium hydroxide and tetraethyl ammonium hydroxide, and alkali water solutions such as pyrrole and piperidine, as the alkali developer.

Furthermore, use is also possible by adding an appropriate amount of alcohols and a surfactant to the alkali solution described above.

The alkali concentration of the alkali developer is generally 0.1 mass % to 20 mass %.

The pH of the alkali developer is generally 10.0 to 15.0.

In particular, a solution of 2.38 mass % of tetramethyl ammonium hydroxide is desirable.

Pure water is used as the rinsing liquid in a rinsing step which is performed after alkali development and use is also possible by adding an appropriate amount of a surfactant.

In addition, it is possible to perform a process which removes developer or rinsing liquid which is attached to the pattern using a supercritical fluid after the developing process or the rinsing process.

It is possible to use a polar solvent and a hydrocarbon-based solvent such as a ketone-based solvent, an ester-based solvent, an alcohol-based solvent, an amide-based solvent, and an ether-based solvent as a developer (also referred to below as an organic-based developer) in a step of developing using the developer which contains an organic solvent which is included in the pattern forming method of the present invention.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate, and the like.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol, glycol-based solvents such as ethylene glycol, diethylene glycol, and triethylene glycol, glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxy methyl butanol, and the like.

Examples of the ether-based solvent include dioxane, tetrahydrofuran, and the like other than the glycol ether-based solvents described above.

As the amide-based solvent, it is possible to use, for example, N-methyl-2-pyrrolidone, N,N-dimethyl acetamide, N,N-dimethyl formamide, hexamethylphosphoric triamide, 1,3-dimethyl-2-imidazolidinone, and the like.

Examples of the hydrocarbon-based solvent include aromatic hydrocarbon-based solvents such as toluene and xylene and aliphatic hydrocarbon-based solvents such as pentane, hexane, octane, and decane.

A plurality of the solvents described above may be mixed, and may be used after being mixed with a solvent other than the solvents described above or water. However, in order to sufficiently exhibit the effects of the present invention, the moisture content of the developer as a whole is preferably less than 10 mass %, and water is more preferably substantially not contained.

That is, the usage amount of an organic solvent with respect to an organic-based developer is preferably 90 mass % to 100 mass % with respect to the total amount of the developer, and more preferably 95 mass % to 100 mass %.

In particular, the organic-based developer is preferably a developer which contains at least one type of organic solvent which is selected from the group consisting of a ketone-based solvent, an ester-based solvent, an alcohol-based solvent, an amide-based solvent, and an ether-based solvent.

The vapor pressure of the organic-based developer is preferably 5 kPa or less, more preferably 3 kPa or less, and particularly preferably 2 kPa or less at 20° C. By setting the vapor pressure of an organic-based developer to 5 kPa or less, evaporation of the developer on a substrate or inside a developing cup is suppressed, temperature uniformity in the wafer surface is improved, and as a result, the uniformity of the dimensions in the wafer surface is improved.

Specific examples having steam pressure of 5 kPa or less include a ketone-based solvent such as 1-octanone, 2-octanone, 1-nonanone, 2-nonanone, 2-heptanone(methyl amyl ketone), 4-heptanone, 2-hexanone, diisobutyl ketone, cyclohexanone, methylcyclohexanone, phenylacetone, and methyl isobutyl ketone, an ester-based solvent such as butyl acetate, pentyl acetate, isopentyl acetate, amyl acetate, propylene glycol monomethyl ether acetate, ethylene glycol monoethyl ether acetate, diethylene glycol monobutylether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, and propyl lactate, an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol, a glycol-based solvent such as ethylene glycol, diethylene glycol, and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol, an ether-based solvent such as tetrahydrofuran, an amide-based solvent such as N-methyl-2-pyrrolidone, N,N-dimethyl acetamide, and N,N-dimethyl formamide, an aromatic hydrocarbon-based solvent such as toluene and xylene, and an aliphatic hydrocarbon-based solvent such as octane and decane.

Specific examples having steam pressure of 2 kPa or less which is a particularly preferable range include a ketone-based solvent such as 1-octanone, 2-octanone, 1-nonanone, 2-nonanone, 4-heptanone, 2-hexanone, diisobutyl ketone, cyclohexanone, methylcyclohexanone, and phenylacetone, an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, and propyl lactate, an alcohol-based solvent such as n-butyl alcohol, sec-butyl alcohol, tert-butyl alcohol, isobutyl alcohol, n-hexyl alcohol, n-heptyl alcohol, n-octyl alcohol, and n-decanol, a glycol-based solvent such as ethylene glycol, diethylene glycol, and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol, an amide-based solvent such as N-methyl-2-pyrrolidone, N,N-dimethyl acetamide, and N,N-dimethyl formamide, an aromatic hydrocarbon-based solvent such as xylene, and an aliphatic hydrocarbon-based solvent such as octane and decane.

It is possible to add an appropriate amount of a surfactant to an organic-based developer as necessary.

The surfactant is not particularly limited; however, for example, it is possible to use ionic or non-ionic fluorine-based and/or silicon-based surfactants and the like. Examples of the fluorine-based and/or silicon-based surfactant include the surfactants which are described in JP 1987-36663A (JP-S62-36663A), JP1986-226746A (JP-S61-226746A), JP1986-226745A (JP-S61-226745A), JP 1987-170950A (JP-S62-170950A), JP 1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451, and a non-ionic surfactant is preferable. The non-ionic surfactant is not particularly limited; however, it is more preferable to use a fluorine-based surfactant or a silicon-based surfactant.

The usage amount of the surfactant is generally 0.001 mass % to 5 mass %, preferably 0.005 mass % to 2 mass %, and even more preferably 0.01 mass % to 0.5 mass % with respect to the total amount of the developer.

A developer which includes an organic solvent may include a basic compound. Specific examples and preferable examples of a basic compound which may be included in the developer used in the present invention are the same examples in the basic compound described above which may be included in the actinic ray-sensitive or radiation-sensitive resin composition.

It is possible to apply, for example, a method in which a substrate is dipped in a tank which is filled with a developer for a certain period (a dipping method), a method of developing by raising a developer on a substrate surface using surface tension and resting for a certain period (a paddle method), a method for spraying a developer onto a substrate surface (a spraying method), a method which carries on ejecting a developer onto a substrate which is rotated at a certain speed while scanning developer ejecting nozzles at a certain speed (a dynamic dispensing method), and the like, as the developing method.

In a case where the various types of developing methods described above include a step of ejecting a developer from developing nozzles of a developing apparatus onto a resist film, the ejecting pressure of the developer which is ejected (the flow speed in each unit area of the developer which is ejected) is preferably 2 mL/sec/mm² or less, more preferably 1.5 mL/sec/mm² or less, and even more preferably 1 mL/sec/mm² or less. There is no lower limit on the flow speed; however, when considering throughput, 0.2 mL/sec/mm² or more is preferable.

By setting the ejecting pressure of the developer which is ejected to the ranges described above, it is possible to remarkably reduce pattern defects deriving from the resist residue after developing.

Details of the mechanism are not clear; however, it is considered that, by setting the ejecting pressure to the ranges described above, the pressure which the developer applies to the resist film is small and the resist film or resist pattern is suppressed from being unnecessarily scraped or broken.

Here, the ejecting pressure (mL/sec/mm²) of the developer is a value at a developing nozzle opening in the developing apparatus.

Examples of a method for adjusting the ejecting pressure of the developer include a method for adjusting the ejecting pressure by a pump and the like, a method for changing the pressure by adjusting the pressure in the supply from a pressure tank, and the like.

In addition, after a step of developing using a developer which contains an organic solvent, a step of stopping developing while carrying out substitution with another solvent may be carried out.

A step of cleaning using a rinsing liquid is preferably included after the step of developing using a developer which contains an organic solvent.

The rinsing liquid which is used for the rinsing step after the step of developing using a developer which contains an organic solvent is not particularly limited as long as the resist pattern is not dissolved and it is possible to use a solution which includes a general organic solvent. It is preferable to use a rinsing liquid which contains at least one type of an organic solvent which is selected from the group consisting of a hydrocarbon-based solvent, a ketone-based solvent, an ester-based solvent, an alcohol-based solvent, an amide-based solvent, and an ether-based solvent as the rinsing liquid.

Specific examples of the hydrocarbon-based solvent, the ketone-based solvent, the ester-based solvent, the alcohol-based solvent, the amide-based solvent, and the ether-based solvent include the same solvents as the description for the developer which contains an organic solvent.

After the step of developing using a developer which contains an organic solvent, a step of cleaning using a rinsing liquid which contains at least one type of an organic solvent which is selected from the group consisting of a ketone-based solvent, an ester-based solvent, an alcohol-based solvent, and an amide-based solvent is more preferably performed, a step of cleaning using a rinsing liquid which contains an alcohol-based solvent or an ester-based solvent is even more preferably performed, a step of cleaning using a rinsing liquid which contains a monovalent alcohol is particularly preferably performed, and a step of cleaning using a rinsing liquid which contains a monovalent alcohol with 5 or more carbon atoms is most preferably performed.

Here, examples of the monovalent alcohol which is used in the rinsing step include linear, branched, or cyclic monovalent alcohols and specifically, it is possible to use 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, and the like, and, as particularly preferable monovalent alcohols with 5 or more carbon atoms, it is possible to use 1-hexanol, 2-hexanol, 4-methyl-2-pentanol, 1-pentanol, 3-metyl-1-butanol, and the like.

A plurality of each of the components may be mixed, or may be used after mixing with an organic solvent other than the solvents described above.

The moisture content in the rinsing liquid is preferably 10 mass % or less, more preferably 5 mass % or less, and particularly preferably 3 mass % or less. By setting the moisture content to 10 mass % or less, it is possible to obtain favorable developing characteristics.

The vapor pressure of the rinsing liquid which is used after the step of developing using a developer which contains an organic solvent is preferably 0.05 kPa to 5 kPa or less, more preferably 0.1 kPa to 5 kPa, and most preferably 0.12 kPa to 3 kPa at 20° C. By setting the vapor pressure of the rinsing liquid to 0.05 kPa to 5 kPa, the temperature uniformity in the wafer surface is improved, additionally, swelling which is caused by the permeation of the rinsing liquid is suppressed, and the uniformity of the dimensions in the wafer surface is improved.

Use is also possible by adding an appropriate amount of a surfactant to the rinsing liquid.

In the rinsing step, a cleaning process is carried out on the wafer on which developing is performed using a developer which contains an organic solvent, using a rinsing liquid which contains an organic solvent. The method of the cleaning processing is not particularly limited; however, for example, it is possible to apply a method which carries on ejecting a rinsing liquid onto a substrate which is rotated at a certain speed (a rotary coating method), a method which dips a substrate in a tank which is filled with a rinsing liquid for a certain period (a dipping method), a method which sprays a rinsing liquid onto a substrate surface (a spraying method), and the like, and it is preferable to perform the cleaning process using the rotary coating method among these methods, to rotate the substrate at a rotation speed of 2000 rpm to 4000 rpm after cleaning, and to remove the rinsing liquid from the substrate. In addition, it is also preferable to include a heating step (Post Bake) after the rinsing step. Due to the baking, the developer and the rinsing liquid which remain between the patterns and in the patterns are removed. The heating step after the rinsing step is generally performed at 40° C. to 160° C., preferably 70° C. to 95° C., and generally for 10 seconds to 3 minutes, preferably 30 seconds to 90 seconds.

In addition, the present invention also relates to a method for manufacturing an electronic device which includes the pattern forming method of the present invention described above and to an electronic device which is manufactured by the manufacturing method.

The electronic device of the present invention is suitable for mounting on electrical and electronic equipment (household electrical appliances, OA and media-related apparatuses, optical equipment, telecommunication equipment, and the like).

### EXAMPLES

Detailed description will be given below of the present invention using examples; however, the content of the present invention is not limited thereto.

Resins A1 to A10 were used as the resin (A). The resins A1 to A10 were synthesized according to the method described in JP2013-8020A. Below, the structures, composition ratios (molar ratio), molecular weights, and degrees of dispersion of the resins A1 to A10 will be shown.

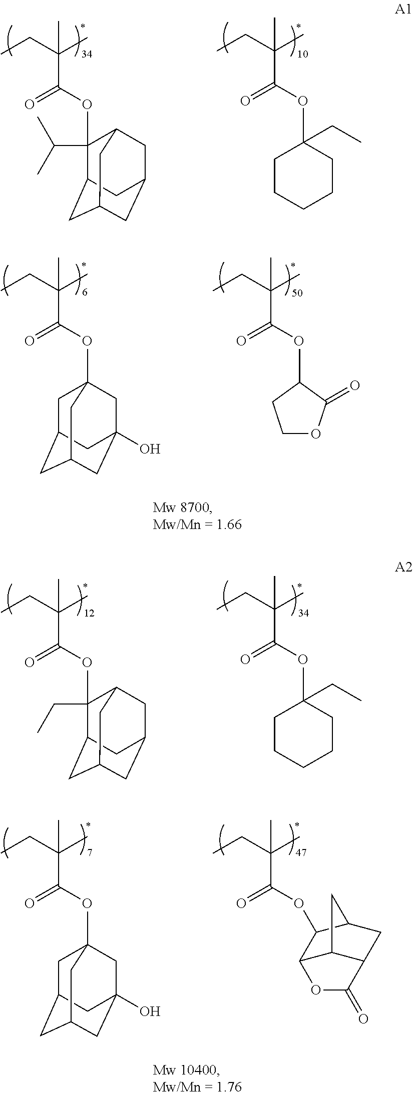

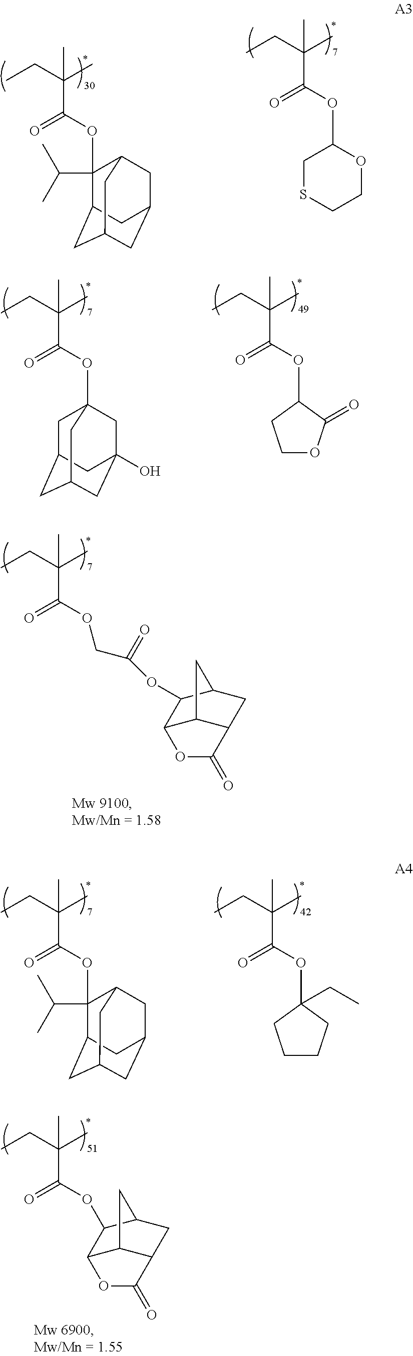

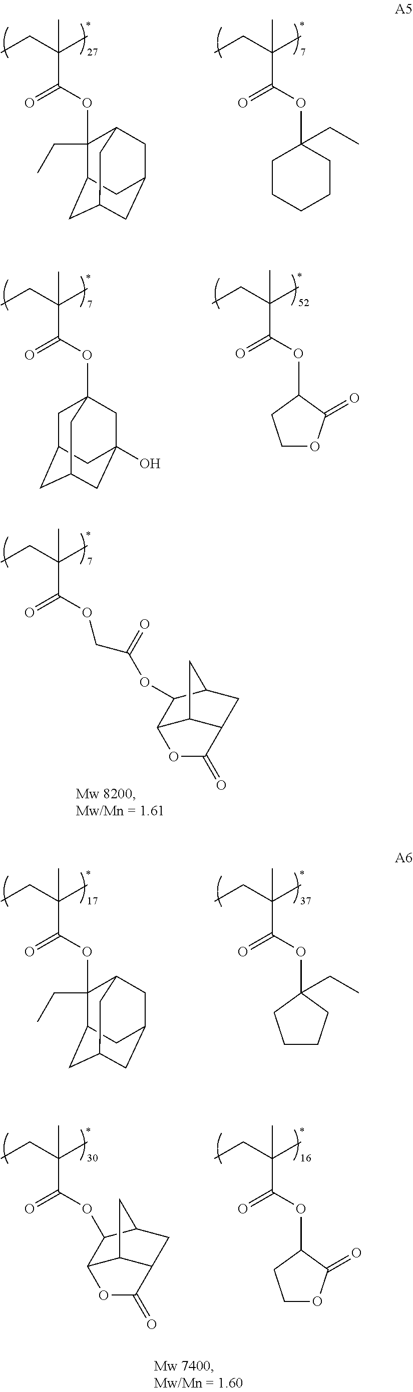

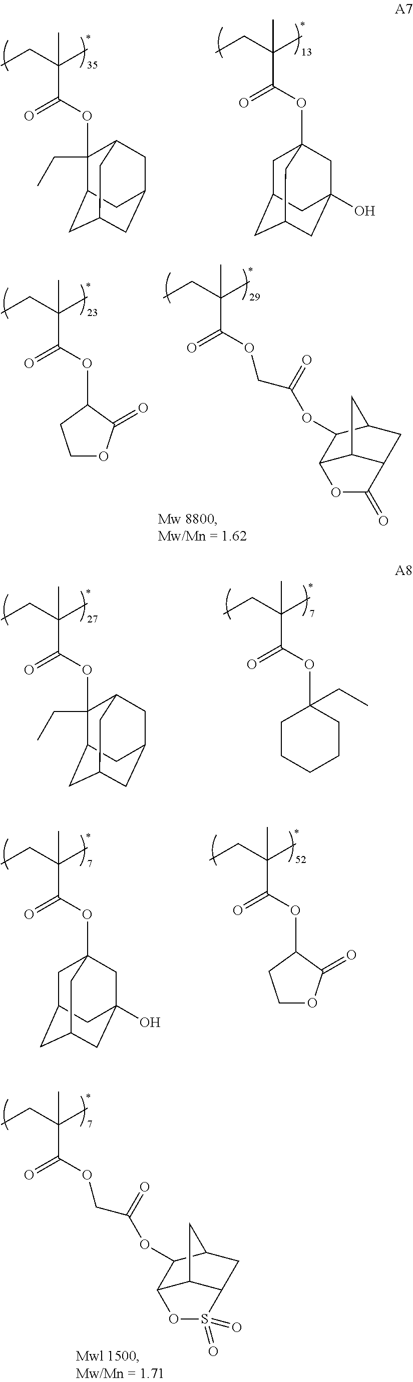

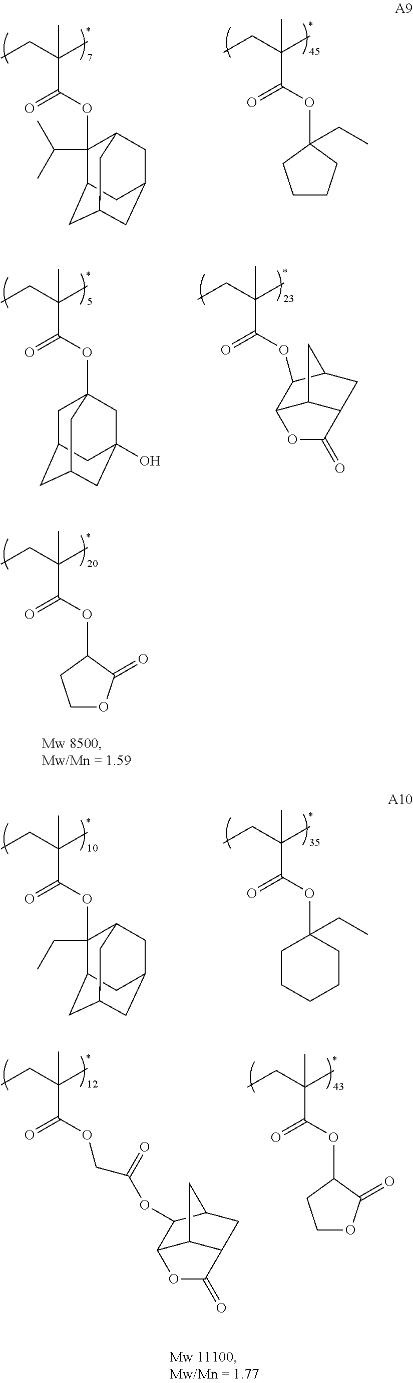

HR1 to HR4 were used as the hydrophobic resin (HR). The hydrophobic resins HR1 to HR4 were synthesized according to the method described in JP2012-256011A. Below, the structures, composition ratios (molar ratio), molecular weights, and degrees of dispersion of the hydrophobic resins HR1 to HR4 will be shown.

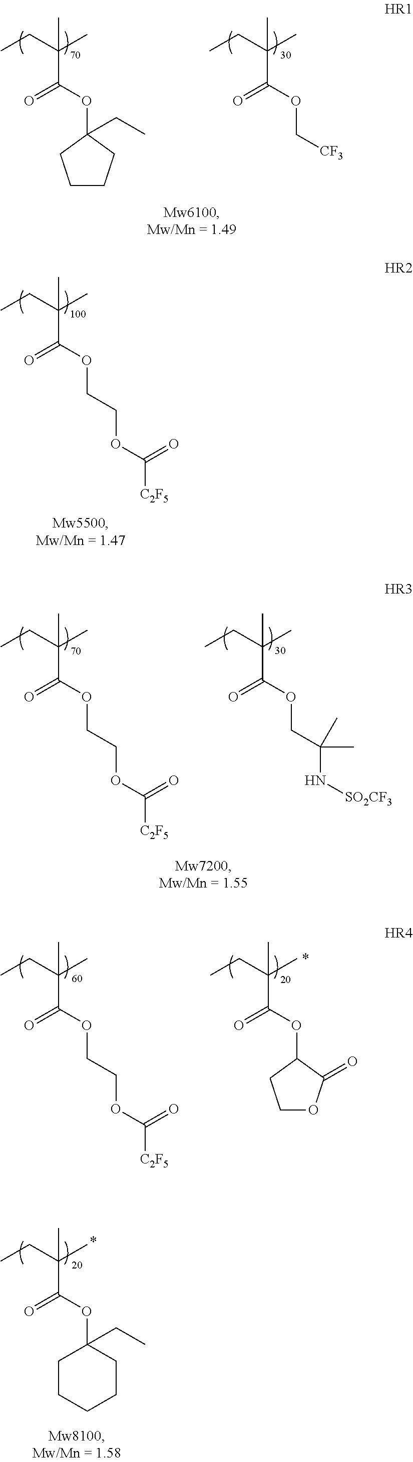

B1 to B4 below were used as the acid generator (B).

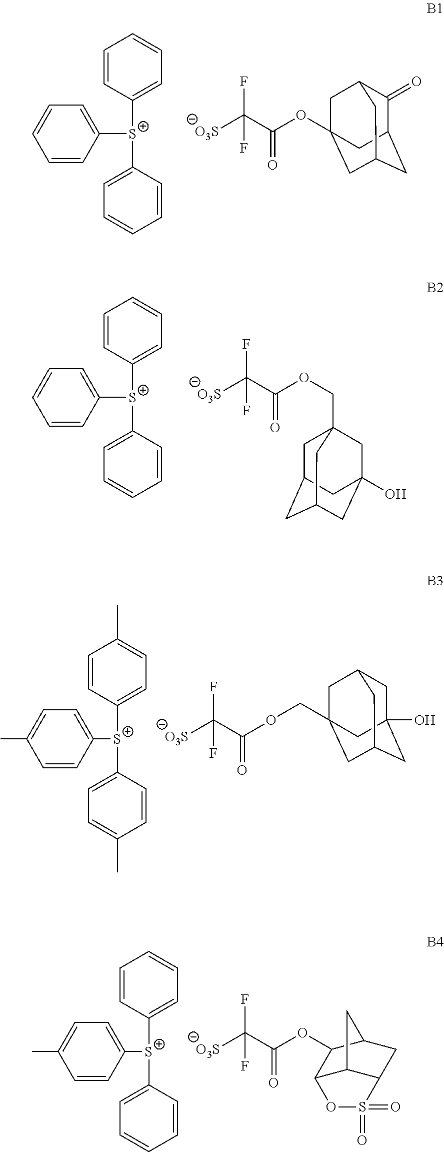

C1 to C8 below were used as the compound (C).

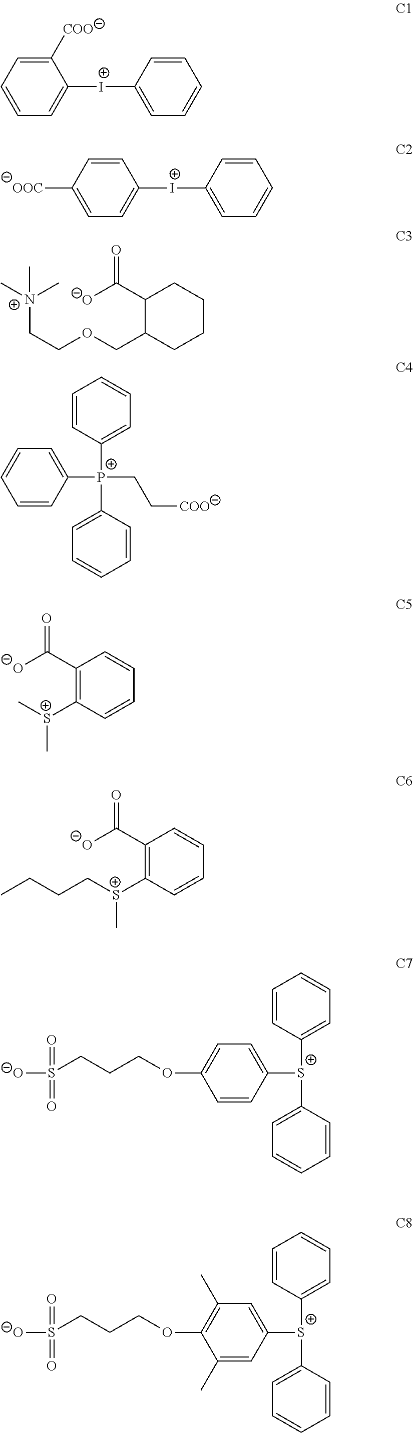

Basic compounds N-1 to N-3 shown below were used as necessary.

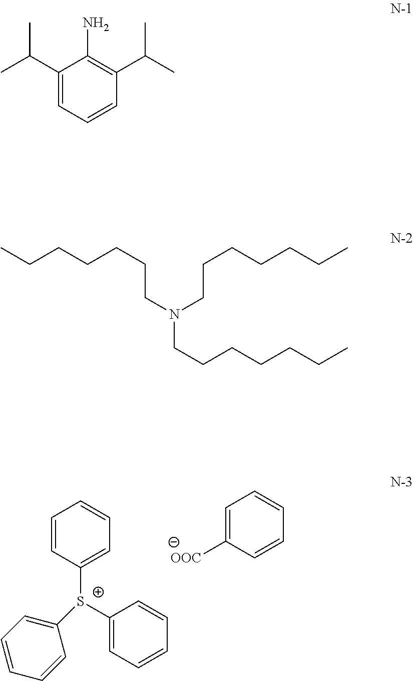

The following were used as a surfactant.
W-1: Megafac F176 (manufactured by DIC Inc.) (fluorine-based)
W-2: Megafac R08 (manufactured by DIC Inc.) (fluorine-based and silicon-based)
W-3: Polysiloxane polymer KP-341 (manufactured by Shin-Etsu Chemical Co., Ltd.) (silicon-based)
W-4: Troyzol S-366 (manufactured by Troy Chemical Industries, Inc.)
W-5: KH-20 (manufactured by Asahi Kasei Corporation)
W-6: Poly Fox™ PF-6320 (manufactured by OMNOVA Solution Inc.) (fluorine-based)

The following were used as solvents.

Group a
SL-1: Propylene glycol monomethyl ether acetate (PGMEA)
SL-2: Propylene glycol monomethyl ether propionate
SL-3: 2-heptanone

Group b
SL-4: Ethyl lactate
SL-5: Propylene glycol monomethyl ether (PGME)
SL-6: Cyclohexanone

Group c
SL-7: y-butylolactone
SL-8: Propylene carbonate

Preparation of Resist Composition

Resist compositions in Examples 1 to 12 and Comparative Examples 1 and 2 were prepared by dissolving components shown in Table 1 below in a solvent and filtering each thereof using a polyethylene filter with a pore size of 0.03 μm.

TABLE 1

| | | | | | | Acid generator | | Compound | | Basic Com- | | Surfactant | | | |
|---|---|---|---|---|---|---|---|---|---|---|---|---|---|---|---|
| | | Resin (A) | | Resin (HR) | | (B) | | (C) | | pound (E) | | (F) | | Solvent (D) | |
| | | Com- | Parts | Com- | Parts | Com- | Parts | Com- | | Com- | Parts | Com- | Parts | Com- | |
| | | pound | by | pound | by | pound | by | pound | Parts by | pound | by | pound | by | pound | Parts by |
| | | number | mass | number | mass | number | mass | number | mass | number | mass | number | mass | number | mass |
| Exam- | 1 | A1 | 82 | HR1 | 2 | B1 | 14 | C1 | 1.5 | | | W-1 | 0.5 | SL-1/SL- | 1700/600/ |
| ple | | | | | | | | | | | | | | 6/SL-7 | 100 |
| Exam- | 2 | A2 | 80.5 | HR2 | 1.9 | B2 | 15 | C1/C2 | 1.5/0.1 | | | W-6 | 1 | SL-1/SL- | 1100/1000/ |
| ple | | | | | | | | | | | | | | 4/SL-7 | 300 |
| Exam- | 3 | A3 | 77.1 | HR3 | 1.9 | B3 | 18 | C3 | 2 | | | W-2 | 1 | SL-1/SL- | 1770/600/ |
| ple | | | | | | | | | | | | | | 6/SL-7 | 30 |
| Exam- | 4 | A4 | 83.7 | HR3 | 1.8 | B4/B1 | 5/6.5 | C4 | 2.5 | | | W-4 | 0.5 | SL-1/SL- | 1900/400/ |
| ple | | | | | | | | | | | | | | 4/SL-7 | 100 |
| Exam- | 5 | A5/A1 | 67.1/20 | HR2 | 1.7 | B1/B3 | 7/2 | C5 | 2.2 | | | | | SL-1/SL- | 1980/400/ |
| ple | | | | | | | | | | | | | | 3/SL-8 | 20 |
| Exam- | 6 | A6 | 87 | HR4 | 1.5 | B2/B3 | 6/2 | C6/C1 | 1.5/1 | | | W-6 | 1 | SL-6/SL-1 | 1750/650 |
| ple | | | | | | | | | | | | | | | |
| Exam- | 7 | A7/A8 | 60.9/15 | HR4 | 2.8 | B3/B4 | 10/8 | C7 | 3.3 | | | | | SL-1/SL-4 | 1200/1200 |
| ple | | | | | | | | | | | | | | | |
| Exam- | 8 | A8 | 87.8 | HR1 | 2.2 | B4/B1 | 4/3.5 | C8/C3 | 1/0.5 | | | W-3 | 1 | SL-2/SL- | 1580/800/ |
| ple | | | | | | | | | | | | | | 6/SL-8 | 20 |
| Exam- | 9 | A1 | 80.8 | HR2 | 4 | B1/B2 | 8/6 | C1 | 1 | N-2 | 0.2 | | | SL-1/SL-2/ | 2200/90/ |
| ple | | | | | | | | | | | | | | SL-3/SL-7 | 90/20 |
| Exam- | 10 | A2 | 81.9 | HR4 | 3.5 | B1/B4 | 8/5 | C4 | 1.1 | N-3 | 0.5 | | | SL-1/SL-2/ | 2100/150/ |
| ple | | | | | | | | | | | | | | SL-3/SL-7 | 100/50 |
| Exam- | 11 | A9 | 77.05 | HR4 | 4 | B1/B4 | 10/6.5 | C1/C4 | 1.2/ | | | W-6 | 0.5 | SL-1/SL- | 1400/850/ |
| ple | | | | | | | | | 0.75 | | | | | 4/SL-7 | 150 |
| Exam- | 12 | A10 | 82 | HR2 | 2 | B2/B3 | 7.5/6.5 | C3 | 1.5 | | | W-1 | 0.5 | SL-1/SL- | 1450/850/ |
| ple | | | | | | | | | | | | | | 5/SL-7 | 100 |
| Com- | 1 | A1 | 80.9 | HR1 | 2.5 | B1/B2 | 8/6 | | | N-1 | 1.6 | W-1 | 1 | SL-1/SL-6 | 1800/600 |
| par- | | | | | | | | | | | | | | | |
| ative | | | | | | | | | | | | | | | |
| Exam- | | | | | | | | | | | | | | | |
| ple | | | | | | | | | | | | | | | |
| Com- | 2 | A2 | 81.5 | HR1 | 2 | B1/B3 | 7/6.5 | | | N-3 | 2.5 | W-5 | 0.5 | SL-1/SL-5 | 1600/800 |
| par- | | | | | | | | | | | | | | | |
| ative | | | | | | | | | | | | | | | |
| Exam- | | | | | | | | | | | | | | | |
| ple | | | | | | | | | | | | | | | |

Using the prepared resist compositions, resist patterns were formed by the method below.

ArF Light Immersion Exposure 1: Line and Space Pattern

### Example 1

ARC29SR (manufactured by Nissan Chemical Industries, Ltd.) for forming an organic antireflection film was coated on a silicon wafer, baking was performed at 205° C. for 60 seconds, and an antireflection film with a film thickness of 86 nm was formed. The resist composition of Example 1 was coated thereon, baking (PB) was performed at 100° C. for 60 seconds, and a resist film with a film thickness of 100 nm was formed. Patterning exposure was performed on the obtained wafer via a 6% halftone mask with a 1:1 line and space pattern with a line width of 50 nm using an ArF excimer laser liquid immersion scanner (XT1700i manufactured by ASML, NA1.20, C-Quad, outer sigma 0.981, inner sigma 0.895, and XY inclination). Ultra-pure water was used as the liquid immersion liquid. Next, after heating (PEB) was carried out at 100° C. for 60 seconds, development was carried out by paddling the developer (butyl acetate) for 30 seconds and subsequently rinsing was carried out by paddling for 30 seconds using a rinsing liquid (4-methyl-2-pentanol). After that, a 1:1 line and space resist pattern with a line width of 50 nm was obtained by performing baking at 90° C. for 60 seconds after rotating the wafer at a rotation speed of 4000 rpm for 30 seconds.

### Examples 2 to 12 and Comparative Examples 1 and 2

1:1 line and space resist patterns with a line width of 50 nm were obtained in the same manner as the method in Example 1 apart from adopting the resist compositions described in Table 1.

LWR

The line width was measured using a scanning electron microscope at 50 arbitrary points included in 50 μm in the length direction of the resist pattern formed using the exposure amount when forming the resist pattern described above. Then, the standard deviation of this value was calculated and 3σ was obtained. It was shown that the smaller the value is, the more favorable the performance is.

Development Defects

With regard to the pattern which was obtained by the method described above, development defects were detected using a defect inspecting apparatus UVision (product name) manufactured by Applied Materials, Inc., under the conditions of: pixel size: 120 nm, light source polarization Horizontal, and detection mode Gray Field. The number of development defects per unit area (number/cm²) was obtained and evaluation of the development defect performance was performed using the criteria below.
A (Particularly favorable) . . . A case where the value is less than 0.5
B (Favorable) . . . A case where the value is 0.5 or more to less than 1.0
C (Defective) . . . A case where the value is 1.0 or more

Pattern Cross-Sectional Shape

Cross-sectional shapes of the patterns obtained by the method described above were observed through a scanning electron microscope and a line width Lb in a bottom section of the resist patterns and a line width La in an upper section of the resist patterns were measured. A case of 0.9≦(La/Lb)≦1.1 was defined as “rectangular” and a case of (La/Lb)>1.1 was defined as “T top shape”, the cross-sectional shape of the obtained pattern was observed through a scanning electron microscope, and evaluation was carried out by setting a cross-sectional shape where a rectangular pattern was obtained as A and a cross-sectional shape where a T top shape was obtained as B. A rectangular pattern is preferable as the cross-sectional shape.

ArF Liquid Immersion Exposure 2: Contact Hole Pattern

ARC29SR (manufactured by Nissan Chemical Industries, Ltd.) for forming an organic antireflection film was coated on a silicon wafer, baking was performed at 205° C. for 60 seconds, and an antireflection film with a film thickness of 86 nm was formed. A resist composition was coated thereon, baking was performed at 100° C. for 60 seconds, and a resist film with a film thickness of 100 nm was formed.

With regard to the obtained wafer, patterning exposure was performed via a squarely arrayed halftone mask with hole portions of 60 nm and pitches between holes of 90 nm (here, in order to form a negative image, portions which correspond to holes were shielded) using an ArF excimer laser liquid immersion scanner (manufactured by ASML; XT1700i, NA1.20, C-Quad, outer sigma 0.900, inner sigma 0.812, and XY inclination). Ultra-pure water was used as the liquid immersion liquid. After that, heating (PEB: Post Exposure Bake) was carried out at 105° C. for 60 seconds. Subsequently, development was carried out by paddling for 30 seconds using butyl acetate and rinsing was carried out by paddling for 30 seconds using a rinsing liquid (4-methyl-2-pentanol). Subsequently, a contact hole pattern with a hole diameter of 45 nm was obtained by rotating the wafer at a rotation speed of 4000 rpm for 30 seconds.

Uniformity of Pattern Size (CDU, nm)

Within one shot which was exposed with the exposure amount when obtaining the contact hole pattern with the hole diameter of 45 nm described above, in a region of 20 places with intervals of 1 μm therebetween, the hole sizes of arbitrary 25 places (that is, 500 in total) were measured for each region, the standard deviation thereof was calculated, and 3σ was obtained. It was shown that the smaller the value is, the less variation in the size and the more favorable the performance is.

Pattern Cross-Sectional Shape

The cross-sectional shapes of the resist patterns were observed using a scanning electron microscope, a hole diameter Lb in a bottom section of the resist pattern and a hole diameter La in an upper section of the resist pattern were measured, and a case of 0.9≦(La/Lb)≦1.1 was evaluated as “A (favorable)” and a case of being outside this range was evaluated as “B (defect)”.

Table 2 below shows the evaluation results.

TABLE 2

| | | | | | Contact hole | |
|---|---|---|---|---|---|---|
| | | Line and space performance | | | performance | |
| | | evaluation result | | | evaluation result | |
| | | | Develop- | Cross- | | Cross- |
| | | LWR | ment | sectional | CDU | sectional |
| | | (nm) | defects | shape | (nm) | shape |
| Example | 1 | 3.1 | A | A | 3.6 | A |
| Example | 2 | 3.1 | B | A | 3.6 | A |
| Example | 3 | 3.7 | A | A | 3.8 | A |
| Example | 4 | 3.8 | B | A | 3.8 | A |
| Example | 5 | 3.1 | A | A | 3.5 | A |
| Example | 6 | 2.9 | A | A | 3.1 | A |
| Example | 7 | 3.2 | A | A | 3.5 | A |
| Example | 8 | 3.1 | A | A | 3.5 | A |
| Example | 9 | 3.1 | A | A | 3.5 | A |
| Example | 10 | 3.7 | B | A | 3.8 | A |
| Example | 11 | 2.9 | A | A | 3 | A |
| Example | 12 | 3.2 | A | A | 3.4 | A |
| Comparative | 1 | 5.2 | C | B | 4.9 | B |
| Example | | | | | | |
| Comparative | 2 | 4.4 | C | B | 4.7 | B |
| Example | | | | | | |

From the results according to the table above, it is understood that, for Examples 1 to 12 where the actinic ray-sensitive or radiation-sensitive resin composition of the present invention was used, the LWR was small, there were fewer development defects, and the cross-sectional shape of a pattern and CDU were excellent in compared to Comparative Examples 1 and 2 where an actinic ray-sensitive or radiation-sensitive resin composition which did not contain the compound (C) was used.

In addition, it is understood that there were particularly few development defects in Examples 1, 3, 5 to 9, 11, and 12 where an actinic ray-sensitive or radiation-sensitive resin composition which contained a resin which had a repeating unit derived from the monomer (a3-1) was used.

In addition, it is understood that LWR and CDU were particularly excellent in Examples 6 and 11 where the content ratio (the total thereof in a case where a plurality of types were present) of a repeating unit which is derived from the monomer (a1) was 50 mol % or more.

What is claimed is:

1. A pattern forming method comprising:
(a) forming a film using an actinic ray-sensitive or radiation-sensitive resin composition which contains (A) to (C) below,
(A) a resin where polarity increases due to an action of acid and solubility decreases with respect to a developer which includes an organic solvent,
(B) a compound which generates acid when irradiated with actinic rays or radiation, and
(C) a compound which has a cation site and an anion site in a same molecule with the cation site and the anion site being linked with each other by a covalent bond;
(b) exposing the film; and
(c) forming a negative tone pattern by developing the exposed film using a developer which includes an organic solvent.

2. The pattern forming method according to claim 1,
wherein the compound (C) is a compound which is represented by any of general Formulas (C-1) to (C-4) below; 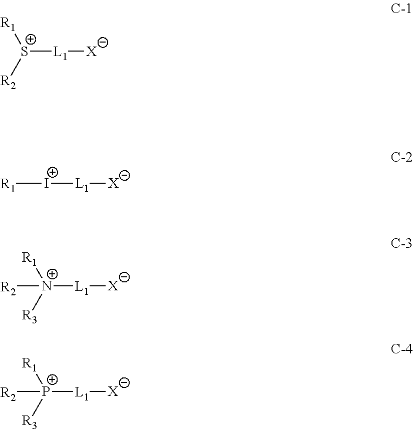
in general Formulas (C-1) to (C-4),
R₁, R₂, and R₃ each independently represents a substituent with 1 or more carbon atoms;
L₁ represents a divalent linking group or a single bond which links a cation site and an anion site;
—X⁻ represents an anion site which is selected from —COO⁻, —SO₃⁻, —SO₂⁻, and —N—R₄, R₄ represents a monovalent substituent having a group selected from a carbonyl group: —C(═O)—, a sulfonyl group: —S(═O)₂—, and a sulfinyl group: —S(═O)— in a linking site with an adjacent N atom;
two groups selected from R₁, R₂, and L₁ in general Formula (C-1) may be linked to form a ring structure;
R₁ and L₁ in general Formula (C-2) may be linked to form a ring structure;
two or more groups selected from R₁, R₂, R₃, and L₁ in general Formula (C-3) may be linked to form a ring structure; and
two or more groups selected from R₁, R₂, R₃, and L₁ in general Formula (C-4) may be linked to form a ring structure.

3. The pattern forming method according to claim 1,
wherein the content of the organic solvent in the developer which includes the organic solvent is 90 mass % to 100 mass % with respect to the total amount of the developer.

4. The pattern forming method according to claim 2,
wherein the content of the organic solvent in the developer which includes the organic solvent is 90 mass % to 100 mass % with respect to the total amount of the developer.

5. The pattern forming method according to claim 1,
wherein the developer contains at least one type of an organic solvent selected from the group consisting of a ketone-based solvent, an ester-based solvent, an alcohol-based solvent, an amide-based solvent, and an ether-based solvent.

6. The pattern forming method according to claim 4, wherein the developer contains at least one type of an organic solvent selected from the group consisting of a ketone-based solvent, an ester-based solvent, an alcohol-based solvent, an amide-based solvent, and an ether-based solvent.

7. The pattern forming method according to claim 1,
wherein the actinic ray-sensitive or radiation-sensitive resin composition further contains a hydrophobic resin (HR) which is different from the resin (A).

8. The pattern forming method according to claim 6,
wherein the actinic ray-sensitive or radiation-sensitive resin composition further contains a hydrophobic resin (HR) which is different from the resin (A).

9. The pattern forming method according to claim 1,
wherein the exposure in step (b) is liquid immersion exposure.

10. An actinic ray-sensitive or radiation-sensitive resin composition which is used for the pattern forming method according to claim 1.

11. A resist film which is formed of the actinic ray-sensitive or radiation-sensitive resin composition according to claim 10.

12. A method for manufacturing an electronic device which includes the pattern forming method according to claim 1.
